(19) United States
(12) Patent Application Publication
(10) Pub. No.: US 2025/0254876 A1
(43) Pub. Date: Aug. 7, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Seokcheon BAEK, Suwon-si (KR); Seungtae KIM, Suwon-si (KR); Seongjun SEO, Suwon-si (KR); Sori LEE, Suwon-si (KR)

(73) Assignee: Samsung Electronics Co., Ltd., Suwon-si (KR)

(21) Appl. No.: 18/806,955

(22) Filed: Aug. 16, 2024

(30) Foreign Application Priority Data
Feb. 6, 2024 (KR) 10-2024-0018416

(51) Int. Cl. H10B 43/27; H10B 41/27; H10B 41/41; H10B 43/40

(52) U.S. Cl. CPC H10B 43/27; H10B 41/27; H10B 41/41; H10B 43/40

(57) ABSTRACT

A semiconductor device includes a peripheral circuit structure including a circuit substrate and circuits on the circuit substrate, and a through-electrode region overlapping the peripheral circuit structure in a vertical direction, wherein the through-electrode region includes an insulating structure including first insulating films and second insulating films, which include different materials from each other and are alternately stacked one-by-one in the vertical direction, and having an upper surface that has a varying height in the vertical direction along with each of a first horizontal direction and a second horizontal direction perpendicular to the first horizontal direction, an interlayer dielectric covering the upper surface of the insulating structure, and through-electrodes passing through the insulating structure and the interlayer dielectric in the vertical direction in a local region of the through-electrode region and each configured to be connected to one circuit selected from the circuits of the peripheral circuit structure.

### CROSS-REFERENCE TO RELATED APPLICATION

This application is based on and claims priority under 35 U.S.C. § 119 to Korean Patent Application No. 10-2024-0018416, filed on Feb. 6, 2024, in the Korean Intellectual Property Office, the disclosure of which is incorporated by reference herein in its entirety.

### BACKGROUND

The inventive concepts relate to semiconductor devices and electronic systems including the semiconductor device, and more particularly, to semiconductor devices including a nonvolatile vertical memory device and electronic systems including the semiconductor device.

Semiconductor devices capable of storing large amounts of data are required in electronic systems requiring data storage. Therefore, to increase the data storage capacity of semiconductor devices, semiconductor devices including vertical memory devices including 3-dimensionally arranged memory cells have been proposed.

### SUMMARY

Some example embodiments of the inventive concepts provide semiconductor devices having a structure capable of securing reliability and improving electrical characteristics of the semiconductor device by omitting structures that may generate structural defects, such as cracks, during the process of manufacturing an integrated circuit device, even when the degree of integration of the semiconductor device including 3-dimensionally arranged memory cells increases.

Some example embodiments of the inventive concepts provide electronic systems including a semiconductor device that has a structure capable of securing reliability and improving electrical characteristics of the semiconductor device by omitting structures that may generate structural defects, such as cracks, during the process of manufacturing an integrated circuit device, even when the degree of integration of the semiconductor device including 3-dimensionally arranged memory cells increases.

According to an example embodiments of the inventive concepts, a semiconductor device includes a peripheral circuit structure including a circuit substrate and a plurality of circuits on the circuit substrate, and a through-electrode region overlapping the peripheral circuit structure in a vertical direction, wherein the through-electrode region includes an insulating structure that includes a plurality of first insulating films and a plurality of second insulating films and has an upper surface having a varying height in the vertical direction along with each of a first horizontal direction and a second horizontal direction perpendicular to the first horizontal direction, the plurality of first insulating films and the plurality of second insulating films including different materials from each other and being alternately stacked one-by-one in the vertical direction, an interlayer dielectric covering the upper surface of the insulating structure, and a plurality of through-electrodes passing through the insulating structure and the interlayer dielectric in the vertical direction in a local region of the through-electrode region, each of the plurality of through-electrodes being configured to be connected to one circuit selected from the plurality of circuits of the peripheral circuit structure.

According to an example embodiments of the inventive concepts, a semiconductor device includes a peripheral circuit structure including a circuit substrate and a plurality of circuits on the circuit substrate, a plurality of memory cell blocks, each of the plurality of memory cell blocks overlapping the peripheral circuit structure in a vertical direction, each of the plurality of memory cell blocks extending lengthwise in a first horizontal direction, and a through-electrode region overlapping the peripheral circuit structure in the vertical direction, the through-electrode region being between two adjacent memory cell blocks selected from the plurality of memory cell blocks, wherein the through-electrode region includes an insulating structure that includes a plurality of first insulating films and a plurality of second insulating films and has an upper surface having a varying height in the vertical direction along with each of the first horizontal direction and a second horizontal direction perpendicular to the first horizontal direction, the plurality of first insulating films and the plurality of second insulating films including different materials from each other and being alternately stacked one-by-one in the vertical direction, an interlayer dielectric covering the upper surface of the insulating structure, and a plurality of through-electrodes passing through the insulating structure and the interlayer dielectric in the vertical direction in a local region of the through-electrode region, each of the plurality of through-electrodes being configured to be connected to one circuit selected from the plurality of circuits of the peripheral circuit structure.

According to an example embodiments of the inventive concepts, a semiconductor device includes a peripheral circuit structure including a circuit substrate and a plurality of circuits on the circuit substrate, a plurality of mats overlapping the peripheral circuit structure in a vertical direction, each of the plurality of mats including a plurality of memory cell blocks extending lengthwise in a first horizontal direction, and at least one through-electrode region overlapping the peripheral circuit structure in the vertical direction, the at least one through-electrode region being at at least one of a first position or a second position, the first position being between two adjacent memory cell blocks selected from the plurality of memory cell blocks, and the second position being between two adjacent mats in a second horizontal direction perpendicular to the first horizontal direction from among the plurality of mats, wherein the at least one through-electrode region includes an insulating structure including a plurality of first insulating films, a plurality of second insulating films, and a plurality of third insulating films, the plurality of first insulating films and the plurality of second insulating films including different materials from each other, the plurality of first insulating films and the plurality of second insulating films alternately stacked one-by-one in the vertical direction, the plurality of third insulating films contacting an upper second insulating film among the plurality of second insulating films, the insulating structure having an upper surface that has a varying height in the vertical direction along with each of the first horizontal direction and the second horizontal direction, an interlayer dielectric covering the upper surface of the insulating structure, and a plurality of through-electrodes passing through the insulating structure and the interlayer dielectric in the vertical direction in a local region of the at least one through-electrode region, each of the plurality of through-electrodes being configured to be connected to one circuit selected from the plurality of circuits of the peripheral circuit structure, and wherein each of the plurality of first insulating films includes a silicon oxide film, and each of the plurality of second insulating films and the plurality of third insulating films includes a silicon nitride film or a hydrogenated silicon nitride film.

According to an example embodiment of the inventive concepts, an electronic system includes a main substrate, a semiconductor device on the main substrate, and a controller on the main substrate and electrically connected to the semiconductor device, wherein the semiconductor device includes a peripheral circuit structure including a circuit substrate and a plurality of circuits on the circuit substrate, and a through-electrode region overlapping the peripheral circuit structure in a vertical direction, and wherein the through-electrode region includes an insulating structure that includes a plurality of first insulating films and a plurality of second insulating films and has an upper surface having a varying height in the vertical direction along with each of a first horizontal direction and a second horizontal direction perpendicular to the first horizontal direction, the plurality of first insulating films and the plurality of second insulating films including different materials from each other and being alternately stacked one-by-one in the vertical direction, an interlayer dielectric covering the upper surface of the insulating structure, and a plurality of through-electrodes passing through the insulating structure and the interlayer dielectric in the vertical direction in a local region of the through-electrode region, each of the plurality of through-electrodes being configured to be connected to one circuit selected from the plurality of circuits of the peripheral circuit structure.

### BRIEF DESCRIPTION OF THE DRAWINGS

Example embodiments will be more clearly understood from the following detailed description taken in conjunction with the accompanying drawings in which:

FIG. 1 is a block diagram of a semiconductor device according to an example embodiment;

FIGS. 2A and 2B are plan views each illustrating a schematic planar structure that may be used for a memory cell array of a semiconductor device according to some example embodiments;

FIG. 3 is a schematic perspective view of a semiconductor device including a region EX1 of FIG. 2A;

FIG. 4 is a schematic plan view of a portion of a cell array structure of a semiconductor device according to an example embodiment;

FIG. 5 is an equivalent circuit diagram of a memory cell array of a semiconductor device according to an example embodiment;

FIG. 6A is a plan view illustrating an example of a configuration of a region NB of FIG. 4, FIG. 6B is a plan view illustrating some components of a through-electrode region of a semiconductor device according to an example embodiment, and FIG. 6C is a plan view illustrating, in detail, an example of a configuration of a region EX2 of FIG. 4;

FIGS. 7 to 11 are cross-sectional views illustrating a semiconductor device according to an example embodiment in detail, and in particular, FIG. 7 is a cross-sectional view taken along a line X1-X1′ of FIG. 6A, FIG. 8 is a cross-sectional view taken along a line Y1-Y1′ of FIG. 6A, FIG. 9 is a cross-sectional view taken along a line Y2-Y2′ of FIG. 6B, FIG. 10 is a cross-sectional view taken along a line Y3-Y3′ of FIG. 6B, and FIG. 11 is a cross-sectional view taken along a line Y4-Y4′ of FIG. 6B;

FIGS. 12A, 12B, and 12C are cross-sectional views illustrating a semiconductor device according to an example embodiment;

FIGS. 13A and 13B are cross-sectional views illustrating a semiconductor device according to an example embodiment;

FIGS. 14A and 14B are cross-sectional views illustrating a semiconductor device according to an example embodiment;

FIGS. 15A and 15B are cross-sectional views illustrating a semiconductor device according to an example embodiment;

FIG. 16 is a cross-sectional view illustrating a semiconductor device according to an example embodiment;

FIG. 17 is a plan view illustrating a semiconductor device according to an example embodiment;

FIG. 18 is a diagram schematically illustrating an electronic system including a semiconductor device, according to an example embodiment;

FIG. 19A is a perspective view schematically illustrating an electronic system including a semiconductor device, according to an example embodiment;

FIG. 19B is a cross-sectional view taken along a line I-I′ of FIG. 19A and conceptually illustrates a semiconductor package shown in FIG. 19A.; and

FIGS. 20A to 32D are cross-sectional views illustrating a method of manufacturing a semiconductor device, according to an example embodiment. In particular, FIG. 20A, FIG. 21A, FIG. 22A, FIG. 23, FIG. 24A, FIG. 25A, FIG. 26, FIG. 27A, FIG. 28A, FIG. 29, FIG. 31A, and FIG. 32A are cross-sectional views illustrating some components of a region corresponding to the cross-section taken along the line X1-X1′ of FIG. 6A, according to a sequence of processes, FIG. 20B, FIG. 21B, FIG. 22B, FIG. 25B, and FIG. 28B are cross-sectional views illustrating some components of a region corresponding to the cross-section taken along the line Y1-Y1′ of FIG. 6A, according to the sequence of processes, FIG. 24B, FIG. 27B, FIG. 28C, FIG. 30A, FIG. 31B, and FIG. 32B are cross-sectional views illustrating some components of a region corresponding to the cross-section taken along the line Y2-Y2′ of FIG. 6B, according to the sequence of processes, FIG. 24C, FIG. 27C, FIG. 28D, FIG. 30B, FIG. 31C, and FIG. 32C are cross-sectional views illustrating some components of a region corresponding to the cross-section taken along the line Y3-Y3′ of FIG. 6B, according to the sequence of processes, and FIG. 24D, FIG. 27D, FIG. 28E, FIG. 30C, FIG. 31D, and FIG. 32D are cross-sectional views illustrating some components of a region corresponding to the cross-section taken along the line Y4-Y4′ of FIG. 6B, according to the sequence of processes.

### DETAILED DESCRIPTION

Hereinafter, some example embodiments of the inventive concepts will be described in detail with reference to the accompanying drawings. Like components are denoted by like reference numerals throughout the specification, and repeated descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

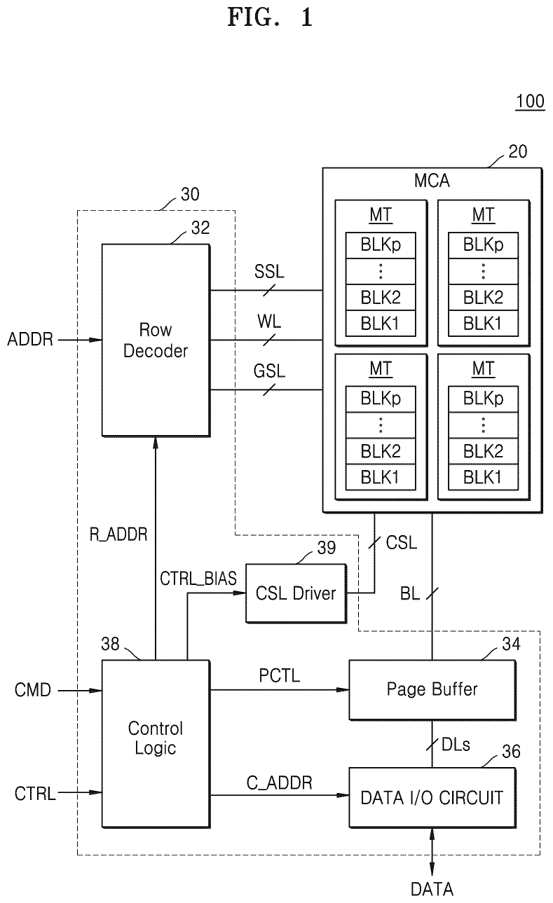

FIG. 1 is a block diagram of a semiconductor device 100 according to an example embodiment.

Referring to FIG. 1, the semiconductor device 100 may include a memory cell array 20 and a peripheral circuit 30. The memory cell array 20 may include a plurality of mats MT. Each of the plurality of mats MT may include a plurality of memory cell blocks BLK1, BLK2, . . . , and BLKp. Each of the plurality of memory cell blocks BLK1, BLK2, . . . , and BLKp may include a plurality of memory cells. A memory cell block BLK1, BLK2, . . . , or BLKp may be connected to the peripheral circuit 30 via a bit line BL, a word line WL, a string select line SSL, and a ground select line GSL. Herein, the memory cell array 20 may be referred to as a memory cell array MCA.

The peripheral circuit 30 may include a row decoder 32, a page buffer 34, a data input/output circuit 36, a control logic 38, and a common source line driver 39. The peripheral circuit 30 may further include various circuits, such as a voltage generation circuit for generating various voltages desired for operations of the semiconductor device 100, an error correction circuit for correcting errors in data read from the memory cell array 20, an input/output interface, and the like.

The memory cell array 20 may be connected to the row decoder 32 via the word line WL, the string select line SSL, and the ground select line GSL and may be connected to the page buffer 34 via the bit line BL. In the memory cell array 20, each of the plurality of memory cells, which are included in the plurality of memory cell blocks BLK1, BLK2, . . . , and BLKp, may include a flash memory cell. The memory cell array 20 may include a 3-dimensional memory cell array. The 3-dimensional memory cell array may include a plurality of NAND strings, and each of the plurality of NAND strings may include a plurality of memory cells respectively connected to a plurality of word lines WL that are vertically stacked.

The peripheral circuit 30 may receive an address ADDR, a command CMD, and a control signal CTRL from outside the semiconductor device 100 and may transmit data DATA to and receive data DATA from a device external to the semiconductor device 100.

The row decoder 32 may select at least one of the plurality of memory cell blocks BLK1, BLK2, . . . , and BLKp in response to the address ADDR from outside the semiconductor device 100 and may select the word line WL, the string select line SSL, and the ground select line GSL of the selected memory cell block. The row decoder 32 may transfer a voltage for performing a memory operation to the word line WL of the selected memory cell block.

The page buffer 34 may be connected to the memory cell array 20 via the bit line BL. The page buffer 34 may apply a voltage according to the data DATA, which is intended to be stored in the memory cell array 20, to the bit line BL by operating as a write driver during a program operation and may sense the data DATA, which is stored in the memory cell array 20, by operating as a sense amplifier during a read operation. The page buffer 34 may operate according to a control signal PCTL provided by the control logic 38.

The data input/output circuit 36 may be connected with the page buffer 34 via a plurality of data lines DLs. During the program operation, the data input/output circuit 36 may receive the data DATA from a memory controller (not shown) and may provide program data DATA to the page buffer 34, based on a column address C_ADDR provided by the control logic 38. During the read operation, the data input/output circuit 36 may provide read data DATA stored in the page buffer 34 to the memory controller, based on the column address C_ADDR provided by the control logic 38.

The data input/output circuit 36 may transfer an address or a command, which is input thereto, to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data input/output circuit 36. The control logic 38 may generate various internal control signals, which are used in the semiconductor device 100, in response to the control signal CTRL. For example, when a memory operation, such as a program operation or an erase operation, is performed, the control logic 38 may adjust levels of voltages provided to the word line WL and the bit line BL, respectively.

The common source line driver 39 may be connected to the memory cell array 20 via a common source line CSL. The common source line driver 39 may apply a common source voltage (e.g., a power supply voltage) or a ground voltage to the common source line CSL, based on a control signal CTRL_BIAS of the control logic 38.

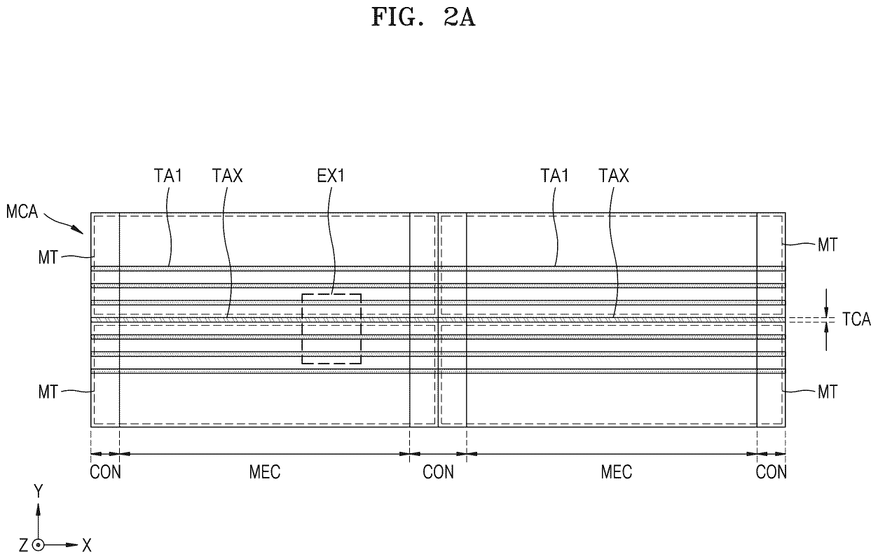

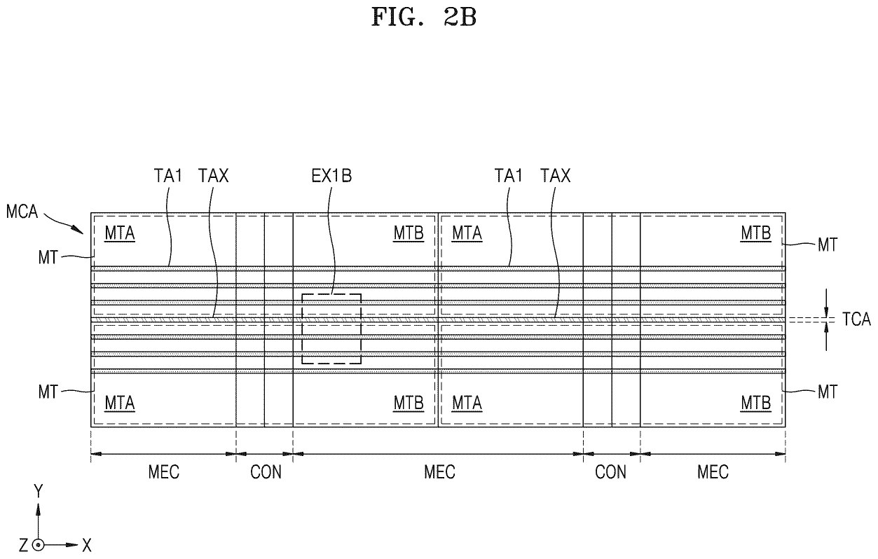

FIGS. 2A and 2B are plan views each illustrating a schematic planar structure that may be used for the memory cell array MCA of the semiconductor device 100 according to some example embodiments. The memory cell array MCA shown in each of FIGS. 2A and 2B may constitute a portion of the memory cell array 20 shown in FIG. 1.

Referring to FIG. 2A, the memory cell array MCA may include four mats MT arranged one-by-one in four quadrants dividing one rectangular area, respectively. Each of the four mats MT may include a memory cell area MEC, and connection areas CON arranged on both sides of the memory cell area MEC, respectively, in terms of a first horizontal direction (an X direction). In each of the four mats MT, one of the two connection areas CON arranged on both sides of the memory cell area MEC, respectively, in terms of the first horizontal direction (the X direction) may be omitted. For example, a connection area CON adjacent to a central portion of the rectangular area, which includes the four mats MT, in terms of the first horizontal direction (the X direction) may be omitted, and in this case, in each of the four mats MT, the memory cell area MEC may further extend to the central portion of the rectangular area in terms of the first horizontal direction (the X direction) than that shown in FIG. 2A.

Referring to FIG. 2B, the memory cell array MCA may include four mats MT arranged one-by-one in four quadrants dividing one rectangular area, respectively, similar to the example described with reference to FIG. 2A. However, in the memory cell array MCA shown in FIG. 2B, a connection area CON may be arranged in a central portion of each of the four mats MT. Each of the four mats MT may have a structure divided into a first mat MTA and a second mat MTB by the connection area CON.

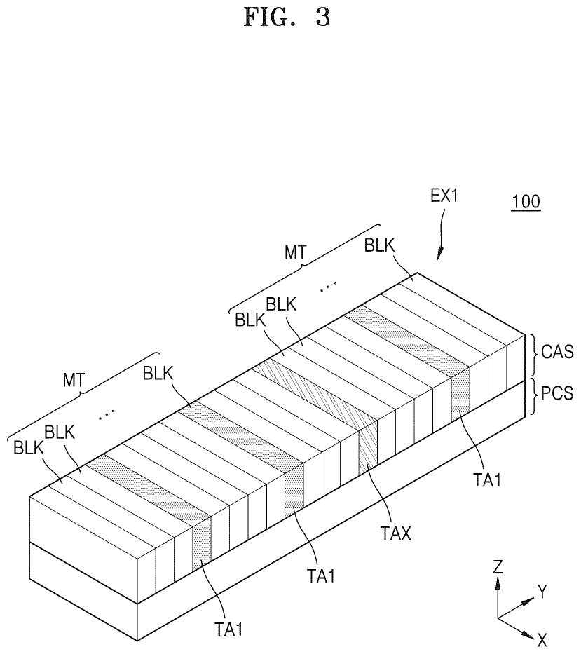

FIG. 3 is a schematic perspective view of the semiconductor device 100 including a region EX1 of FIG. 2A. Although the region EX1 of FIG. 2A is described below, a configuration described below with reference to FIG. 3 may also be equally applied to a region EX1B of FIG. 2B.

Referring to FIGS. 2A and 3, the semiconductor device 100 may include a cell array structure CAS and a peripheral circuit structure PCS, which overlap each other in the vertical direction (a Z direction). The cell array structure CAS may include the memory cell array 20 described with reference to FIG. 1. The peripheral circuit structure PCS may include the peripheral circuit 30 described with reference to FIG. 1.

The cell array structure CAS may include a plurality of mats MT, and each of the plurality of mats MT may include a plurality of memory cell blocks BLK1, BLK2, . . . , and BLKp (see FIG. 1) and a plurality of through-electrode regions TA1. Each of the plurality of through-electrode regions TA1, which are included in one mat MT, may correspond to a dummy memory cell block not including actually operating memory cells.

In one mat MT, each of the plurality of through-electrode regions TA1 may extend lengthwise in the first horizontal direction (the X direction) through the memory cell area MEC and the connection area CON. In one met MT, the plurality of through-electrode regions TA1 are apart from each other in a second horizontal direction (a Y direction), and at least one memory cell block selected from the plurality of memory cell blocks BLK1, BLK2, . . . , and BLKp (see FIG. 1) may be arranged between each of the plurality of through-electrode regions TA1.

A through-electrode region TAX may be arranged in a tile cut area TCA between two mats MT adjacent to each other in the second horizontal direction (the Y direction) from among the plurality of mats MT. Each of the plurality of through-electrode regions TA1 arranged in a mat MT and the through-electrode region TAX arranged in the tile cut area TCA may have substantially the same configuration. In some example embodiments, the through-electrode region TAX arranged in the tile cut area TCA may be omitted, and in this case, the through-electrode region TAX may be replaced by an insulating structure.

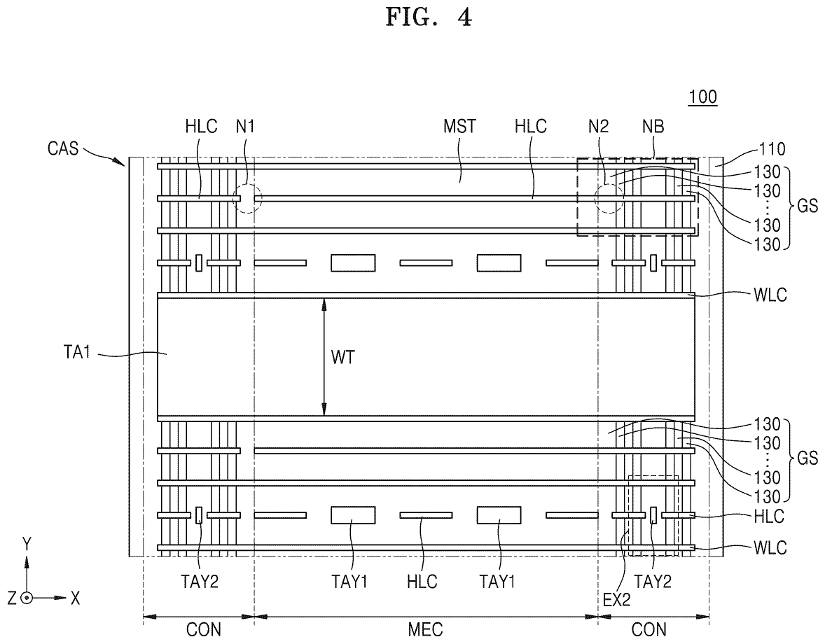

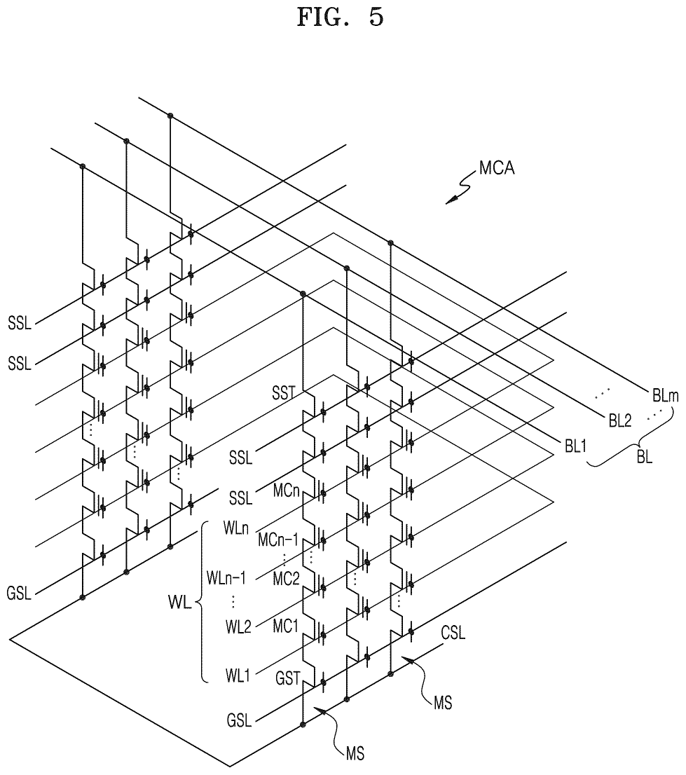

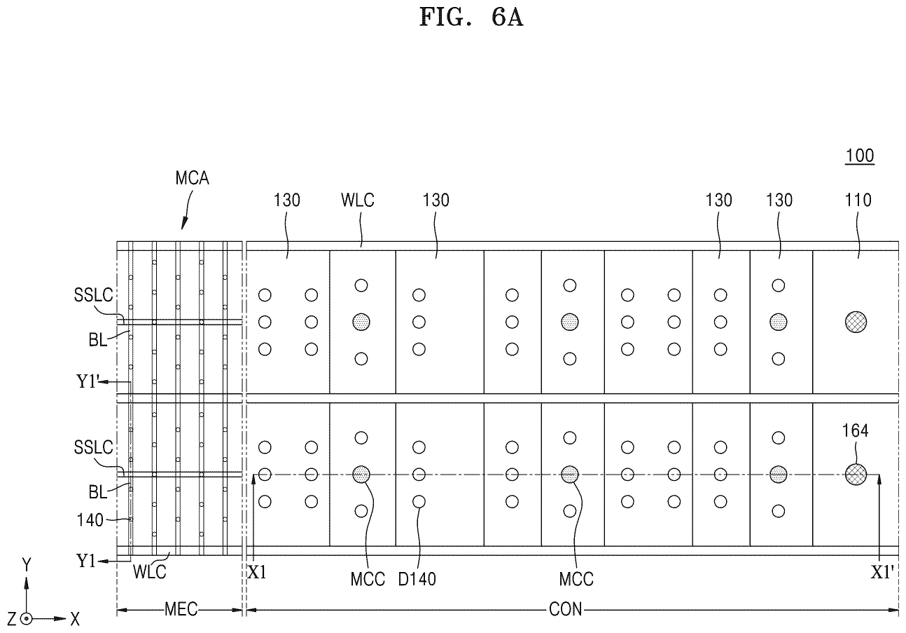

FIG. 4 is a schematic plan view of a portion of the cell array structure CAS of the semiconductor device 100 according to an example embodiment.

Referring to FIG. 4, the cell array structure CAS of the semiconductor device 100 may include a plate common source line 110 and a plurality of memory cell blocks arranged on the plate common source line 110. The plurality of memory cell blocks may correspond to the plurality of memory cell blocks BLK1, BLK2, . . . , and BLKp described with reference to FIG. 1. The peripheral circuit structure PCS (see FIG. 3) may be arranged under the plate common source line 110. The plurality of memory cell blocks may be arranged to overlap the peripheral circuit structure PCS in the vertical direction (the Z direction) with the plate common source line 110 therebetween. Each of the plurality of memory cell blocks may have a shape extending lengthwise in the first horizontal direction (the X direction) when viewed in a plane (the X-Y plane in FIG. 4).

The cell array structure CAS may include a memory cell area MEC, and a connection area CON arranged on both sides of the memory cell area MEC in terms of the first horizontal direction (the X direction). Each of the plurality of memory cell blocks may include a memory stack structure MST extending in the first horizontal direction (the X direction) throughout the memory cell area MEC and the connection area CON. The memory stack structure MST may include a plurality of gate lines 130 stacked to overlap each other in the vertical direction (the Z direction) in the memory cell area MEC and the connection area CON on the plate common source line 110. In each of a plurality of memory stack structures MST, the plurality of gate lines 130 may constitute a gate stack GS. In each of the plurality of memory stack structures MST, the plurality of gate lines 130 may respectively constitute the ground select line GSL, the plurality of word lines WL, and the string select line SSL, which are shown in FIG. 1. The plurality of gate lines 130 may respectively have decreasing areas in the X-Y plane with the increasing distance from the plate common source line 110. Respective central portions of the plurality of gate lines 130, which overlap each other in the vertical direction (the Z direction), may constitute the memory cell area MEC, and respective edge portions of the plurality of gate lines 130 may constitute the connection area CON. Although FIG. 4 illustrates that the edge portion of each of the plurality of gate lines 130 in the connection area CON extends with a straight line shape in the second horizontal direction (the Y direction), this is for the simplicity of illustration, and the edge portion of each of the plurality of gate lines 130, in the connection area CON of each of the plurality of memory cell blocks, may extend with an uneven shape in the second horizontal direction (the Y direction), when viewed in a plane (the X-Y plane in FIG. 4).

A plurality of word line cut structures WLC may be arranged on the plate common source line 110 in the memory cell area MEC and the connection area CON to extend lengthwise in the first horizontal direction (the X direction). The plurality of word line cut structures WLC may be apart from each other in the second horizontal direction (the Y direction). Each of the plurality of memory cell blocks may be arranged between a pair of word line cut structures WLC adjacent to each other from among the plurality of word line cut structures WLC. The plurality of word line cut structures WLC may respectively arranged one-by-one on both sides of each of the plurality of memory cell blocks in terms of the second horizontal direction (the Y direction) to define the width of each of the plurality of memory cell blocks in the second horizontal direction (the Y direction). In at least some of the plurality of memory cell blocks, a plurality of separation cut structures HLC may be arranged to extend lengthwise in the first horizontal direction (the X direction). A certain region of each of the at least some memory cell blocks may be separated in the second horizontal direction (the Y direction) by a separation cut structure HLC. In some example embodiments, as shown in a region N1 of FIG. 4, the separation cut structure HLC in a memory cell block may include portions intermittently extending in the first horizontal direction (the X direction). In some example embodiments, as shown in a region N2 of FIG. 4, the separation cut structure HLC in the memory cell block may include a portion continuously extending in the first horizontal direction (the X direction). In some example embodiments, the plurality of word line cut structures WLC and the plurality of separation cut structures HLC may each include, but are not limited to, a silicon oxide film.

A width WT of the through-electrode region TA1 in the second horizontal direction (the Y direction) may be defined by a pair of word line cut structures WLC arranged on both sides of the through-electrode region TA1, respectively, with the through-electrode region TA1 therebetween.

In some example embodiments, in the second horizontal direction (the Y direction), the width WT of the through-electrode region TA1 may be greater than the width of each of the plurality of memory cell blocks that are included in the cell array structure CAS. In some example embodiments, in the second horizontal direction (the Y direction), the width WT of the through-electrode region TA1 may be at least twice the width of each of the plurality of memory cell blocks. In some example embodiments, unlike the example shown in FIG. 4, in the second horizontal direction (the Y direction), the width WT of the through-electrode region TA1 may be equal or similar to the width of each of the plurality of memory cell blocks.

In some example embodiments, the semiconductor device 100 may further include a plurality of through-electrode regions TAY1 and TAY2, which pass through the memory cell block of the cell array structure CAS in the vertical direction (the Z direction). A plurality of through-electrode regions TAY1 may each be arranged in the memory cell area MEC of the cell array structure CAS, and a plurality of through-electrode regions TAY2 may each be arranged in the connection area CON of the cell array structure CAS. The through-electrode region TAX shown in FIGS. 2A, 2B, and 3 and the plurality of through-electrode regions TAY1 and TAY2 shown in FIG. 4 may each include at least some of characteristic components of the plurality of through-electrode regions TA1, which are described below.

The semiconductor device 100 may not include a separate dam structure that defines the width of each of the plurality of through-electrode regions (that is, TA1, TAX, TAY1, and TAY2).

FIG. 5 is an equivalent circuit diagram of the memory cell array MCA of the semiconductor device 100 according to an example embodiment. FIG. 5 illustrates an equivalent circuit diagram of a vertical NAND flash memory device having a vertical channel structure.

Referring to FIG. 5, the memory cell array MCA may include a plurality of memory cell strings MS. The memory cell array MCA may include a plurality of bit lines BL (that is, BL1, BL2, . . . , and BLm), a plurality of word lines WL (that is, WL1, WL2, . . . , WLn−1, and WLn), at least one string select line SSL, at least one ground select line GSL, and a common source line CSL. The plurality of memory cell strings MS may be formed between the plurality of bit lines BL and the common source line CSL. Although FIG. 5 illustrates an example in which each of the plurality of memory cell strings MS includes one ground select line GSL and two string select lines SSL, the inventive concepts are not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn−1, and MCn. A drain region of the string select transistor SST may be connected to a bit line BL, and a source region of the ground select transistor GST may be connected to the common source line CSL. The common source line CSL may be a region to which source regions of a plurality of ground select transistors GST are commonly connected.

The string select transistor SST may be connected to the string select line SSL, and the ground select transistor GST may be connected to the ground select line GSL. Each of the plurality of memory cell transistors MC1, MC2, . . . , MCn−1, and MCn may be connected to a word line WL.

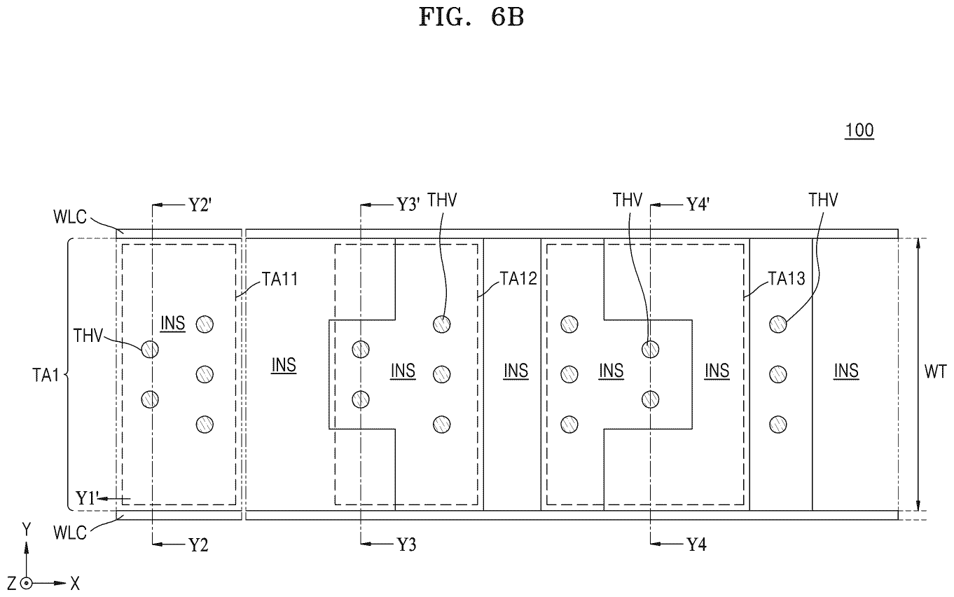

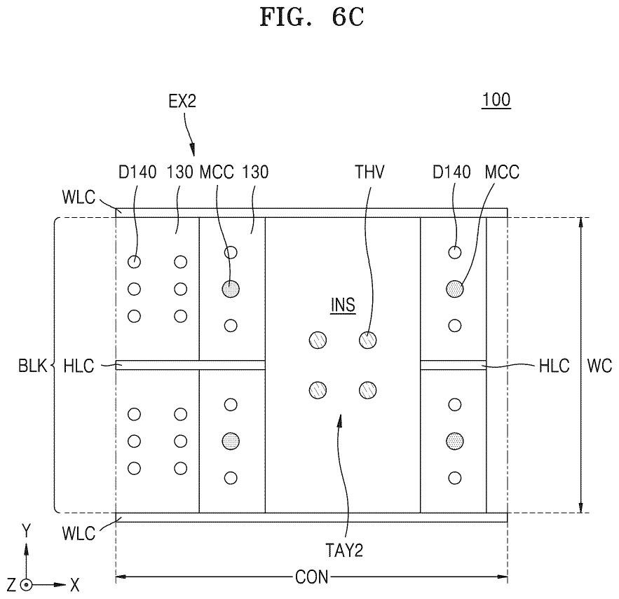

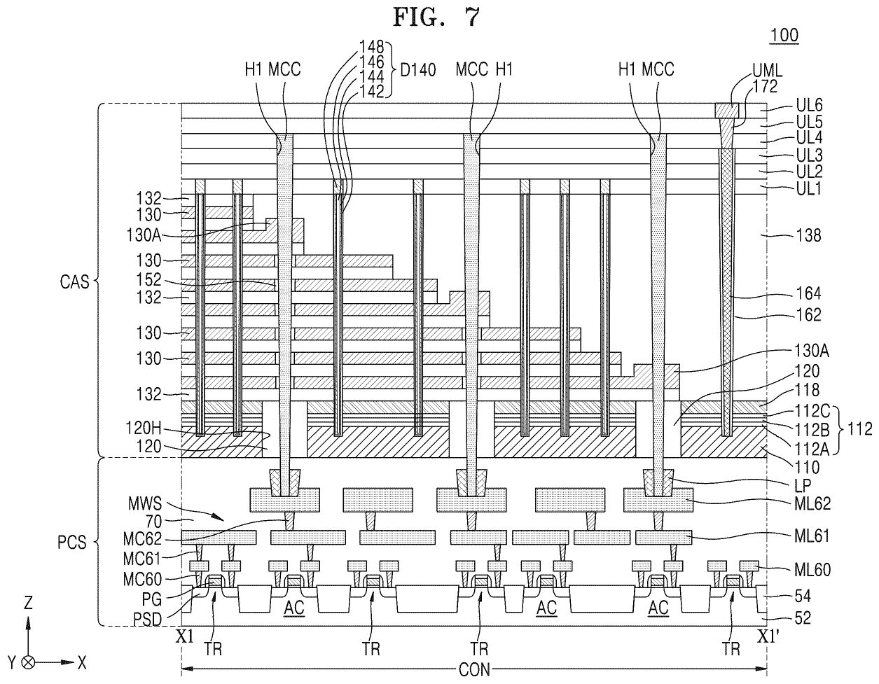

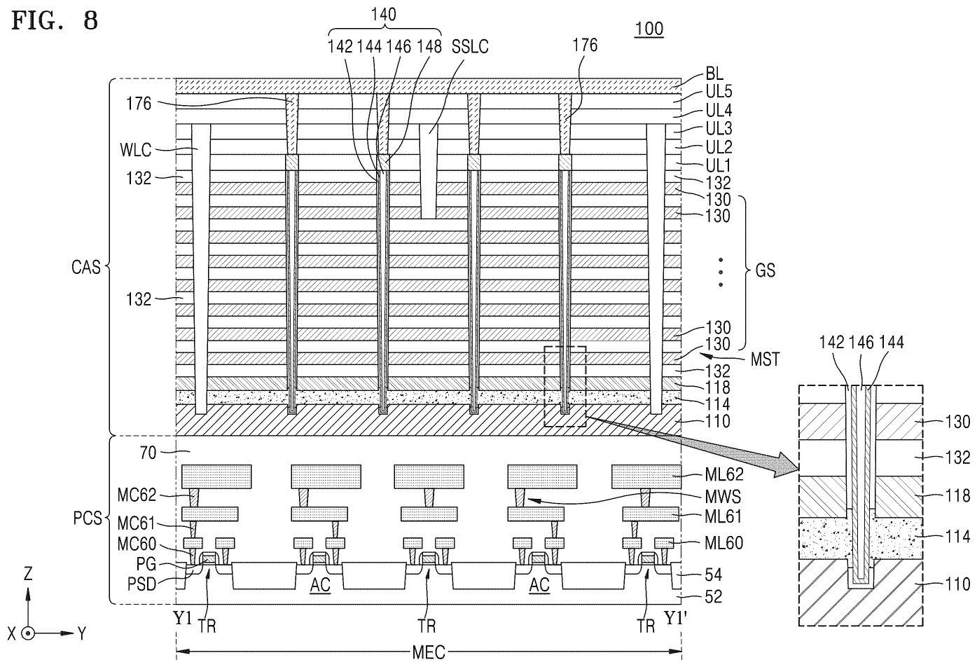

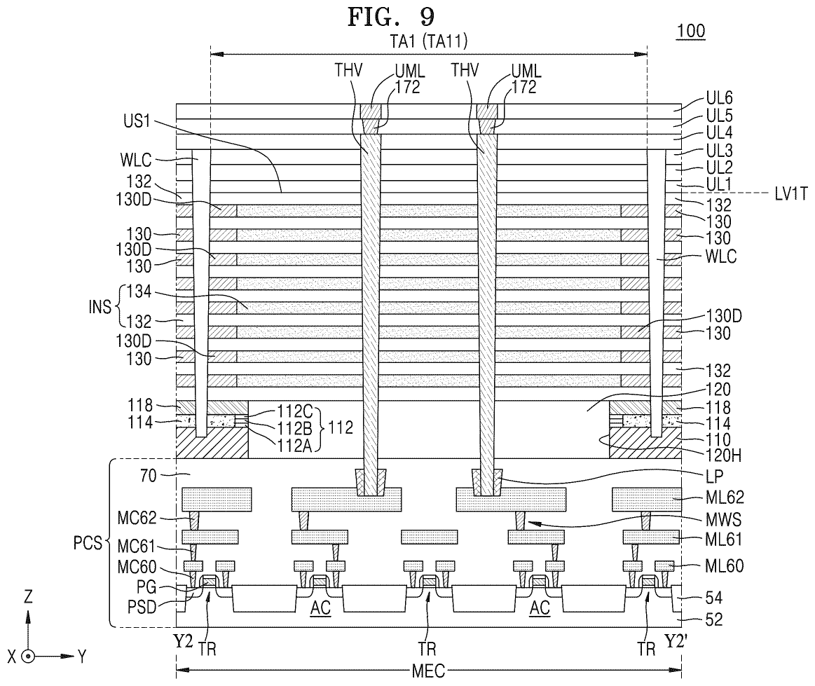

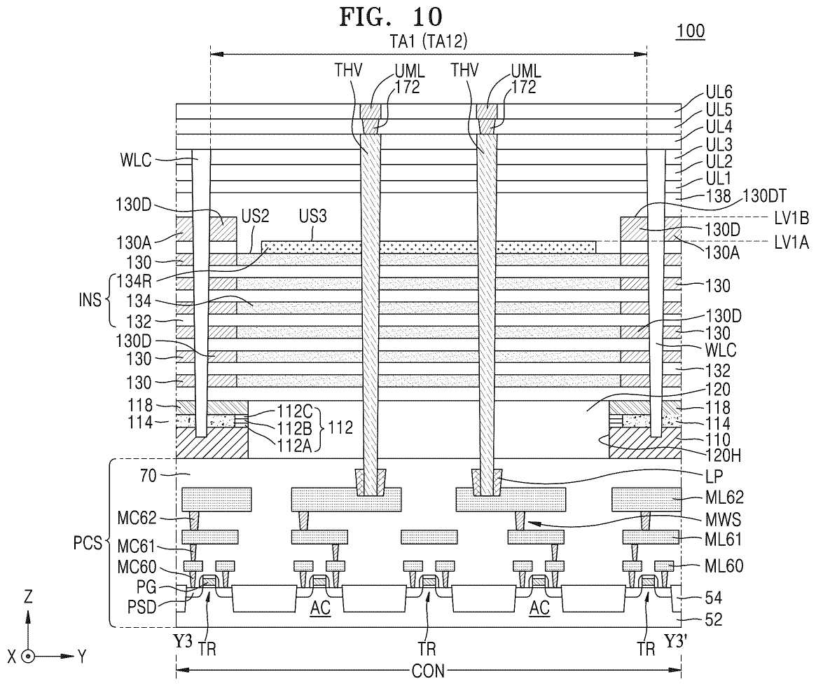

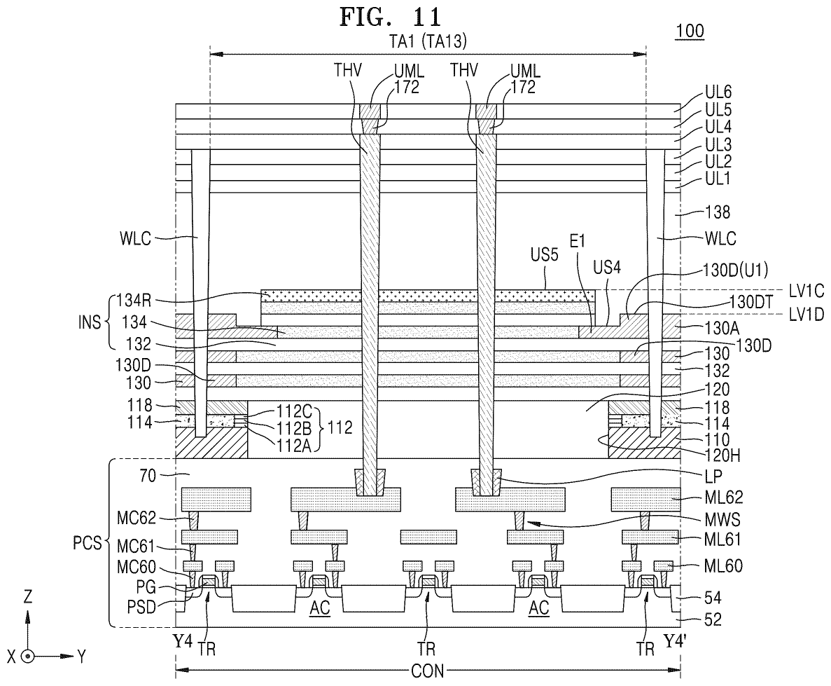

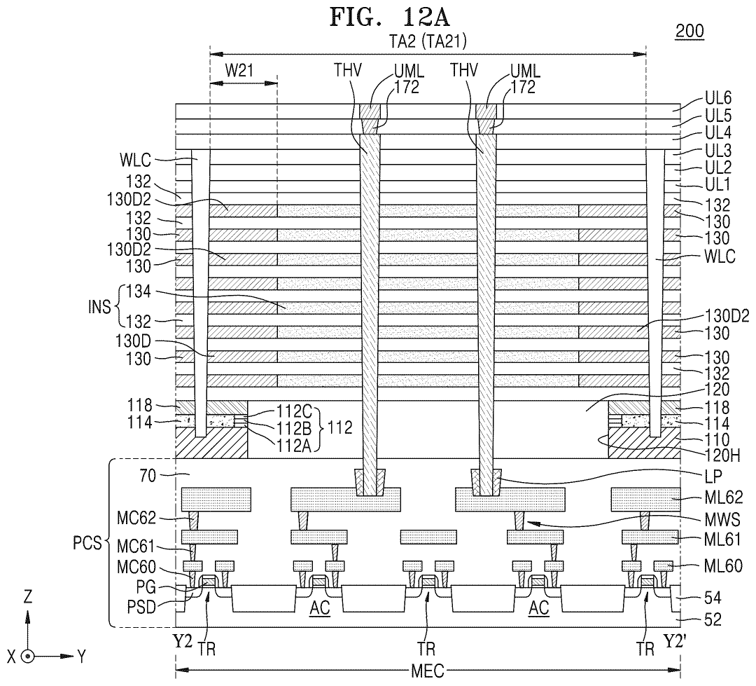

FIG. 6A is a plan view illustrating an example of a configuration of a region NB of FIG. 4 in detail, FIG. 6B is a plan view illustrating some components of a through-electrode region TA1 of a semiconductor device according to an example embodiment, and FIG. 6C is a plan view illustrating an example of a configuration of a region EX2 of FIG. 4 in detail and illustrates an example of a configuration of a through-electrode region TAY2 of a memory cell block BLK. The memory cell block BLK in FIG. 6C may correspond to one of the memory cell blocks BLK1, BLK2, . . . , and BLKp of FIG. 1. FIGS. 7 to 11 are cross-sectional views illustrating a semiconductor device according to an example embodiment in detail. More specifically, FIG. 7 is a cross-sectional view of the semiconductor device, taken along a line X1-X1′ of FIG. 6A. FIG. 8 is a cross-sectional view of the semiconductor device, taken along a line Y1-Y1′ of FIG. 6A. FIG. 9 is a cross-sectional view of the semiconductor device, taken along a line Y2-Y2′ of FIG. 6B. FIG. 10 is a cross-sectional view of the semiconductor device, taken along a line Y3-Y3′ of FIG. 6B. FIG. 11 is a cross-sectional view of the semiconductor device, taken along a line Y4-Y4′ of FIG. 6B. In FIGS. 6A to 11, the same reference numerals as in FIGS. 1 to 5 denote the same members, respectively, and here, repeated descriptions thereof are omitted.

Referring to FIGS. 6A to 11, the semiconductor device 100 may include a peripheral circuit structure PCS, and a cell array structure CAS arranged on the peripheral circuit structure PCS and overlapping the peripheral circuit structure PCS in the vertical direction (the Z direction).

The cell array structure CAS may include a plate common source line 110, a first conductive plate 114, a second conductive plate 118, a memory stack structure MST, which are arranged in a memory cell area MEC, and an insulating plate 112, the second conductive plate 118, and a memory stack structure MST (e.g., respective edge portions of the plurality of gate lines 130), which are arranged in a connection area CON.

As shown in FIG. 7, in the connection area CON of the cell array structure CAS, the insulating plate 112, the second conductive plate 118, and respective edge portions of a plurality of gate lines 130 may be sequentially stacked in the stated order on the plate common source line 110. As shown in FIG. 8, in the memory cell area MEC of the cell array structure CAS, the first conductive plate 114, the second conductive plate 118, and the memory stack structure MST may be sequentially stacked in the stated order on the plate common source line 110.

The plate common source line 110, the first conductive plate 114, and the second conductive plate 118 may function as a common source line CSL supplying currents to vertical memory cells of the cell array structure CAS.

In some example embodiments, the plate common source line 110 may include a semiconductor material, such as polysilicon. Each of the first conductive plate 114 and the second conductive plate 118 may include a doped polysilicon film, a metal film, or a combination thereof. The metal film may include, but is not limited to, tungsten (W). The memory stack structure MST may include a gate stack GS. The gate stack GS may include a plurality of gate lines 130 extending in a horizontal direction to be parallel to each other and overlapping each other in the vertical direction (the Z direction). Each of the plurality of gate lines 130 may include metal, metal silicide, an impurity-doped semiconductor, or a combination thereof. For example, each of the plurality of gate lines 130 may include metal, such as tungsten, nickel, cobalt, or tantalum, metal silicide, such as tungsten silicide, nickel silicide, cobalt silicide, or tantalum silicide, doped polysilicon, or a combination thereof.

A first insulating film 132 may be arranged between the second conductive plate 118 and the plurality of gate lines 130 and between each of the plurality of gate lines 130. The uppermost gate line 130 from among the plurality of gate lines 130 may be covered by the first insulating film 132. The first insulating film 132 may include silicon oxide.

As shown in FIGS. 6A and 8, in the memory cell area MEC (as well as in the connection area CON), a plurality of word line cut structures WLC may extend lengthwise in the first horizontal direction (the X direction) on the plate common source line 110. The width of each of the plurality of gate lines 130 in the second horizontal direction (the Y direction) may be defined by the plurality of word line cut structures WLC.

Each of the plurality of word line cut structures WLC may include an insulating structure. In some example embodiments, the insulating structure may include silicon oxide, silicon nitride, silicon oxynitride, or a low-k material. For example, the insulating structure may include a silicon oxide film, a silicon nitride film, a SiON film, a SiOCN film, a SiCN film, or a combination thereof. In some example embodiments, at least a portion of the insulating structure may include an air gap. As used herein, the term “air” may refer to the atmosphere or to other gases that may be present during a manufacturing process.

The plurality of gate lines 130 constituting one gate stack GS may be stacked on the second conductive plate 118 between two adjacent word line cut structures WLC to overlap each other in the vertical direction (the Z direction). The plurality of gate lines 130 constituting one gate stack GS may include the ground select line GSL, the plurality of word lines WL, and the string select line SSL, which are described with reference to FIG. 1.

As shown in FIG. 8, among the plurality of gate lines 130, each of two upper gate lines 130 may be separated (e.g., divided) in the second horizontal direction (the Y direction) with a string select line cut structure SSLC therebetween. Two gate lines 130 separated from each other with the string select line cut structure SSLC therebetween may each constitute the string select line SSL described with reference to FIG. 1. Although FIG. 8 illustrates an example in which one string select line cut structure SSLC is formed in one gate stack GS, the inventive concepts are not limited to the example shown in FIG. 8. For example, at least two string select line cut structures SSLC may be formed in one gate stack GS. The string select line cut structure SSLC may include an insulating film. In some example embodiments, the string select line cut structure SSLC may include an insulating film including an oxide film, a nitride film, or a combination thereof. In some example embodiments, at least a portion of the string select line cut structure SSLC may include an air gap.

As shown in FIGS. 7 to 11, the peripheral circuit structure PCS may include a substrate 52, a plurality of peripheral circuits on the substrate 52, and a multilayer wiring structure MWS for connecting the plurality of peripheral circuits to each other or connecting the plurality of peripheral circuits to components in the memory cell area MEC.

The substrate 52 may include a semiconductor substrate. For example, the substrate 52 may include Si, Ge, or SiGe. An active region AC may be defined in the substrate 52 by a device isolation film 54. A plurality of transistors TR constituting the plurality of peripheral circuits may each be formed on the active region AC. Each of the plurality of transistors TR may include a gate PG and a plurality of ion-implanted regions PSD formed in the active region AC on both sides of the gate PG. Each of the plurality of ion-implanted regions PSD may constitute a source region or a drain region of a transistor TR.

The plurality of circuits of the peripheral circuit structure PCS may include various circuits that are included in the peripheral circuit 30 described with reference to FIG. 1. In some example embodiments, the plurality of circuits of the peripheral circuit structure PCS may include the row decoder 32, the page buffer 34, the data input/output circuit 36, the control logic 38, and the common source line driver 39, which are shown in FIG. 1.

The multilayer wiring structure MWS of the peripheral circuit structure PCS may include a plurality of wiring layers ML60, ML61, and ML62 and a plurality of contacts MC60, MC61, and MC62. At least some of the plurality of wiring layers ML60, ML61, and ML62 may be configured to be electrically connected to the transistors TR. The plurality of contacts MC60, MC61, and MC62 may be configured to respectively connect the plurality of transistors TR to some selected from the plurality of wiring layers ML60, ML61, and ML62. A conductive landing pad LP may be arranged on a portion of the uppermost wiring layer ML62 from among the plurality of wiring layers ML60, ML61, and ML62. The conductive landing pad LP may include polysilicon. The plurality of transistors TR, the multilayer wiring structure MWS, and the conductive landing pad LP, which are included in the peripheral circuit structure PCS, may be covered by an interlayer dielectric 70. The interlayer dielectric 70 may include a silicon oxide film, a silicon nitride film, a SiON film, a SiOCN film, or a combination thereof. The plate common source line 110 may be arranged on the interlayer dielectric 70.

The plate common source line 110, the insulating plate 112, the first conductive plate 114, and the second conductive plate 118 may each extend in the horizontal direction to cover the peripheral circuit structure PCS.

As shown in FIGS. 7 to 11, in some regions of each of the memory cell area MEC and the connection area CON, a plurality of through-openings 120H may be formed to pass through the plate common source line 110, the insulating plate 112, the first conductive plate 114, and the second conductive plate 118. Each of the plurality of through-openings 120H may be filled with an insulating plug 120. The insulating plug 120 may include a silicon oxide film, a silicon nitride film, or a combination thereof.

As shown in FIG. 8, in the memory cell area MEC, a plurality of channel structures 140 may pass through, in the vertical direction (the Z direction), the plurality of gate lines 130, a plurality of first insulating films 132, the second conductive plate 118, the first conductive plate 114, and the plate common source line 110. The plurality of channel structures 140 may be arranged at certain intervals in the first horizontal direction (the X direction) and the second horizontal direction (the Y direction) to be apart from each other. Each of the plurality of channel structures 140 may include a gate dielectric film 142, a channel region 144, a buried insulating film 146, and a drain region 148.

The gate dielectric film 142 may include a tunneling dielectric film, a charge storage film, and a blocking dielectric film, which are formed in the stated order on the channel region 144. The tunneling dielectric film may include silicon oxide, hafnium oxide, aluminum oxide, zirconium oxide, tantalum oxide, or the like. The charge storage film is a region, in which electrons having passed through the tunneling dielectric film from the channel region 144 may be stored, and may include silicon nitride, boron nitride, silicon boron nitride, or impurity-doped polysilicon. The blocking dielectric film may include silicon oxide, silicon nitride, or metal oxide having a dielectric constant that is greater than that of silicon oxide. The metal oxide may include hafnium oxide, aluminum oxide, zirconium oxide, tantalum oxide, or a combination thereof.

As shown in FIG. 8, the first conductive plate 114 may pass through a portion of the gate dielectric film 142 in the horizontal direction (the X direction and/or the Y direction) to contact the channel region 144. The gate dielectric film 142 may include a portion arranged at a higher level than the first conductive plate 114 and covering the sidewall of the channel region 144 and a portion arranged at a lower level than the first conductive plate 114 and covering the lower surface of the channel region 144. The channel region 144 may be apart from the plate common source line 110 with the gate dielectric film 142 therebetween. The sidewall of the channel region 144 may be in contact with the first conductive plate 114 and may be configured to be electrically connected to the first conductive plate 114.

As shown in FIG. 8, the channel region 144 may have a cylindrical shape. The channel region 144 may include doped polysilicon or undoped polysilicon. The buried insulating film 146 may fill an inner space of the channel region 144. The buried insulating film 146 may include an insulating material. For example, the buried insulating film 146 may include silicon oxide, silicon nitride, silicon oxynitride, or a combination thereof. In some example embodiments, the buried insulating film 146 may be omitted. In this case, the channel region 144 may have a pillar structure having no inner space.

The drain region 148 may include doped polysilicon. A plurality of drain regions 148 may be insulated from each other by a first upper insulating film UL1. In the memory cell area MEC, the plurality of channel structures 140 and the first upper insulating film UL1 may be covered by a second upper insulating film UL2.

The string select line cut structure SSLC may pass through the first upper insulating film UL1, the second upper insulating film UL2, and a third upper insulating film UL3 in the vertical direction (the Z direction). The upper surface of the string select line cut structure SSLC, the upper surface of the word line cut structure WLC, and the upper surface of the third upper insulating film UL3 may extend at an approximately equal vertical level. A fourth upper insulating film UL4 and a fifth upper insulating film UL5 may be sequentially formed in the stated order on the string select line cut structure SSLC, the word line cut structure WLC, and the third upper insulating film UL3. Each of the first upper insulating film UL1, the second upper insulating film UL2, the third upper insulating film UL3, the fourth upper insulating film UL4, and the fifth upper insulating film UL5 may include an oxide film, a nitride film, or a combination thereof.

As shown in FIGS. 6A and 8, a plurality of bit lines BL may be arranged on the fifth upper insulating film UL5 in the memory cell area MEC of the memory stack structure MST. The plurality of bit lines BL may extend in the second horizontal direction (the Y direction) to be apart from each other. The plurality of channel structures 140 may be respectively connected to the plurality of bit lines BL via a plurality of contact plugs 176, which pass through the second upper insulating film UL2, the third upper insulating film UL3, the fourth upper insulating film UL4, and the fifth upper insulating film UL5.

As shown in FIG. 7, in the connection area CON of the memory stack structure MST, the insulating plate 112 and the second conductive plate 118 may be sequentially stacked in the stated order on the plate common source line 110. The insulating plate 112 may include a multilayer-structure insulating film including a first insulating thin film 112A, a second insulating thin film 112B, and a third insulating thin film 112C, which are sequentially stacked in the stated order on the plate common source line 110. In some example embodiments, the first insulating thin film 112A and the third insulating thin film 112C may each include a silicon oxide film, and the second insulating thin film 112B may include a silicon nitride film.

In the connection area CON, each of the plurality of gate lines 130 may include a gate pad portion 130A having a greater thickness in the vertical direction (the Z direction) than other portions of the gate line 130. The gate pad portion 130A of the gate line 130 may be arranged in an edge portion, which is farthest from the memory cell area MEC, of the gate line 130. Although FIG. 7 illustrates that gate pad portions 130A are arranged only in one-side end portions of some gate lines 130 from among the plurality of gate lines 130, some gate lines 130 not having gate pad portions 130A in the one-side end portions thereof may include gate pad portions 130A in other-side end portions thereof.

In the connection area CON, an edge portion of each of the plurality of gate lines 130 and the plurality of first insulating films 132 may be covered by an interlayer dielectric 138. The interlayer dielectric 138 may include, but is not limited to, a silicon oxide film.

As shown in FIG. 7, a plurality of memory cell contacts MCC may be arranged in the connection area CON. Each of the plurality of memory cell contacts MCC may be arranged in a vertical hole H1 passing through at least some of the interlayer dielectric 138, the plurality of gate lines 130, and the plurality of first insulating films 132. Each of the plurality of memory cell contacts MCC may pass through at least one gate line 130, at least one first insulating film 132, the insulating plug 120, and the conductive landing pad LP in the vertical direction (the Z direction) and may be connected to one wiring layer ML62 selected from the plurality of wiring layers ML60, ML61, and ML62 of the multilayer wiring structure MWS of the peripheral circuit structure PCS.

Each of the plurality of memory cell contacts MCC may be connected to one gate line 130 selected from the plurality of gate lines 130 and may not be connected to other gate lines 130 except for the selected one gate line 130. Each of the plurality of memory cell contacts MCC may be in contact with the gate pad portion 130A of one gate line 130 selected from the plurality of gate lines 130 and may be connected to the selected one gate line 130 via the gate pad portion 130A. The memory cell contact MCC in the vertical hole H1 may be apart from other gate lines 130 except for the selected one gate line 130 in the horizontal direction. An insulating ring 152 may be arranged between the memory cell contact MCC and a gate line 130 not connected to the memory cell contact MCC. In some example embodiments, the insulating ring 152 may include, but is not limited to, a silicon oxide film.

As shown in FIGS. 6A and 7, a plurality of dummy channel structures D140 may be arranged in the connection area CON. Each of the plurality of dummy channel structures D140 may pass through at least some of the interlayer dielectric 138, the plurality of gate lines 130, and the plurality of first insulating films 132. Each of the plurality of dummy channel structures D140 may pass through at least one of the plurality of gate lines 130. Each of the plurality of dummy channel structures D140 may pass through at least one gate line 130, at least one first insulating film 132, the second conductive plate 118, and the insulating plate 112 in the vertical direction (the Z direction) and may pass through a portion of the plate common source line 110 in the vertical direction (the Z direction).

Similar to the channel structure 140, each of the plurality of dummy channel structures D140 may include a gate dielectric film 142, a channel region 144, a buried insulating film 146, and a drain region 148. However, the planar size of each of the plurality of dummy channel structures D140 may be greater than the planar size of the channel structure 140. In some example embodiments, unlike the example shown in FIG. 7, the plurality of dummy channel structures D140 may each include a silicon oxide plug. The number and arrangement shape of dummy channel structures D140, which are shown in FIGS. 6A and 6C, are only examples, and the inventive concepts are not limited thereto. In the connection area CON, the plurality of dummy channel structures D140 may be variously arranged in various positions selected in the memory stack structure MST.

As shown in FIG. 7, in the connection area CON, the interlayer dielectric 138 may be covered by the first upper insulating film UL1. Respective drain regions 148 of the plurality of dummy channel structures D140 may be insulated from each other by the first upper insulating film UL1. In the connection area CON, the plurality of dummy channel structures D140 and the first upper insulating film UL1 may be covered by the second upper insulating film UL2.

As shown in FIGS. 6A and 7, a conductive plate contact 164 may be arranged in the connection area CON. The conductive plate contact 164 may extend in the vertical direction (the Z direction) to the plate common source line 110 through the third upper insulating film UL3, the second upper insulating film UL2, the first upper insulating film UL1, the interlayer dielectric 138, the second conductive plate 118, and the insulating plate 112. The sidewall of the conductive plate contact 164 may be covered by an insulating spacer 162. The fourth upper insulating film UL4 may cover the upper surface of each of the conductive plate contact 164 and the insulating spacer 162.

The plurality of memory cell contacts MCC may pass through the first upper insulating film UL1, the second upper insulating film UL2, the third upper insulating film UL3, and the fourth upper insulating film UL4. The upper surface of each of the plurality of memory cell contacts MCC may be covered by the fifth upper insulating film UL5 and the sixth upper insulating film UL6.

The conductive plate contact 164 may be connected to one upper wiring layer UML from among a plurality of upper wiring layers UML via a contact plug 172 passing through the fourth upper insulating film UL4 and the fifth upper insulating film UL5. The plurality of upper wiring layers UML may be arranged at the same level as that of the plurality of bit lines BL arranged in the memory cell area MEC. A space between each of the plurality of upper wiring layers UML and a space between each of the plurality of bit lines BL may be filled with the sixth upper insulating film UL6. The sixth upper insulating film UL6 may include an oxide film, a nitride film, or a combination thereof.

The plurality of memory cell contacts MCC, the conductive plate contact 164, a plurality of contact plugs 172, and the plurality of upper wiring layers UML may each include tungsten, titanium, tantalum, copper, aluminum, titanium nitride, tantalum nitride, tungsten nitride, or a combination thereof.

In the connection area CON, the plate common source line 110, the insulating plate 112, and the second conductive plate 118 may extend in the horizontal direction to cover the peripheral circuit structure PCS.

Each of the plurality of memory cell contacts MCC may be configured to be connected to at least one peripheral circuit selected from the plurality of peripheral circuits via the multilayer wiring structure MWS of the peripheral circuit structure PCS. Although FIGS. 7 to 11 illustrate an example in which the multilayer wiring structure MWS includes three wiring layers in the vertical direction (the Z direction), the inventive concepts are not limited to the example shown in FIGS. 7 to 11. For example, the multilayer wiring structure MWS may include two wiring layers or four or more wiring layers.

Each of the plurality of wiring layers ML60, ML61, and ML62 and the plurality of contacts MC60, MC61, and MC62 may include metal, conductive metal nitride, metal silicide, or a combination thereof. For example, each of the plurality of wiring layers ML60, ML61, and ML62 and the plurality of contacts MC60, MC61, and MC62 may include conductive material, such as tungsten, molybdenum, titanium, cobalt, tantalum, nickel, tungsten silicide, titanium silicide, cobalt silicide, tantalum silicide, or nickel silicide.

Although FIG. 6A illustrates a configuration in which the plurality of memory cell contacts MCC are arranged in a line along a straight line in the first horizontal direction (the X direction), the inventive concepts are not limited thereto. A planar placement structure of each of the plurality of memory cell contacts MCC may be variously selected without departing from the scope of the inventive concepts.

As shown in FIGS. 6B, 9, 10, and 11, the through-electrode region TA1 may include a first through-electrode portion TA11, a second through-electrode portion TA12, and a third through-electrode portion TA13, which are arranged at different positions in the first horizontal direction (the X direction) and have different configurations. The first through-electrode portion TA11 may be arranged at a position (referred to as the memory cell area MEC, hereinafter) facing the memory cell area MEC adjacent thereto in the second horizontal direction (the Y direction). Each of the second through-electrode portion TA12 and the third through-electrode portion TA13 may be arranged at a position (referred to as the connection area CON, hereinafter) facing the connection area CON adjacent thereto in the second horizontal direction (the Y direction).

According to some example embodiments, the first through-electrode portion TA11 arranged in the memory cell area MEC as shown in FIG. 9 may be omitted from the through-electrode region TA1. According to some example embodiments, one of the second through-electrode portion TA12, which is arranged at a first position in the connection area CON as shown in FIG. 10, and the third through-electrode portion TA13, which is arranged at a second position in the connection area CON as shown in FIG. 11, may be omitted from the through-electrode region TA1. According to some example embodiments, it is sufficient for the semiconductor device 100 to include only one of the second through-electrode portion TA12, which is arranged at the first position in the connection area CON as shown in FIG. 10, or the third through-electrode portion TA13, which is arranged at the second position in the connection area CON as shown in FIG. 11, from among the components of the through-electrode region TA1. As used herein, the terms “first position” and “second position” may refer to different regions apart from each other in the first horizontal direction (the X direction) as shown in FIG. 6B, or different regions apart from each other in the second horizontal direction (the Y direction).

The through-electrode region TA1 may include an insulating structure INS arranged on the insulating plug 120 in the memory cell area MEC and the connection area CON, and a plurality of through-electrodes THV passing through the insulating structure INS in the vertical direction (the Z direction).

Each of the plurality of through-electrodes THV may be configured to pass through the insulating structure INS, the insulating plug 120, and the conductive landing pad LP in the vertical direction (the Z direction) and to be connected to one circuit selected from the plurality of circuits in the multilayer wiring structure MWS of the peripheral circuit structure PCS. For example, some through-electrodes THV from among the plurality of through-electrodes THV may be configured to be connected to the page buffer 34 (see FIG. 1) of the peripheral circuit structure PCS. Some other through-electrodes THV from among the plurality of through-electrodes THV may be configured to be connected to the row decoder 32 (see FIG. 1) of the peripheral circuit structure PCS. Yet some other through-electrodes THV from among the plurality of through-electrodes THV may be configured to be connected to the common source driver 39 (see FIG. 1) of the peripheral circuit structure PCS. Yet some other through-electrodes THV from among the plurality of through-electrodes THV may be configured to be connected to a pass circuit that is included in the peripheral circuit structure PCS and includes a plurality of pass transistors. However, the inventive concepts are not limited to the examples set forth above, and various modifications and changes may be made thereto without departing from the scope of the inventive concepts.

In the memory cell area MEC, the upper surface of the insulating structure INS of the through-electrode region TA1 may be in contact with the first upper insulating film UL1, as shown in FIG. 9, and in the connection area CON, the upper surface of the insulating structure INS of the through-electrode region TA1 may be covered by the interlayer dielectric 138, as shown in FIGS. 10 and 11. In the connection area CON, the upper surface of the insulating structure INS of the through-electrode region TA1 may be in contact with the interlayer dielectric 138.

The insulating structure INS may include a plurality of first insulating films 132 and a plurality of second insulating films 134, which are alternately stacked one-by-one in the vertical direction (the Z direction), in each of the memory cell area MEC and the connection area CON, and a plurality of third insulating films 134R, which are in contact with an upper second insulating film 134 adjacent to the interlayer dielectric 138 from among the plurality of second insulating films 134, in the connection area CON. As shown in FIGS. 10 and 11, in the second through-electrode portion TA12 and the third through-electrode portion TA13 of the through-electrode region TA1, which are in the connection area CON, a third insulating film 134R may be arranged between the upper second insulating film 134 adjacent to the interlayer dielectric 138, among the plurality of second insulating films 134, and the interlayer dielectric 138 and may be in contact with each of the upper second insulating film 134 and the interlayer dielectric 138. In the second through-electrode portion TA12 and the third through-electrode portion TA13, at least one through-electrode THV selected from the plurality of through-electrodes THV may pass through the third insulating film 134R in the vertical direction (the Z direction).

As shown in FIG. 9, in the memory cell area MEC, an upper surface US1 of the insulating structure INS of the through-electrode region TA1 may extend flat in the horizontal direction (the X-Y plane in FIG. 9) while maintained at a constant vertical level LVIT. As used herein, the term “vertical level” refers to a distance in the vertical direction (the Z direction) from the upper surface of the insulating plug 120, which faces the insulating structure INS.

As shown in FIGS. 10 and 11, in the connection area CON, the upper surface of the insulating structure INS of the through-electrode region TA1 may have a varying height in the vertical direction (the Z direction) along with each of the first horizontal direction (the X direction) and the second horizontal direction (the Y direction). For example, as shown in FIG. 10, in the second through-electrode portion TA12 of the through-electrode region TA1, an upper surface US2 of the second insulating film 134, which forms the upper surface of the insulating structure INS, may be closer to the substrate 52 of the peripheral circuit structure PCS in the vertical direction (the Z direction) than an upper surface US3 of the third insulating film 134R, which forms the upper surface of the insulating structure INS. As shown in FIG. 11, in the third through-electrode portion TA13 of the through-electrode region TA1, an upper surface US4 of the second insulating film 134, which forms the upper surface of the insulating structure INS, may be closer to the substrate 52 of the peripheral circuit structure PCS in the vertical direction (the Z direction) than an upper surface US5 of the third insulating film 134R, which forms the upper surface of the insulating structure INS. Each of the upper surface US2 of the second insulating film 134 and the upper surface US3 of the third insulating film 134R, which each form the upper surface of the insulating structure INS in the second through-electrode portion TA12 shown in FIG. 10, may be farther from the substrate 52 of the peripheral circuit structure PCS in the vertical direction (the Z direction) than each of the upper surface US4 of the second insulating film 134 and the upper surface US5 of the third insulating film 134R, which each form the upper surface of the insulating structure INS in the third through-electrode portion TA13 shown in FIG. 11.

The respective vertical levels of the plurality of third insulating films 134R arranged in the through-electrode region TA1 may be different depending on the positions thereof in the first horizontal direction (the X direction). The plurality of third insulating films 134R in the through-electrode region TA1 may be respectively arranged at vertical levels that are closer to the substrate 52 of the peripheral circuit structure PCS as the distance from the memory cell area MEC in the first horizontal direction (the X direction) increases. For example, the vertical level of the third insulating film 134R of the second through-electrode portion TA12 may be higher in the vertical direction (the Z direction) from the substrate 52 of the peripheral circuit structure PCS than the vertical level of the third insulating film 134R of the third through-electrode portion TA13.

As shown in FIGS. 10 and 11, because the upper surface of the insulating structure INS of the through-electrode region TA1 in the connection area CON has a varying height in the vertical direction (the Z direction) along with each of the first horizontal direction (the X direction) and the second horizontal direction (the Y direction), the lower surface of the interlayer dielectric 138, which is in contact with the upper surface of the insulating structure INS of the through-electrode region TA1 in the connection area CON, may have a plurality of stepped portions corresponding to the varying height of the upper surface of the insulating structure INS.

In some example embodiments, the first insulating film 132, the second insulating film 134, and the third insulating film 134R may respectively include different materials. For example, the first insulating film 132 may include a silicon oxide film, and each of the second insulating film 134 and the third insulating film 134R may include a silicon nitride film or a hydrogenated silicon nitride film, wherein at least one of a first condition that a content ratio of silicon atoms (Si) in the third insulating film 134R is less than a content ratio of silicon atoms (Si) in the second insulating film 134, a second condition that a content ratio of nitrogen atoms (N) in the third insulating film 134R is greater than a content ratio of nitrogen atoms (N) in the second insulating film 134, or a third condition that a content ratio of hydrogen atoms (H) in the third insulating film 134R is greater than a content ratio of hydrogen atoms (H) in the second insulating film 134 may be satisfied.

When the first condition is satisfied, the content ratio of nitrogen atoms (N) in the third insulating film 134R may be equal to or greater than the content ratio of nitrogen atoms (N) in the second insulating film 134, and the content ratio of hydrogen atoms (H) in the third insulating film 134R may be equal to or greater than the content ratio of hydrogen atoms (H) in the second insulating film 134. When the second condition is satisfied, the content ratio of silicon atoms (Si) in the third insulating film 134R may be equal to or less than the content ratio of silicon atoms (Si) in the second insulating film 134, and the content ratio of hydrogen atoms (H) in the third insulating film 134R may be equal to or greater than the content ratio of hydrogen atoms (H) in the second insulating film 134. When the third condition is satisfied, the content ratio of silicon atoms (Si) in the third insulating film 134R may be equal to or less than the content ratio of silicon atoms (Si) in the second insulating film 134, and the content ratio of nitrogen atoms (N) in the third insulating film 134R may be equal to or greater than the content ratio of nitrogen atoms (N) in the second insulating film 134.

In some example embodiments, the first insulating film 132 may include a different material from a constituent material of each of the second insulating film 134 and the third insulating film 134R, and the second insulating film 134 and the third insulating film 134R may include the same material. For example, the first insulating film 132 may include a silicon oxide film, and each of the second insulating film 134 and the third insulating film 134R may include the same material selected from a silicon nitride film and a hydrogenated silicon nitride film. Here, the content ratio of silicon atoms (Si) and the content ratio of nitrogen atoms (N) may each be equal between the second insulating film 134 and the third insulating film 134R.

As shown in FIGS. 9 to 11, a word line cut structure WLC may be arranged on both sides of the through-electrode region TA1 in terms of the second horizontal direction (the Y direction). The through-electrode region TA1 may include a plurality of dummy conductive layers 130D between the word line cut structure WLC and the insulating structure INS. Each of the plurality of dummy conductive layers 130D may be in contact with the word line cut structure WLC adjacent thereto. Each of the plurality of dummy conductive layers 130D may be arranged between the word line cut structure WLC and the insulating structure INS. Each of the plurality of dummy conductive layers 130D may be arranged at the same vertical level as that of a corresponding one gate line 130 selected from the plurality of gate lines 130 arranged in the memory cell area MEC. Each of the plurality of dummy conductive layers 130D may include the same material as the constituent material of each of the plurality of gate lines 130.

The plurality of dummy conductive layers 130D may include a group of dummy conductive layers 130D contacting one word line cut structure WLC and arranged in a line in the vertical direction (the Z direction). A plurality of dummy conductive layers 130D, which are included in the group of dummy conductive layers 130D, may be apart from each other the vertical direction (the Z direction). In the group of dummy conductive layers 130D, each of the plurality of dummy conductive layers 130D may be arranged at the same vertical level as that of a corresponding one gate line 130 selected from the plurality of gate lines 130 arranged in the memory cell area MEC.

As shown in FIG. 9, in the first through-electrode portion TA11 arranged in the memory cell area MEC, the respective thicknesses of the group of dummy conductive layers 130D in the vertical direction (the Z direction) may be equal or similar to each other. One sidewall out of both sidewalls, in terms of the second horizontal direction (the Y direction), of each of the plurality of dummy conductive layers 130D in the group of dummy conductive layers 130D may be in contact with the word line cut structure WLC, and the other one sidewall may be in contact with the second insulating film 134. In some example embodiments, the respective widths of the plurality of dummy conductive layers 130D, which are included in the group of dummy conductive layers 130D, in the second horizontal direction (the Y direction) may be equal or similar to each other. In some example embodiments, the respective widths of at least some of the plurality of dummy conductive layers 130D, which are included in the group of dummy conductive layers 130D, in the second horizontal direction (the Y direction) may be different. In some example embodiments, the width of each of the plurality of dummy conductive layers 130D, which are included in the group of dummy conductive layers 130D, in the second horizontal direction (the Y direction) may be greater than that shown in FIG. 9. In this case, a separation distance between each of the plurality of dummy conductive layers 130D and the through-electrode THV may be less than that shown in FIG. 9.

As shown in FIGS. 10 and 11, in the second through-electrode portion TA12 and the third through-electrode portion TA13, which are arranged in the connection area CON, an upper dummy conductive layer 130D farthest from the peripheral circuit structure PCS, among the plurality of dummy conductive layers 130D in the group of dummy conductive layers 130D, may have a thickness greater in the vertical direction (the Z direction) than the other dummy conductive layers 130D. In the second through-electrode portion TA12 and the third through-electrode portion TA13, upper dummy conductive layers 130D farthest from the peripheral circuit structure PCS, in the group of dummy conductive layers 130D, may each be arranged at the same vertical level as that of one gate pad portion 130A selected from the plurality of gate pad portions 130A arranged in the memory cell area MEC.

In the second through-electrode portion TA12 shown in FIG. 10, one sidewall out of both sidewalls, in terms of the second horizontal direction (the Y direction), of the upper dummy conductive layer 130D from among the plurality of dummy conductive layers 130D in the group of dummy conductive layers 130D may be in contact with the word line cut structure WLC, and the other one sidewall may be in contact with the interlayer dielectric 138. In the second through-electrode portion TA12, one sidewall out of both sidewalls, in terms of the second horizontal direction (the Y direction), of each of the remaining dummy conductive layers 130D except for the upper dummy conductive layer 130D from among the plurality of dummy conductive layers 130D in the group of dummy conductive layers 130D may be in contact with the word line cut structure WLC, and the other one sidewall may be in contact with the second insulating film 134. In the second through-electrode portion TA12, the respective widths of the plurality of dummy conductive layers 130D, which are included in the group of dummy conductive layers 130D, in the second horizontal direction (the Y direction) may be equal or similar to each other.

In the third through-electrode portion TA13 shown in FIG. 11, one sidewall out of both sidewalls, in terms of the second horizontal direction (the Y direction), of the upper dummy conductive layer 130D from among the plurality of dummy conductive layers 130D in the group of dummy conductive layers 130D may be in contact with the word line cut structure WLC, and the other one sidewall may be in contact with the interlayer dielectric 138 and the second insulating film 134. In the third through-electrode portion TA13, one sidewall out of both sidewalls, in terms of the second horizontal direction (the Y direction), of each of the remaining dummy conductive layers 130D except for the upper dummy conductive layer 130D from among the plurality of dummy conductive layers 130D in the group of dummy conductive layers 130D may be in contact with the word line cut structure WLC, and the other one sidewall may be in contact with the second insulating film 134. In the third through-electrode portion TA13, the respective widths of the plurality of dummy conductive layers 130D, which are included in the group of dummy conductive layers 130D, in the second horizontal direction (the Y direction) may vary with the respective positions of the plurality of dummy conductive layers 130D. For example, as shown in FIG. 11, a portion of the upper dummy conductive layer U1 farthest from the peripheral circuit structure PCS in the vertical direction (the Z direction), among the plurality of dummy conductive layers 130D in the group of dummy conductive layers 130D, may extend longer toward the through-electrode THV in the second horizontal direction (the Y direction) than the other dummy conductive layers 130D. As shown in FIG. 11, an end portion E1 of the upper dummy conductive layer U1 may overlap the third insulating film 134R of the insulating structure INS in the vertical direction (the Z direction), but the inventive concepts are not limited thereto.

As shown in FIG. 10, in the second through-electrode portion TA12 of the through-electrode region TA1, among a first group of dummy conductive layers 130D arranged in a line in the vertical direction (the Z direction), each of the remaining dummy conductive layers 130D except for the upper dummy conductive layer 130D farthest from the peripheral circuit structure PCS may be arranged at the same vertical level as that of one second insulating film 134 selected from the plurality of second insulating films 134 of the insulating structure INS. In the second through-electrode portion TA12 of the through-electrode region TA1, a vertical level LV1A of the upper surface US3 of the third insulating film 134R corresponding to a local region of the insulating structure INS, which is pierced in the vertical direction (the Z direction) by the through-electrode THV, may be closer to the peripheral circuit structure PCS than a vertical level LV1B of an upper surface 130DT of the upper dummy conductive layer 130D farthest from the peripheral circuit structure PCS, among the plurality of dummy conductive layers 130D in the second through-electrode portion TA12.

As shown in FIG. 11, in the third through-electrode portion TA13 of the through-electrode region TA1, a second group of dummy conductive layers 130D arranged in a line in the vertical direction (the Z direction) may each be arranged at the same vertical level as that of a corresponding one second insulating film 134 selected from the plurality of second insulating films 134 of the insulating structure INS. In the third through-electrode portion TA13 of the through-electrode region TA1, a vertical level LV1C of the upper surface US5 of the third insulating film 134R corresponding to a local region of the insulating structure INS, which is pierced in the vertical direction (the Z direction) by the through-electrode THV, may be farther from the peripheral circuit structure PCS than a vertical level LV1D of the upper surface 130DT of the upper dummy conductive layer 130D farthest from the peripheral circuit structure PCS, among the second group of dummy conductive layers 130D.

As shown in FIG. 9, in the first through-electrode portion TA11 of the through-electrode region TA1, the upper surface US1 of the insulating structure INS may be covered by the first upper insulating film UL1, the second upper insulating film UL2, the third upper insulating film UL3, the fourth upper insulating film UL4, the fifth upper insulating film UL5, and the sixth upper insulating film UL6. The second upper insulating film UL2, the third upper insulating film UL3, the fourth upper insulating film UL4, the fifth upper insulating film UL5, and the sixth upper insulating film UL6 may be stacked in the stated order on the first upper insulating film UL1.

As shown in FIGS. 10 and 11, in each of the second through-electrode portion TA12 and the third through-electrode portion TA13 of the through-electrode region TA1, the upper surfaces US2 and US3 of the insulating structure INS may be covered by the interlayer dielectric 138, and the first upper insulating film UL1, the second upper insulating film UL2, the third upper insulating film UL3, the fourth upper insulating film UL4, the fifth upper insulating film UL5, and the sixth upper insulating film UL6 may be stacked in the stated order on the interlayer dielectric 138.

As shown in FIGS. 9 to 11, in each of the first through-electrode portion TA11, the second through-electrode portion TA12, and the third through-electrode portion TA13 of the through-electrode region TA1, each of the plurality of through-electrodes THV may pass through the first upper insulating film UL1, the second upper insulating film UL2, the third upper insulating film UL3, and the fourth upper insulating film UL4. Each of the plurality of through-electrodes THV may be connected to one upper wiring layer UML from among a plurality of upper wiring layers UML via a contact plug 172 passing through the fifth upper insulating film UL5.

The semiconductor device 100 described with reference to FIGS. 1 to 11 has a structure capable of securing the structural stability of the insulating structure INS, which surrounds the plurality of through-electrodes THV, and securing stable insulating distances between the plurality of through-electrodes THV and other conductive regions around the plurality of through-electrodes THV, even without arranging a separate dam structure around the through-electrode region TA1, in which the plurality of through-electrodes THV are arranged, in order to secure an insulating distance of an insulating structure. Therefore, in the process of manufacturing the semiconductor device 100 according to the above example embodiments, by omitting structures such as dam structures, which may generate structural defects such as cracks, the area of the through-electrode region TA1, in which the plurality of through-electrodes THV are arranged, may be sufficiently secured, and a structure improving the degree of integration may be provided. In addition, in the semiconductor device 100 including a plurality of memory cells that are 3-dimensionally arranged, even when the height of the cell array structure CAS in the vertical direction (the Z direction) is increased due to an increase in the number of stacked gate lines 130 to improve the degree of integration, the cell array structure CAS may be mitigated or prevented from suffering from leaning or collapse, thereby suppressing process defects and improving reliability in the manufacturing process of the semiconductor device 100.

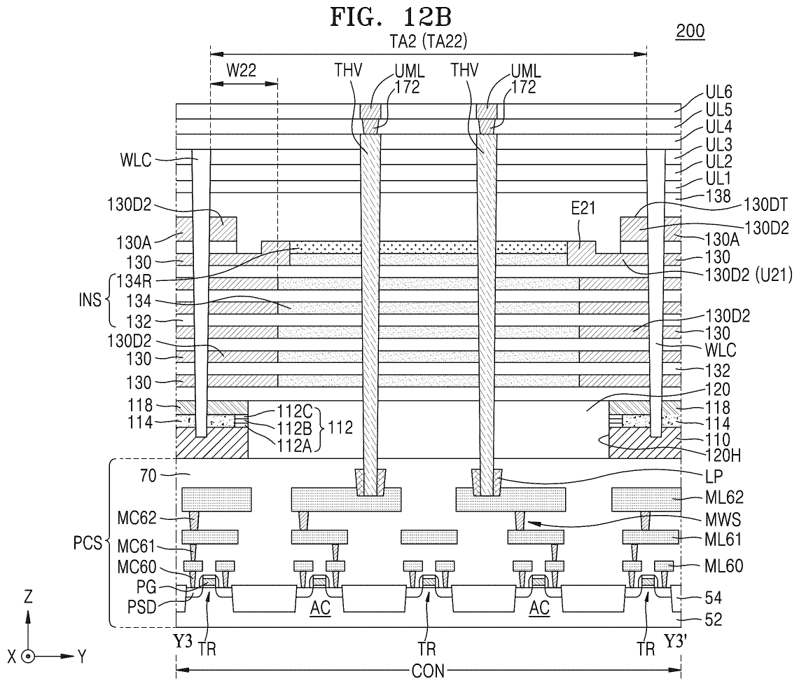

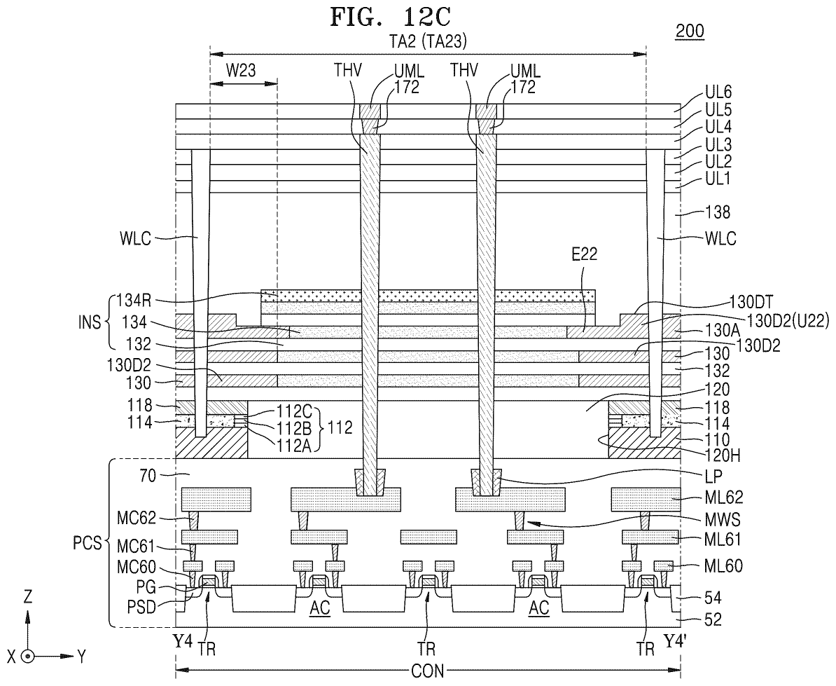

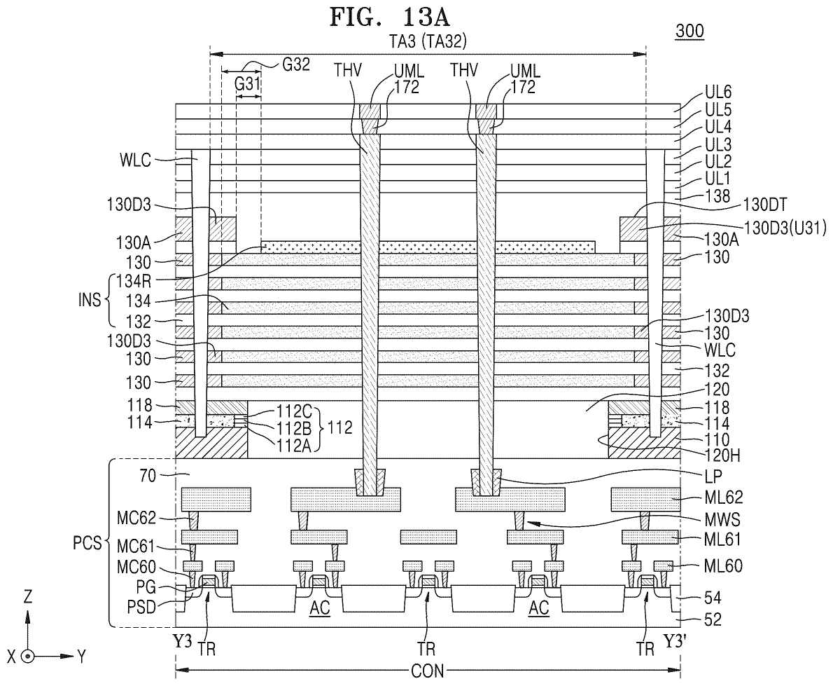

FIGS. 12A, 12B, and 12C are cross-sectional views illustrating a semiconductor device 200 according to an example embodiment. In FIGS. 12A, 12B, and 12C, the same reference numerals as in FIGS. 1 to 11 denote the same members, respectively, and here, repeated descriptions thereof are omitted.

Referring to FIGS. 12A, 12B, and 12C, the semiconductor device 200 has substantially the same configuration as the semiconductor device 100 described with reference to FIGS. 1 to 11. However, the semiconductor device 200 may include a through-electrode region TA2. The through-electrode region TA2 may have substantially the same configuration as the through-electrode region TA1 described with reference to FIGS. 6B and 9 to 11. However, the through-electrode region TA2 may include a plurality of dummy conductive layers 130D2 between the word line cut structure WLC and the insulating structure INS. Each of the plurality of dummy conductive layers 130D2 may be in contact with the word line cut structure WLC adjacent thereto. The plurality of dummy conductive layers 130D2 may have substantially the same configuration as the plurality of dummy conductive layers 130D described with reference to FIGS. 9 to 11. The plurality of dummy conductive layers 130D2 may include a group of dummy conductive layers 130D2 contacting one word line cut structure WLC and arranged in a line in the vertical direction (the Z direction). A plurality of dummy conductive layers 130D2, which are included in the group of dummy conductive layers 130D2, may be apart from each other in the vertical direction (the Z direction). In the group of dummy conductive layers 130D2, each of the plurality of dummy conductive layers 130D2 may be arranged at the same vertical level as that of a corresponding one gate line 130 selected from the plurality of gate lines 130 arranged in the memory cell area MEC. The respective widths of the plurality of dummy conductive layers 130D2, which are included in the group of dummy conductive layers 130D2, in the second horizontal direction (the Y direction) may vary with the respective positions of the plurality of dummy conductive layers 130D2 in the vertical direction (the Z direction).

As shown in FIG. 12A, in a first through-electrode portion TA21, which is arranged in the memory cell area MEC, of the through-electrode region TA2, the respective thicknesses of the group of dummy conductive layers 130D2 in the vertical direction (the Z direction) may be equal or similar to each other. In addition, in the first through-electrode portion TA21, respective widths WS21 of the group of dummy conductive layers 130D2 in the second horizontal direction (the Y direction) may be equal or similar to each other. In some example embodiments, the width WS21 of each of the group of dummy conductive layers 130D2 in the second horizontal direction (the Y direction) may be equal to or greater than about ½ of the pitch of the plurality of word line cut structures WLC in the second horizontal direction (the Y direction). In some example embodiments, when the plurality of separation cut structures HLC are arranged in the memory cell block BLK, as shown in FIGS. 4 and 6C, the width WS21 of each of the group of dummy conductive layers 130D2 in the second horizontal direction (the Y direction) may be equal to or greater than about ½ of the pitch of cut structures in the second horizontal direction (the Y direction), the cut structures including the word line cut structure WLC and the separation cut structure HLC adjacent thereto. In the first through-electrode portion TA21, one sidewall out of both sidewalls, in terms of the second horizontal direction (the Y direction), of each of the plurality of dummy conductive layers 130D2 in the group of dummy conductive layers 130D2 may be in contact with the word line cut structure WLC, and the other one sidewall may be in contact with the second insulating film 134.

As shown in FIGS. 12B and 12C, in a second through-electrode portion TA22 and a third through-electrode portion TA23, which are arranged in the connection area CON, an upper dummy conductive layer 130D2 farthest from the peripheral circuit structure PCS in the vertical direction (the Z direction), among the plurality of dummy conductive layers 130D2 in the group of dummy conductive layers 130D2, may have a thickness greater in the vertical direction (the Z direction) than the other dummy conductive layers 130D2. In the second through-electrode portion TA22 shown in FIG. 12B, a first dummy conductive layer U21, which is arranged in the same vertical level as the second insulating film 134 contacting the lower surface of the third insulating film 134R, among the plurality of dummy conductive layers 130D2 in the group of dummy conductive layers 130D2, may extend longer toward the through-electrode THV in the second horizontal direction (the Y direction) than the other dummy conductive layers 130D2. The first dummy conductive layer U21 may include an end portion E21 contacting the third insulating film 134R. The end portion E21 of the first dummy conductive layer U21, which is in contact with the third insulating film 134R, may have a thickness greater in the vertical direction (the Z direction) than the other portions of the first dummy conductive layer U21. A width W22, in the second horizontal direction (the Y direction), of the dummy conductive layer 130D2 closer to the peripheral circuit structure PCS than the first dummy conductive layer U21, among the plurality of dummy conductive layers 130D2, may be equal or similar to the width W21, in the second horizontal direction (the Y direction), of the dummy conductive layer 130D2 arranged in the first through-electrode portion TA21 shown in FIG. 12A.

In the third through-electrode portion TA23 shown in FIG. 12C, an upper dummy conductive layer U22 farthest from the peripheral circuit structure PCS in the vertical direction (the Z direction), among the plurality of dummy conductive layers 130D2 in the group of dummy conductive layers 130D2, may have a thickness greater in the vertical direction (the Z direction) than the other dummy conductive layers 130D2. A portion of the upper dummy conductive layer U22 may extend longer toward the through-electrode THV in the second horizontal direction (the Y direction) than the other dummy conductive layers 130D2. As shown in FIG. 12C, an end portion E22 of the upper dummy conductive layer U22 may overlap the third insulating film 134R of the insulating structure INS in the vertical direction (the Z direction), but the inventive concepts are not limited thereto. The respective widths of the other dummy conductive layers 130D2 except for the upper dummy conductive layer U22, in the second horizontal direction (the Y direction), may be equal or similar to each other. A width W23, in the second horizontal direction (the Y direction), of the dummy conductive layer 130D2 closer to the peripheral circuit structure PCS than the upper dummy conductive layer U22, among the plurality of dummy conductive layers 130D2, may be equal or similar to the width W21, in the second horizontal direction (the Y direction), of the dummy conductive layer 130D2 arranged in the first through-electrode portion TA21 shown in FIG. 12A. The dummy conductive layer 130D2 closer to the peripheral circuit structure PCS than the upper dummy conductive layer U22, among the plurality of dummy conductive layers 130D2, may include a portion overlapping the third insulating film 134R of the insulating structure INS in the vertical direction (the Z direction), but the inventive concepts are not limited thereto. A more detailed configuration of the group of dummy conductive layers 130D2 may be substantially the same as that of the group of dummy conductive layers 130D described with reference to FIGS. 9 to 11.

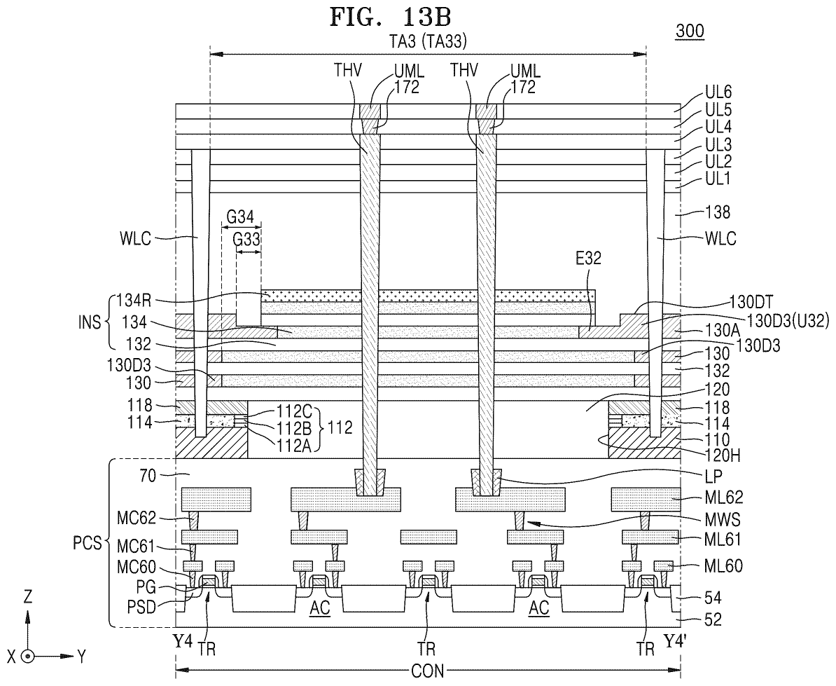

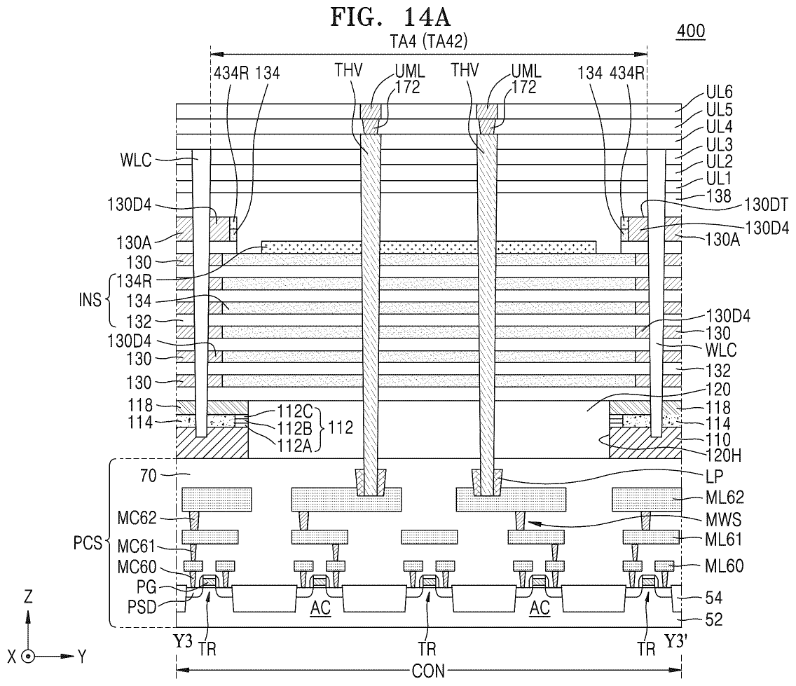

FIGS. 13A and 13B are cross-sectional views illustrating a semiconductor device 300 according to an example embodiment. In FIGS. 13A and 13B, the same reference numerals as in FIGS. 1 to 11 denote the same members, respectively, and here, repeated descriptions thereof are omitted.

Referring to FIGS. 13A and 13B, the semiconductor device 300 has substantially the same configuration as the semiconductor device 100 described with reference to FIGS. 1 to 11. However, the semiconductor device 300 may include a through-electrode region TA3. The through-electrode region TA3 may have substantially the same configuration as the through-electrode region TA1 described with reference to FIGS. 6B and 9 to 11. However, the through-electrode region TA3 may include a plurality of dummy conductive layers 130D3 between the word line cut structure WLC and the insulating structure INS. Each of the plurality of dummy conductive layers 130D3 may be in contact with the word line cut structure WLC adjacent thereto. The plurality of dummy conductive layers 130D3 may have substantially the same configuration as the plurality of dummy conductive layers 130D described with reference to FIGS. 9 to 11. The plurality of dummy conductive layers 130D3 may include a group of dummy conductive layers 130D3 contacting one word line cut structure WLC and arranged in a line in the vertical direction (the Z direction). A plurality of dummy conductive layers 130D3, which are included in the group of dummy conductive layers 130D3, may be apart from each other in the vertical direction (the Z direction). In the group of dummy conductive layers 130D3, each of the plurality of dummy conductive layers 130D3 may be arranged at the same vertical level as that of a corresponding one gate line 130 selected from the plurality of gate lines 130 arranged in the memory cell area MEC. The respective widths of the plurality of dummy conductive layers 130D3, which are included in the group of dummy conductive layers 130D3, in the second horizontal direction (the Y direction) may vary with the respective thicknesses of the plurality of dummy conductive layers 130D3 in the vertical direction (the Z direction).

As shown in FIGS. 13A and 13B, in a second through-electrode portion TA32 and a third through-electrode portion TA33, which are arranged in the connection area CON, an upper dummy conductive layer U31 or U32 farthest from the peripheral circuit structure PCS, among the plurality of dummy conductive layers 130D3 that are included in the group of dummy conductive layers 130D3 contacting one word line cut structure WLC and arranged in a line in the vertical direction (the Z direction), may have a thickness greater in the vertical direction (the Z direction) than the other dummy conductive layers 130D3. In the second through-electrode portion TA32 and the third through-electrode portion TA33, the respective widths, in the second horizontal direction (the Y direction), of the other dummy conductive layers 130D3 except for the upper dummy conductive layer U31 or U32, among the plurality of dummy conductive layers 130D3 in the group of dummy conductive layers 130D3, may be equal or similar to each other and may be less than the width of the upper dummy conductive layer U31 or U32 in the second horizontal direction (the Y direction).

As shown in FIG. 13A a separation distance G31 in the second horizontal direction (the Y direction) between the third insulating film 134R and the upper dummy conductive layer U31 in the group of dummy conductive layers 130D3 in the second through-electrode portion TA32 may be less than a separation distance G32 in the second horizontal direction (the Y direction) between the third insulating film 134R and each of the other dummy conductive layers 130D3 except for the upper dummy conductive layer U31 in the group of dummy conductive layers 130D3.

As shown in FIG. 13B, in the third through-electrode portion TA33, the respective widths of the plurality of dummy conductive layers 130D3, which are included in the group of dummy conductive layers 130D3, in the second horizontal direction (the Y direction) may vary with the respective positions of the plurality of dummy conductive layers 130D3. For example, a portion of the upper dummy conductive layer U32 farthest from the peripheral circuit structure PCS in the vertical direction (the Z direction), among the plurality of dummy conductive layers 130D3 in the group of dummy conductive layers 130D3, may extend longer toward the through-electrode THV in the second horizontal direction (the Y direction) than the other dummy conductive layers 130D3. An end portion E32 of the upper dummy conductive layer U32 may overlap the third insulating film 134R of the insulating structure INS in the vertical direction (the Z direction), but the inventive concepts are not limited thereto.

As shown in FIG. 13B, a separation distance G33 in the second horizontal direction (the Y direction) between the third insulating film 134R and a portion of the upper dummy conductive layer U32 in the group of dummy conductive layers 130D3 in the third through-electrode portion TA33 may be less than a separation distance G34 in the second horizontal direction (the Y direction) between the third insulating film 134R and each of the other dummy conductive layers 130D3 except for the upper dummy conductive layer U32 in the group of dummy conductive layers 130D3.

A more detailed configuration of the group of dummy conductive layers 130D3 is substantially the same as that of the group of dummy conductive layers 130D described with reference to FIGS. 9 to 11.

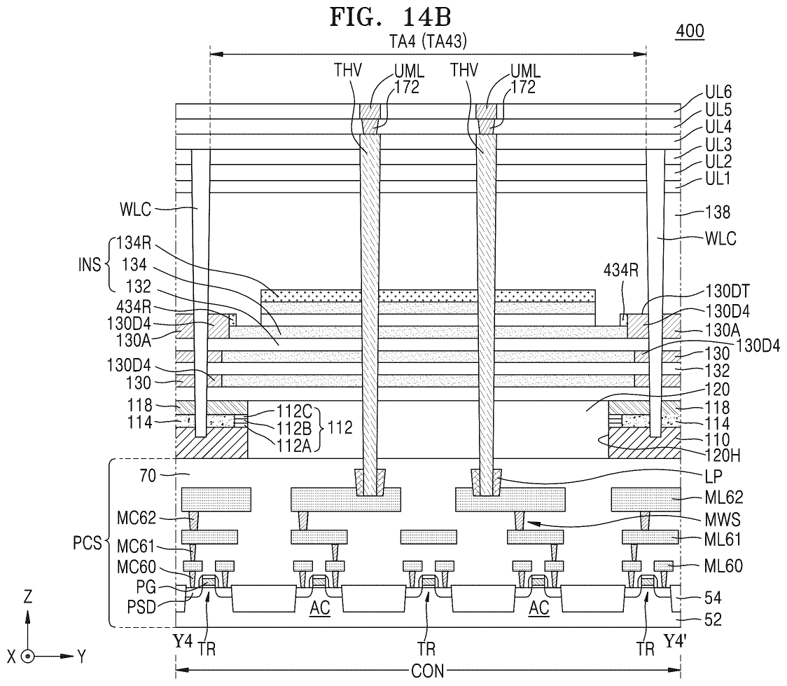

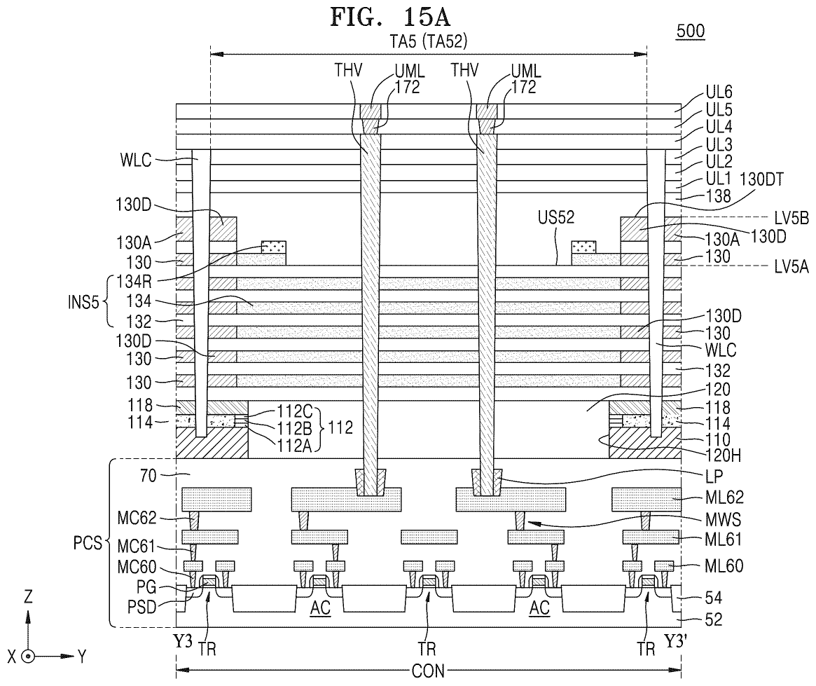

FIGS. 14A and 14B are cross-sectional views illustrating a semiconductor device 400 according to an example embodiment. In FIGS. 14A and 14B, the same reference numerals as in FIGS. 1 to 13B denote the same members, respectively, and here, repeated descriptions thereof are omitted.

Referring to FIGS. 14A and 14B, the semiconductor device 400 has substantially the same configuration as the semiconductor device 300 described with reference to FIGS. 13A and 13B. However, the semiconductor device 400 may include a through-electrode region TA4. The through-electrode region TA4 may have substantially the same configuration as the through-electrode region TA1 described with reference to FIGS. 6B and 9 to 11. However, the through-electrode region TA4 may include a plurality of dummy conductive layers 130D4 between the word line cut structure WLC and the insulating structure INS. Each of the plurality of dummy conductive layers 130D4 may be in contact with the word line cut structure WLC adjacent thereto. The plurality of dummy conductive layers 130D4 may have substantially the same configuration as the plurality of dummy conductive layers 130D described with reference to FIGS. 9 to 11. The plurality of dummy conductive layers 130D4 may include a group of dummy conductive layers 130D4 contacting one word line cut structure WLC and arranged in a line in the vertical direction (the Z direction). A plurality of dummy conductive layers 130D4, which are included in the group of dummy conductive layers 130D4, may be apart from each other in the vertical direction (the Z direction). In the group of dummy conductive layers 130D4, each of the plurality of dummy conductive layers 130D4 may be arranged at the same vertical level as that of a corresponding one gate line 130 selected from the plurality of gate lines 130 arranged in the memory cell area MEC. The respective widths of the plurality of dummy conductive layers 130D4, which are included in the group of dummy conductive layers 130D4, in the second horizontal direction (the Y direction) may be substantially equal or similar to each other.

As shown in FIGS. 14A and 14B, in a second through-electrode portion TA42 and a third through-electrode portion TA43 of the through-electrode region TA4, which are arranged in the connection area CON, an upper dummy conductive layer 130D4 farthest from the peripheral circuit structure PCS, among the plurality of dummy conductive layers 130D4 in the group of dummy conductive layers 130D4, may have a thickness greater in the vertical direction (the Z direction) than the other dummy conductive layers 130D4.

The semiconductor device 400 may further include an additional third insulating film 434R, which is in contact with the upper dummy conductive layer 130D4 of the group of dummy conductive layers 130D4, in the second through-electrode portion TA42 and the third through-electrode portion TA43 of the through-electrode region TA4, which are arranged in the connection area CON. The additional third insulating film 434R may be arranged outside a local region in which the third insulating film 134R pierced in the vertical direction (the Z direction) by the through-electrode THV is arranged. The additional third insulating film 434R may be apart from the third insulating film 134R with the interlayer dielectric 138 therebetween. The additional third insulating film 434R may be apart from the plurality of through-electrodes THV in the second horizontal direction (the Y direction). In the second horizontal direction (the Y direction), a separation distance between the additional third insulating film 434R and the plurality of through-electrodes THV may be greater than a separation distance between the additional third insulating film 434R and the third insulating film 134R that is arranged in the local region. In the second horizontal direction (the Y direction), the width of the additional third insulating film 434R may be less than the width of the third insulating film 134R arranged in the local region. A constituent material of the additional third insulating film 434R may be substantially the same as the constituent material of the third insulating film 134R arranged in the local region and described above. For example, the additional third insulating film 434R and the third insulating film 134R arranged in the local region may include the same material selected from a silicon nitride film and a hydrogenated silicon nitride film, and the content ratio of silicon atoms (Si) and the content ratio of nitrogen atoms (N) each may be equal between the additional third insulating film 434R and the third insulating film 134R arranged in the local region. Herein, the additional third insulating film 434R may be simply referred to as a third insulating film 434R.

More detailed configurations of the group of dummy conductive layers 130D4 and the additional third insulating film 434R are substantially the same as those of the group of dummy conductive layers 130D and the third insulating film 134R described with reference to FIGS. 9 to 11, respectively.

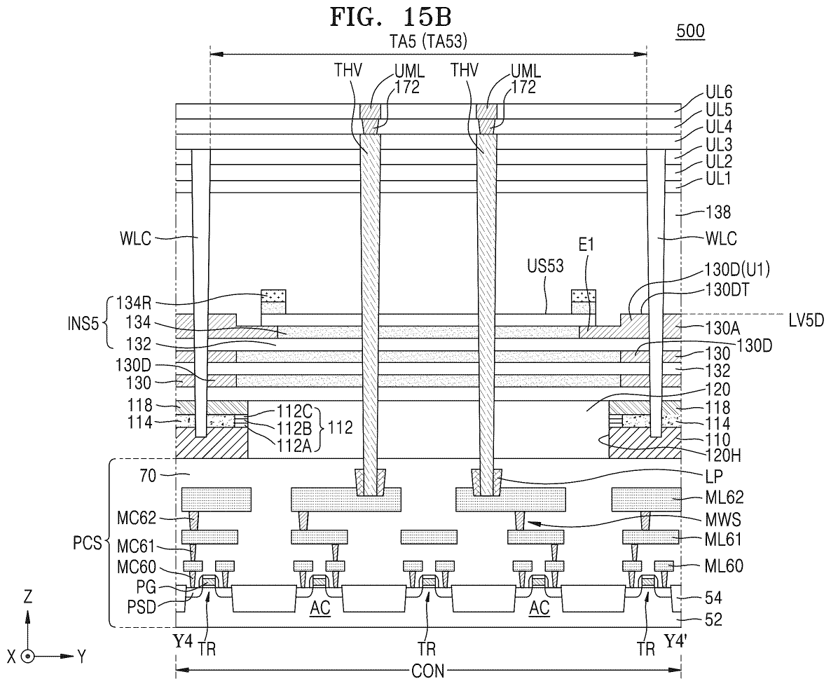

FIGS. 15A and 15B are cross-sectional views illustrating a semiconductor device 500 according to an example embodiment. In FIGS. 15A and 15B, the same reference numerals as in FIGS. 1 to 11 denote the same members, respectively, and here, repeated descriptions thereof are omitted.

Referring to FIGS. 15A and 15B, the semiconductor device 500 has substantially the same configuration as the semiconductor device 100 described with reference to FIGS. 1 to 11. However, a second through-electrode portion TA52 and a third through-electrode portion TA53 of a through-electrode region TA5, which are arranged in the connection area CON, in the semiconductor device 500 may include an insulating structure INS5. The upper surface of the insulating structure INS5 may have a varying height in the vertical direction (the Z direction) along with each of the first horizontal direction (the X direction) and the second horizontal direction (the Y direction).

In the through-electrode region TA5 of the semiconductor device 500, the third insulating film 134R may be apart from the through-electrode THV in the second horizontal direction (the Y direction). The third insulating film 134R may be arranged in a region between the through-electrode THV and the word line cut structure WLC. For example, as shown in FIG. 15A, in the second through-electrode portion TA52 of the through-electrode region TA5, a local region of the insulating structure INS5, which is pierced in the vertical direction (the Z direction) by the plurality of through-electrodes THV, may have an upper surface corresponding to an upper surface US52 of the first insulating film 132, and the upper surface US52 of the first insulating film 132 may be in contact with the interlayer dielectric 138. In the second through-electrode portion TA52 of the through-electrode region TA5, a vertical level LV5A of the upper surface US52 of the first insulating film 132 corresponding to the local region of the insulating structure INS5, which is pierced in the vertical direction (the Z direction) by the through-electrode THV, may be closer to the peripheral circuit structure PCS than a vertical level LV5B of an upper surface 130DT of an upper dummy conductive layer 130D farthest from the peripheral circuit structure PCS, among the plurality of dummy conductive layers 130D in the second through-electrode portion TA52.

As shown in FIG. 15B, in the third through-electrode portion TA53 of the through-electrode region TA5, a local region of the insulating structure INS5, which is pierced in the vertical direction (the Z direction) by the plurality of through-electrodes THV, may have an upper surface corresponding to an upper surface US53 of the first insulating film 132, and the upper surface US53 of the first insulating film 132 may be in contact with the interlayer dielectric 138. In the third through-electrode portion TA53 of the through-electrode region TA5, a vertical level of the upper surface US53 of the first insulating film 132 corresponding to the local region of the insulating structure INS5, which is pierced in the vertical direction (the Z direction) by the through-electrode THV, may be equal or similar to a vertical level LV5D of the upper surface 130DT of the upper dummy conductive layer 130D farthest from the peripheral circuit structure PCS, among the plurality of dummy conductive layers 130D in the third through-electrode portion TA53.

More detailed configurations of the second through-electrode portion TA52 and the third through-electrode portion TA53 are substantially the same as those of the second through-electrode portion TA12 and the third through-electrode portion TA13 of the through-electrode region TA1, which are described with reference to FIGS. 10 and 11, respectively.

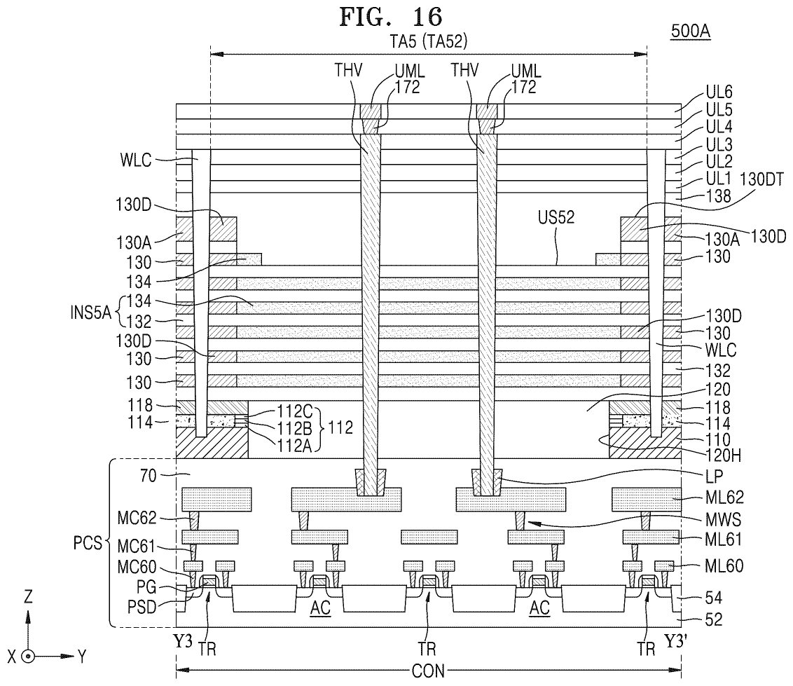

FIG. 16 is a cross-sectional view illustrating a semiconductor device 500A according to an example embodiment. In FIG. 16, the same reference numerals as in FIGS. 1 to 15B denote the same members, respectively, and here, repeated descriptions thereof are omitted.

Referring to FIG. 16, the semiconductor device 500A has substantially the same configuration as the semiconductor device 100 described with reference to FIGS. 1 to 11. However, the second through-electrode portion TA52 of the through-electrode region TA5, which is arranged in the connection area CON, in the semiconductor device 500A may include an insulating structure INS5A. The insulating structure INS5A does not include the third insulating film 134R. The upper surface of the insulating structure INS5A may have a varying height in the vertical direction (the Z direction) along with each of the first horizontal direction (the X direction) and the second horizontal direction (the Y direction).

A local region of the insulating structure INS5A, which is pierced in the vertical direction (the Z direction) by the plurality of through-electrodes THV, may have an upper surface corresponding to the upper surface US52 of the first insulating film 132, and the upper surface US52 of the first insulating film 132 may be in contact with the interlayer dielectric 138.

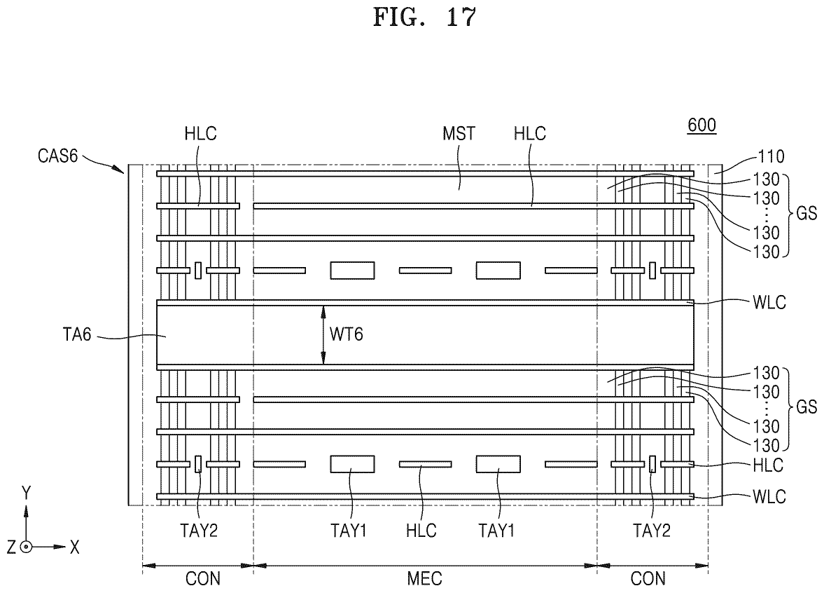

FIG. 17 is a plan view illustrating a semiconductor device 600 according to an example embodiment. In FIG. 17, the same reference numerals as in FIG. 4 denote the same members, respectively, and here, repeated descriptions thereof are omitted.

Referring to FIG. 17, the semiconductor device 600 has substantially the same configuration as the semiconductor device 100 described with reference to FIGS. 1 to 11. However, a cell array structure CAS6 of the semiconductor device 600 may include a through-electrode region TA6.

The through-electrode region TA6 may have substantially the same configuration as the through-electrode region TA1 described with reference to FIGS. 6B and 9 to 11. However, in the second horizontal direction (the Y direction), a width WT6 of the through-electrode region TA6 may be equal or similar to the width of each of the plurality of memory cell blocks.

Similar to the semiconductor device 100 described with reference to FIGS. 1 to 11, each of the semiconductor devices 200, 300, 400, 500, 500A, and 600 described with reference to FIGS. 12A to 17 has a structure capable of securing the structural stability of the insulating structure INS, INS5, or INS5A, which surrounds the plurality of through-electrodes THV, and securing stable insulating distances between the plurality of through-electrodes THV and other conductive regions around the plurality of through-electrodes THV, even without arranging a separate dam structure around the through-electrode region TA2, TA3, TA4, TA5, or TA6, in which the plurality of through-electrodes THV are arranged, in order to secure an insulating distance of an insulating structure. Therefore, in the process of manufacturing each of the semiconductor devices 200, 300, 400, 500, 500A, and 600 according to the example embodiments described above, by omitting structures, such as dam structures, which may generate structural defects, such as cracks, the area of the through-electrode region TA2, TA3, TA4, TA5, or TA6, in which the plurality of through-electrodes THV are arranged, may be sufficiently secured, and a structure having an advantage in improving the degree of integration may be provided. In addition, in the semiconductor devices 200, 300, 400, 500, 500A, and 600 each including a plurality of memory cells that are 3-dimensionally arranged, even when the height of the cell array structure CAS or CAS6 in the vertical direction (the Z direction) is increased due to an increase in the number of stacked gate lines 130 to improve the degree of integration, the cell array structure CAS or CAS6 may be prevented from suffering from leaning or collapse, thereby suppressing process defects and improving reliability in the manufacturing process of each of the semiconductor devices 200, 300, 400, 500, 500A, and 600.

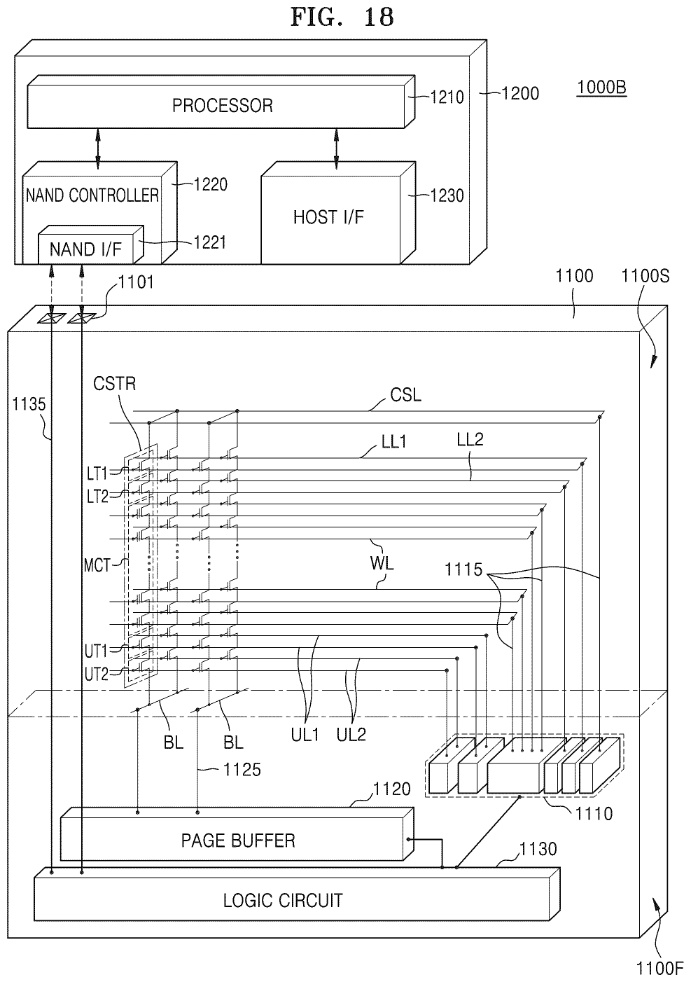

FIG. 18 is a diagram schematically illustrating an electronic system including a semiconductor device, according to an example embodiment.

Referring to FIG. 18, an electronic system 1000B according to an embodiment may include a semiconductor device 1100 and a controller 1200 electrically connected to the semiconductor device 1100. The electronic system 1000B may include a storage device including one or more semiconductor devices 1100 or an electronic device including a storage device. For example, the electronic system 1000B may include a solid-state drive (SSD) device, a universal serial bus (USB), a computing system, a medical device, or a communication device, which includes at least one semiconductor device 1100.

The semiconductor device 1100 may include a nonvolatile memory device. For example, the semiconductor device 1100 may include a NAND flash memory device including at least one of the characteristic structures of the semiconductor devices 100, 200, 300, 400, 500, 500A, and 600 described with reference to FIGS. 1 to 17. The semiconductor device 1100 may include a first structure 1100F and a second structure 1100S on the first structure 1100F. In some example embodiments, the first structure 1100F may be arranged beside the second structure 1100S. The first structure 1100F may include a peripheral circuit structure, which includes a decoder circuit 1110, a page buffer 1120, and a logic circuit 1130. The second structure 1100S may include a memory cell structure, which includes a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The respective numbers of lower transistors LT1 and LT2 and upper transistors UT1 and UT2 may be variously modified depending on embodiments.

In some example embodiments, the upper transistors UT1 and UT2 may include a string select transistor and the lower transistors LT1 and LT2 may include a ground select transistor. A plurality of gate lower lines (that is, LL1 and LL2) may be gate electrodes of the lower transistors LT1 and LT2, respectively. A word line WL may be a gate electrode of a memory cell transistor MCT, and a plurality of gate upper lines (that is, UL1 and UL2) may be gate electrodes of the upper transistors UT1 and UT2, respectively.

The common source line CSL, the plurality of gate lower lines (that is, LL1 and LL2), the plurality of word lines WL, and the plurality of gate upper lines (that is, UL1 and UL2) may be electrically connected with the decoder circuit 1110 via a plurality of first connection wiring lines 1115 extending from inside the first structure 1100F to the second structure 1100S. A plurality of bit lines BL may be electrically connected with the page buffer 1120 via a plurality of second connection wiring lines 1125 extending from inside the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 via an input/output pad 1101 electrically connected with the logic circuit 1130. The input/output pad 1101 may be electrically connected with the logic circuit 1130 via an input/output connection wiring line 1135 extending from inside the first structure 1100F to the second structure 1100S.

The controller 1200 may include a processor 1210, a NAND controller 1220, and a host interface 1230. Depending on some example embodiments, the electronic system 1000B may include a plurality of semiconductor devices 1100, and in this case, the controller 1200 may control the plurality of semiconductor devices 1100.

The processor 1210 may control all operations of the electronic system 1000B including the controller 1200. The processor 1210 may be operated by certain firmware and may access the semiconductor device 1100 by controlling the NAND controller 1220. The NAND controller 1220 may include a NAND interface 1221 that processes communication with the semiconductor device 1100. A control command for controlling the semiconductor device 1100, data intended to be written to the plurality of memory cell transistors MCT of the semiconductor device 1100, data intended to be read from the plurality of memory cell transistors MCT, and the like may be transmitted via the NAND interface 1221. The host interface 1230 may provide a function of communication between the electronic system 1000B and an external host. When receiving a control command from the external host via the host interface 1230, the processor 1210 may control the semiconductor device 1100 in response to the control command.

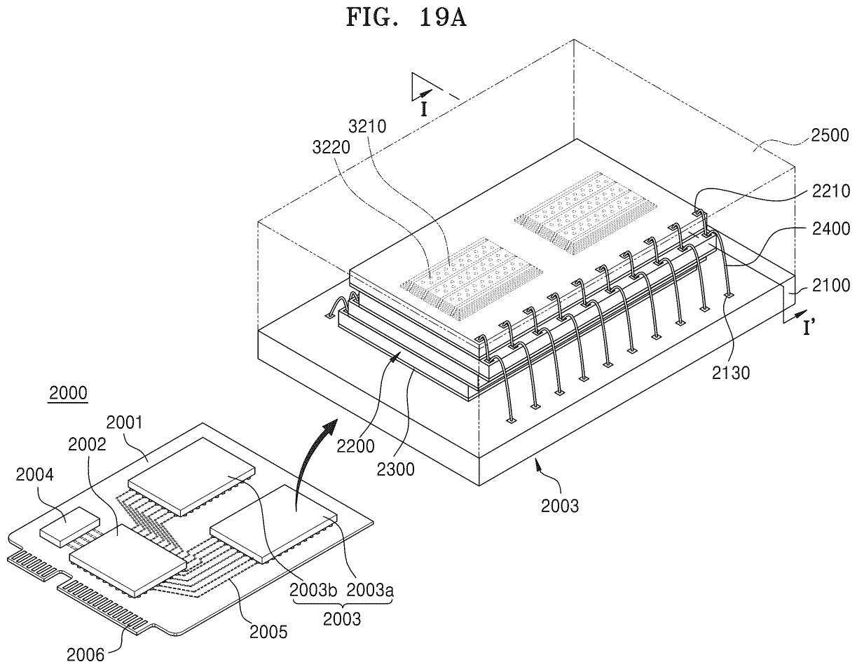

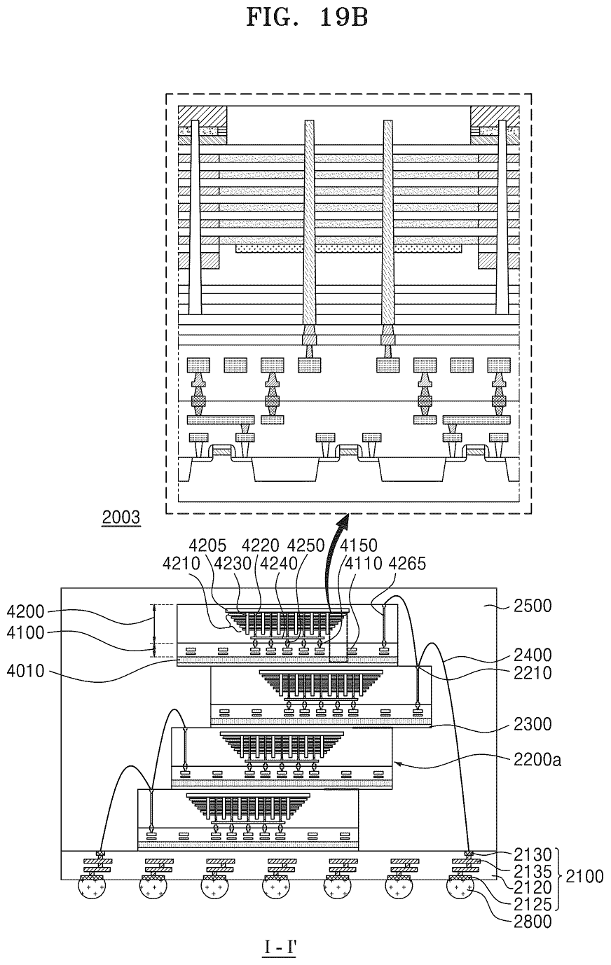

FIG. 19A is a perspective view schematically illustrating an electronic system including a semiconductor device, according to an example embodiment.

Referring to FIG. 19A, an electronic system 2000 according to an example embodiment may include a main substrate 2001, and a controller 2002, one or more semiconductor packages 2003, and DRAM 2004, which are mounted on the main substrate 2001. The semiconductor packages 2003 and the DRAM 2004 may be connected with the controller 2002 by a plurality of wiring patterns 2005 formed on the main substrate 2001.

The main substrate 2001 may include a connector 2006 including a plurality of pins to be coupled with an external host. The number of pins and the arrangement of the plurality of pins, in the connector 2006, may vary depending on a communication interface between the electronic system 2000 and the external host. In some example embodiments, the electronic system 2000 may communicate with the external host according to one of interfaces, such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may be operated by power supplied from the external host via the connector 2006. The electronic system 2000 may further include a power management integrated circuit (PMIC) distributing the power, which is supplied from the external host, to the controller 2002 and the semiconductor packages 2003.

The controller 2002 may write data to or read data from the semiconductor packages 2003 and may improve an operation speed of the electronic system 2000.

The DRAM 2004 may be a buffer memory for alleviating a speed difference between the external host and the semiconductor packages 2003, which are data storage spaces. The DRAM 2004 in the electronic system 2000 may operate as a kind of cache memory and may provide a space for temporarily storing data in a control operation on the semiconductor packages 2003. When the DRAM 2004 is included in the electronic system 2000, the controller 2002 may further include a DRAM controller for controlling the DRAM 2004 in addition to a NAND controller for controlling the semiconductor packages 2003.

The semiconductor package 2003 may include first and second semiconductor packages 2003a and 2003b, which are apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 on a lower surface of each of the plurality of semiconductor chips 2200, a connection structure 2400 electrically connecting the plurality of semiconductor chips 2200 with the package substrate 2100, and a molding layer 2500 arranged on the package substrate 2100 to cover the plurality of semiconductor chips 2200 and the connection structure 2400.

The package substrate 2100 may include a printed circuit board including a plurality of package upper pads 2130. Each of the plurality of semiconductor chips 2200 may include an input/output pad 2210. The input/output pad 2210 may correspond to the input/output pad 1101 of FIG. 18. Each of the plurality of semiconductor chips 2200 may include a plurality of gate stacks 3210 and a plurality of channel structures 3220. Each of the plurality of semiconductor chips 2200 may include at least one of the characteristic structures of the semiconductor devices 100, 200, 300, 400, 500, 500A, and 600 described with reference to FIGS. 1 to 17.

In some example embodiments, the connection structure 2400 may include a bonding wire electrically connecting the input/output pad 2210 with a package upper pad 2130. Therefore, in the first and second semiconductor packages 2003a and 2003b, the plurality of semiconductor chips 2200 may be electrically connected to each other in a bonding wire manner and may be electrically connected with the package upper pads 2130 of the package substrate 2100. In some example embodiments, in the first and second semiconductor packages 2003a and 2003b, the plurality of semiconductor chips 2200 may be electrically connected to each other by a connection structure including a through-silicon via (TSV) rather than by the connection structure 2400 of a bonding wire type.

In some example embodiments, the controller 2002 and the plurality of semiconductor chips 2200 may be included in one package. In some example embodiments, the controller 2002 and the plurality of semiconductor chips 2200 may be mounted on a separate interposer substrate, which is different from the main substrate 2001, and may be connected to each other by wiring lines formed on the interposer substrate.

FIG. 19B is a cross-sectional view taken along a line I-I′ of FIG. 19A and conceptually illustrates the semiconductor package 2003 shown in FIG. 19A.

Referring to FIG. 19B, in the semiconductor package 2003, a plurality of semiconductor chips 2200a may each include a semiconductor substrate 4010, a first structure 4100 on the semiconductor substrate 4010, and a second structure 4200 arranged on the first structure 4100 and bonded to the first structure 4100 in a wafer bonding manner.

The first structure 4100 may include a peripheral circuit area including a peripheral wiring line 4110 and first bonding structures 4150. The second structure 4200 may include a common source line 4205, a gate stack structure 4210 between the common source line 4205 and the first structure 4100, memory channel structures 4220 and a separation structure 4230 each passing through the gate stack structure 4210, and second bonding structures 4250 respectively and electrically connected to the memory channel structures 4220 and word lines (that is, WL of FIG. 1) of the gate stack structure 4210. For example, the second bonding structures 4250 may be respectively and electrically connected to the memory channel structures 4220 and the word lines (that is, WL of FIG. 1) via bit lines 4240 electrically connected to the memory channel structures 4220 and via gate connection wiring lines electrically connected to the word lines (that is, WL of FIG. 1). The first bonding structures 4150 of the first structure 4100 may be brought into contact with and bonded to the second bonding structures 4250 of the second structure 4200, respectively. Bonded portions of the first bonding structures 4150 and the second bonding structures 4250 may include, for example, copper (Cu).

The second structure 4200 may include at least one of the characteristic structures of the semiconductor devices 100, 200, 300, 400, 500, 500A, and 600 described with reference to FIGS. 1 to 17. Each of the semiconductor chips 2200a may further include an input/output pad 2210 and an input/output connection wiring line 4265 under the input/output pad 2210. The input/output connection wiring line 4265 may be electrically connected to some of the second bonding structures 4250.

The semiconductor chips 2200a may be electrically connected to each other by connection structures 2400 of a bonding wire type. In some example embodiments, semiconductor chips in the same one semiconductor package, such as the semiconductor chips 2200a, may be electrically connected to each other by connection structures including TSVs.

Next, a method of manufacturing a semiconductor device, according to an example embodiment, is described in detail.

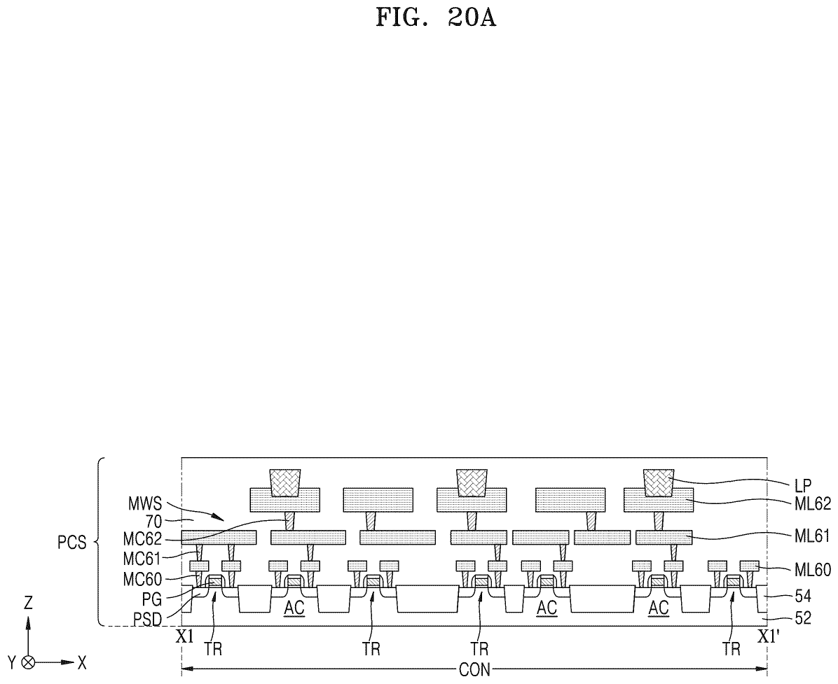

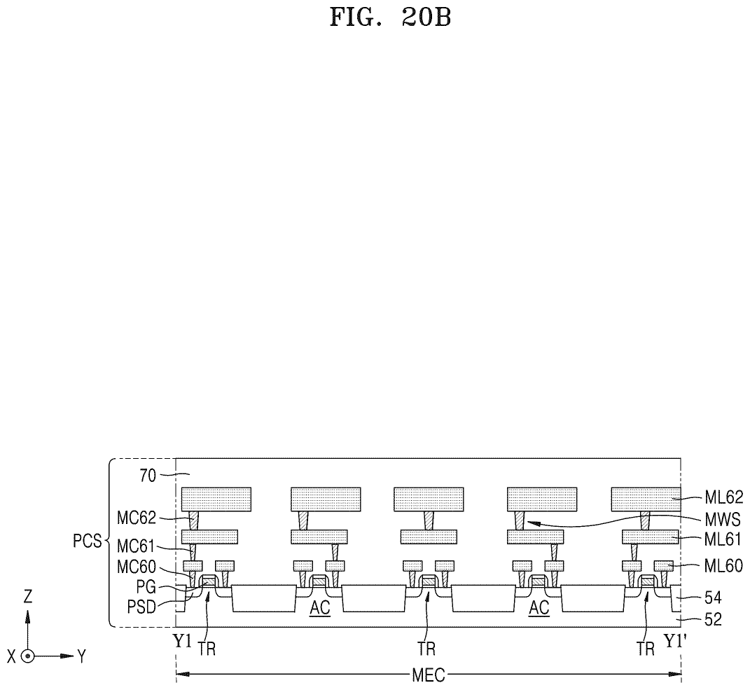

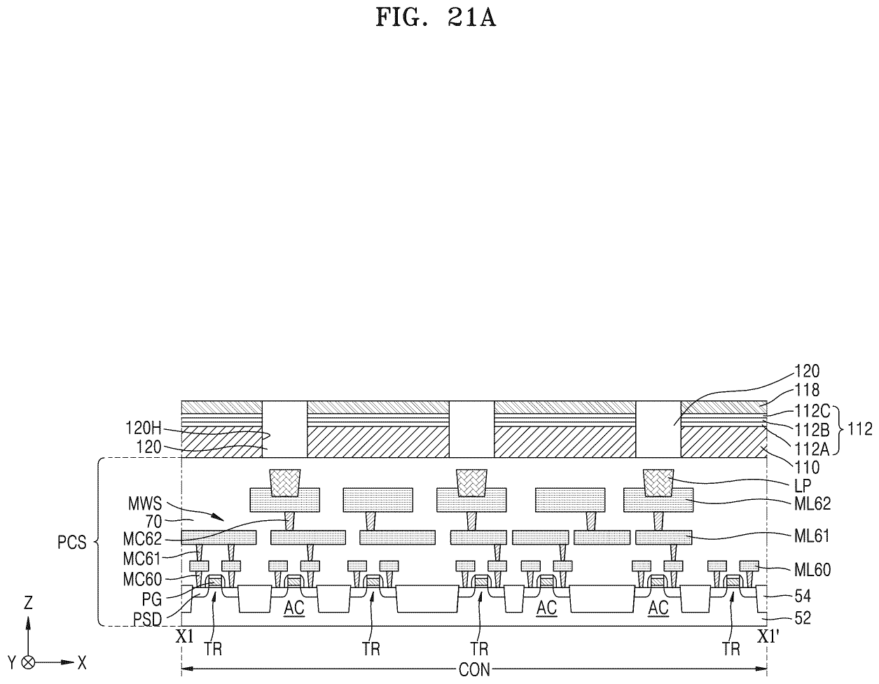

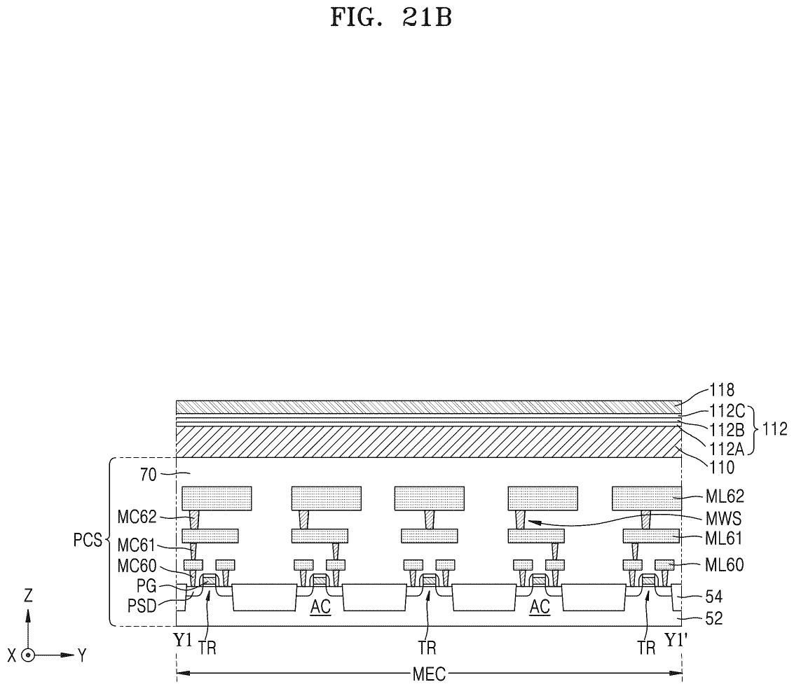

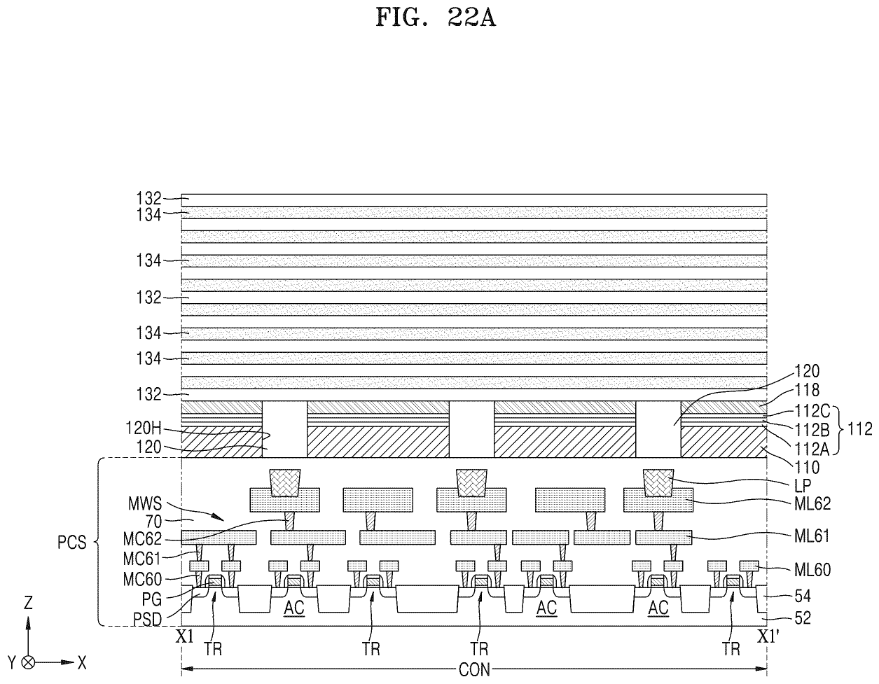

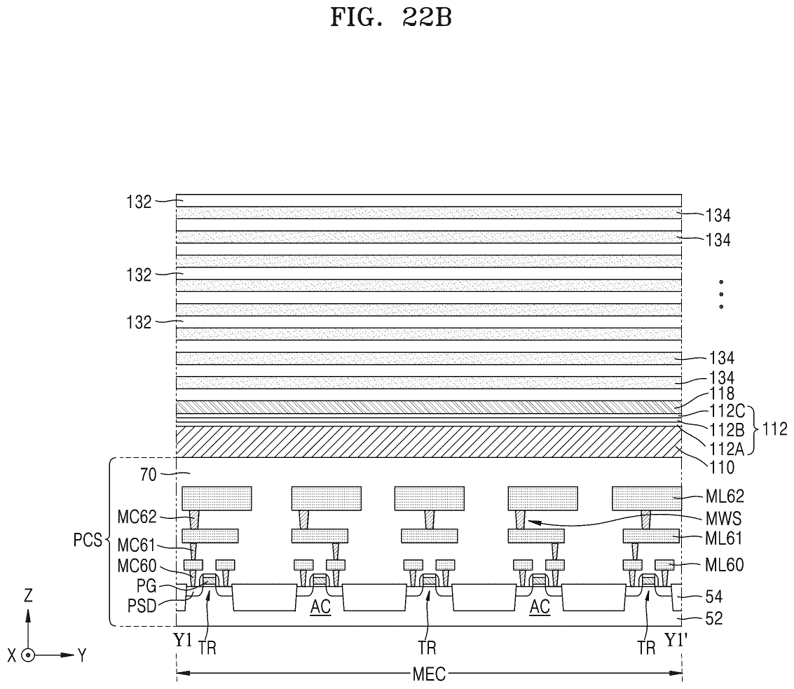

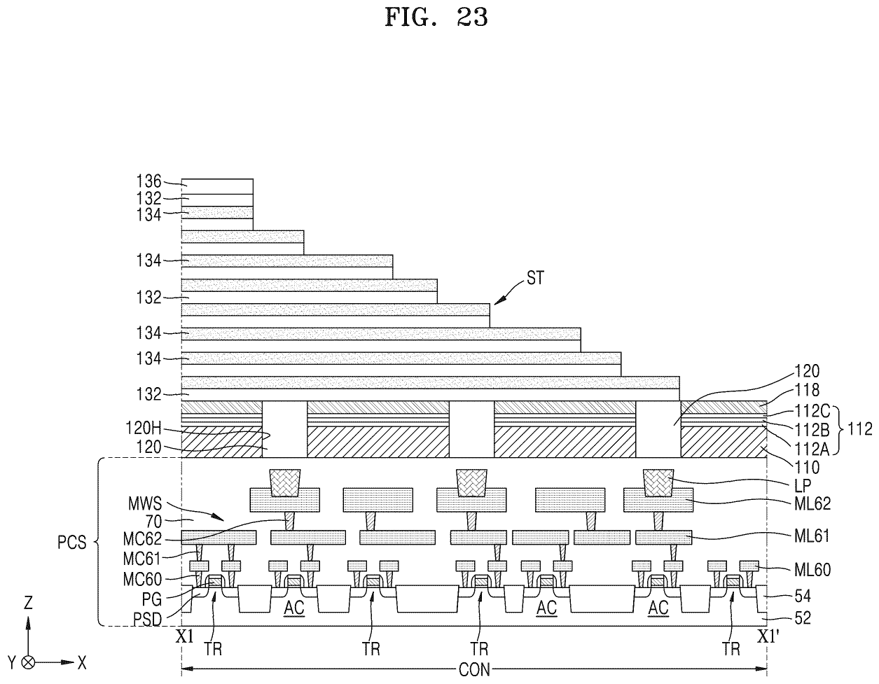

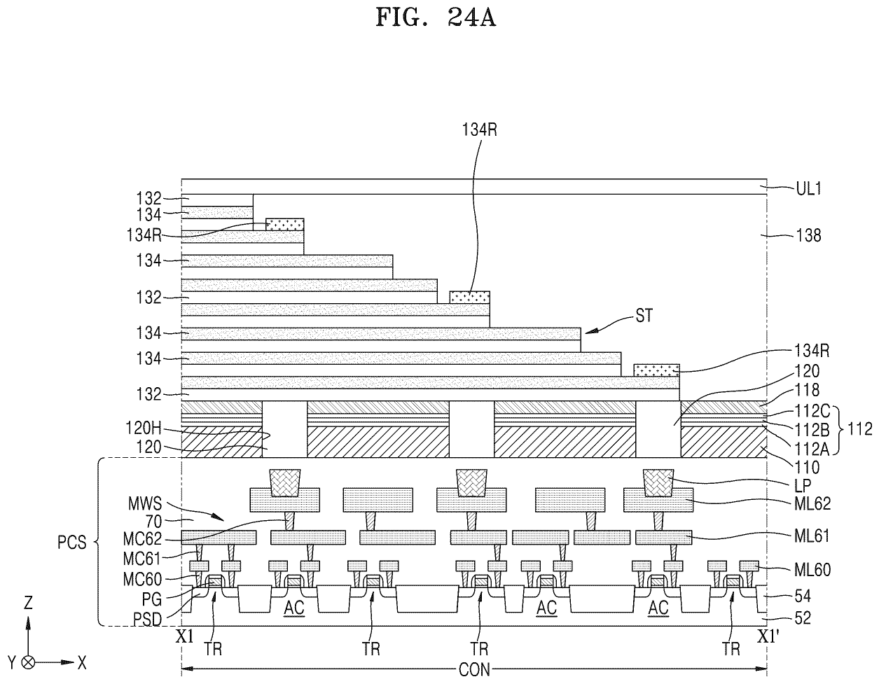

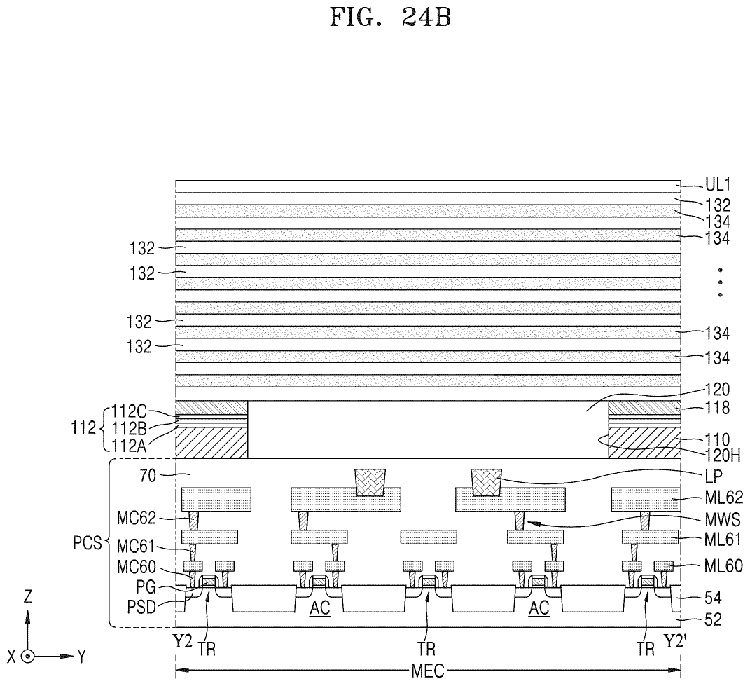

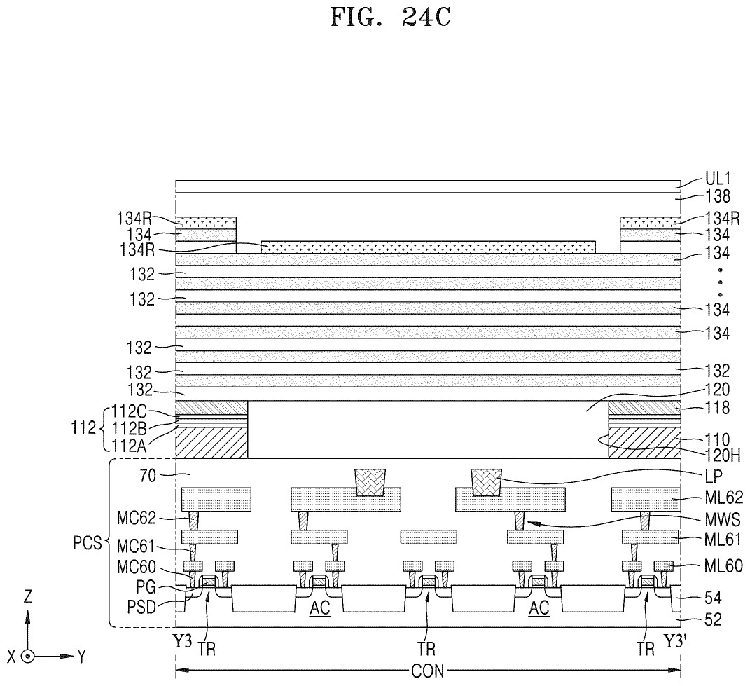

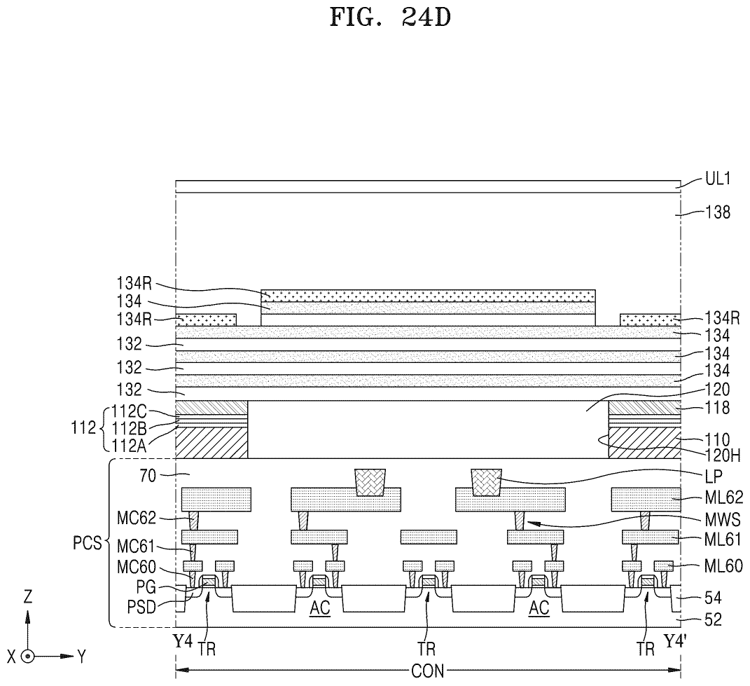

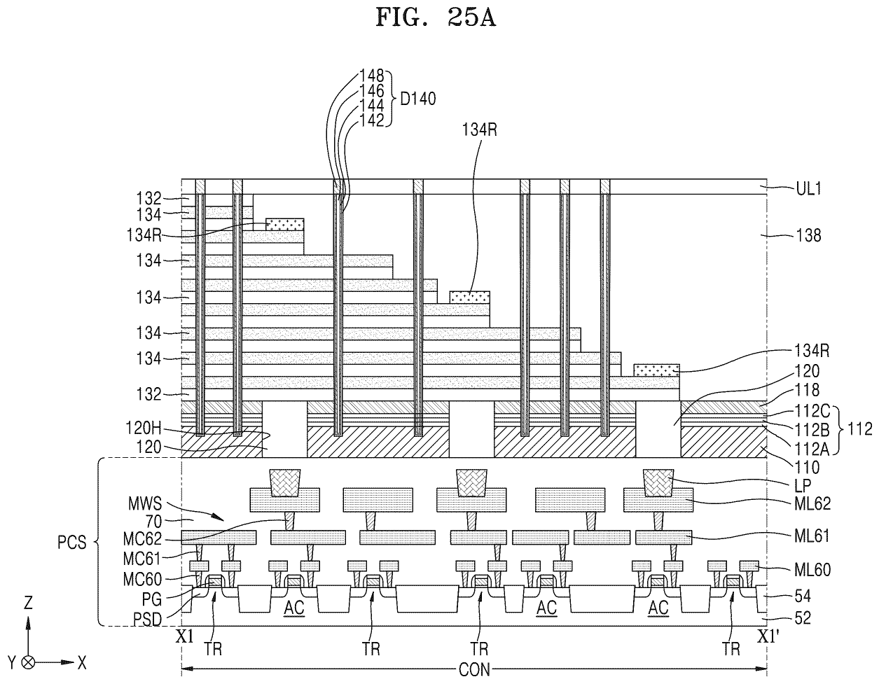

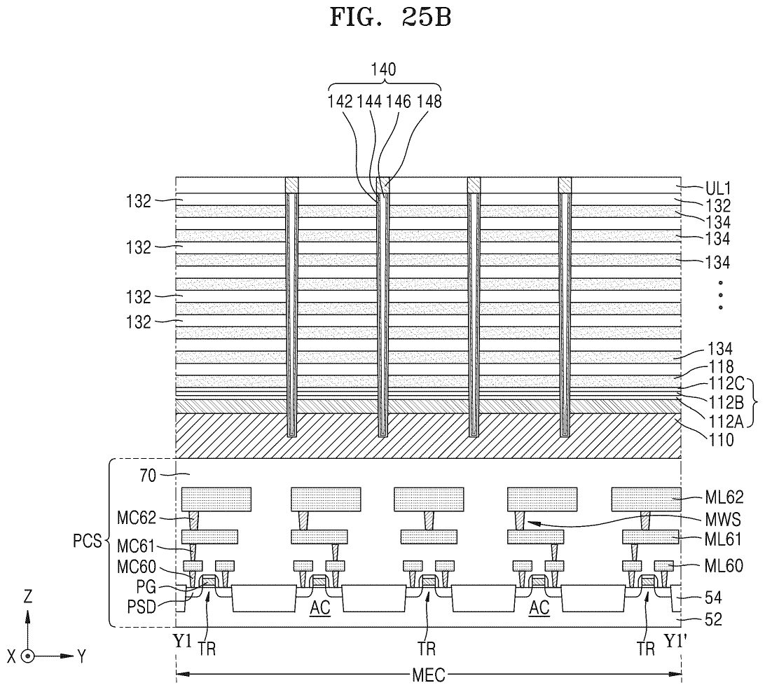

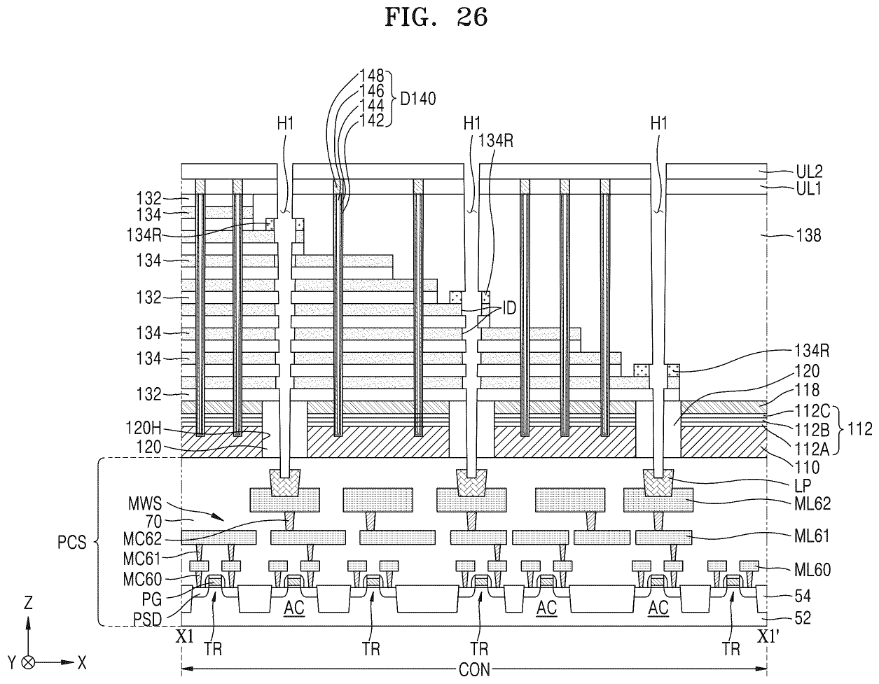

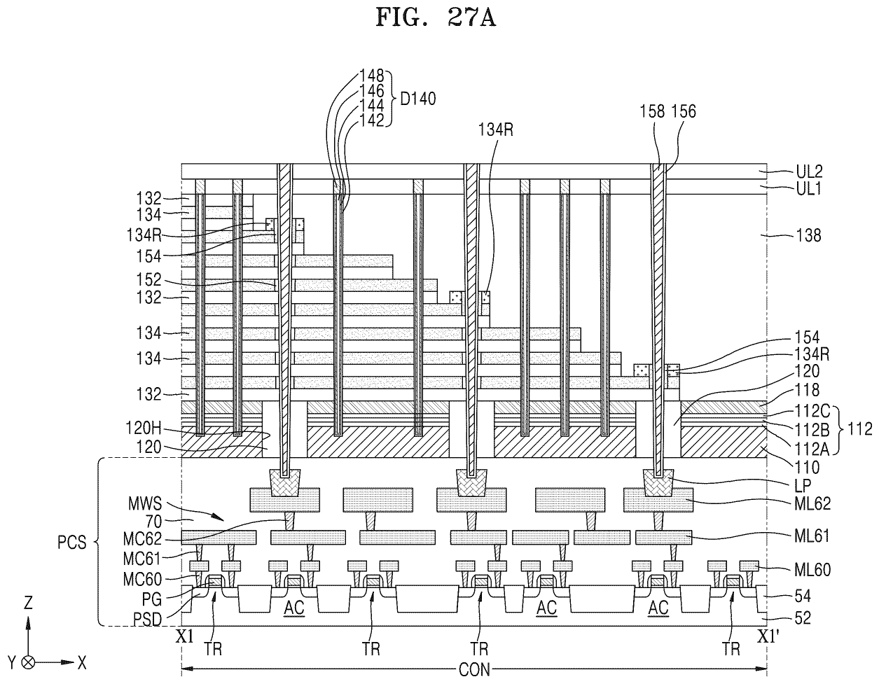

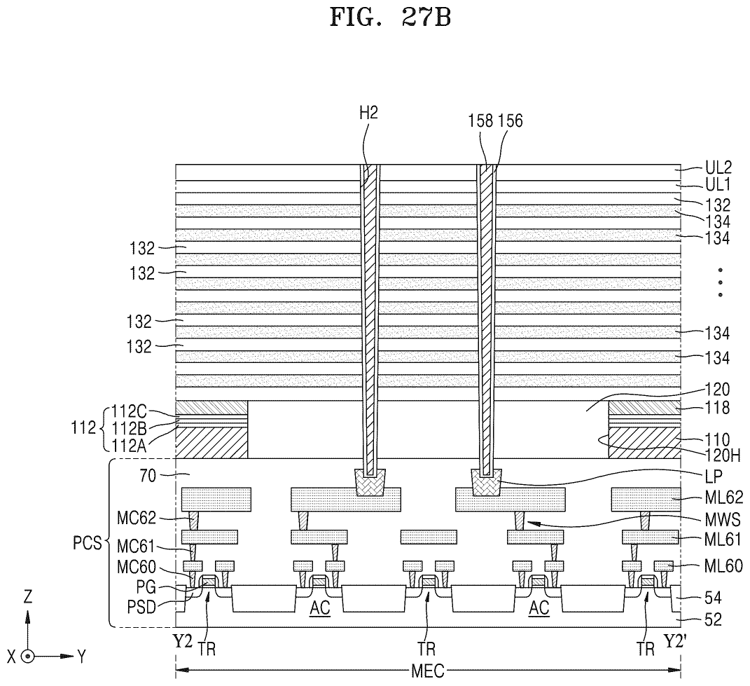

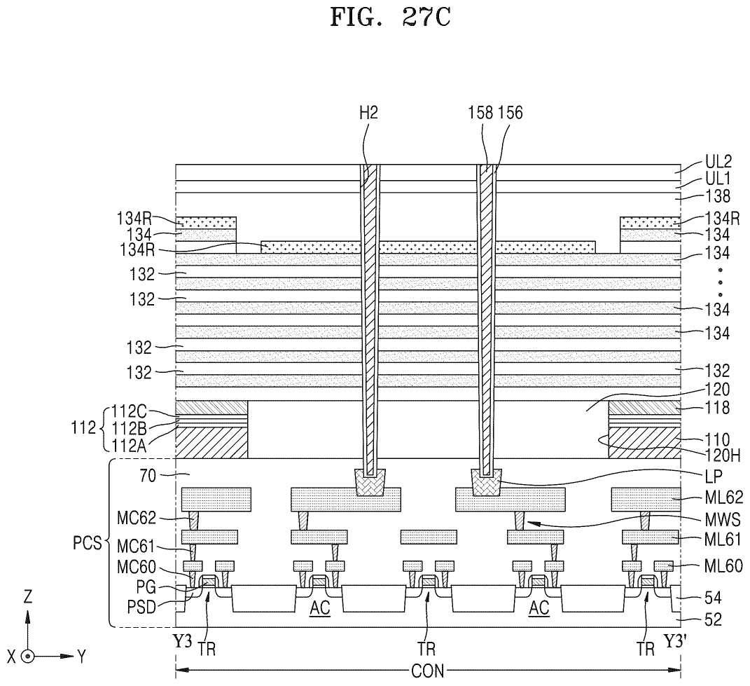

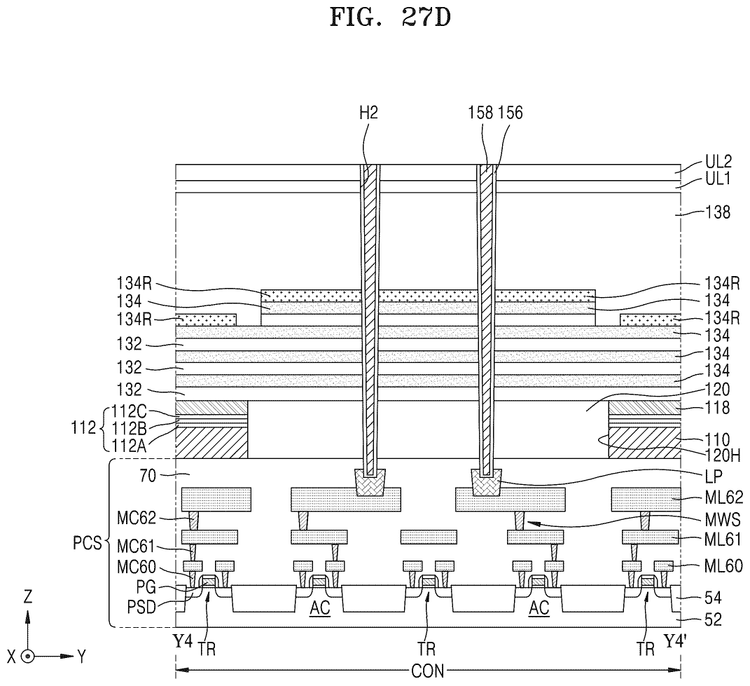

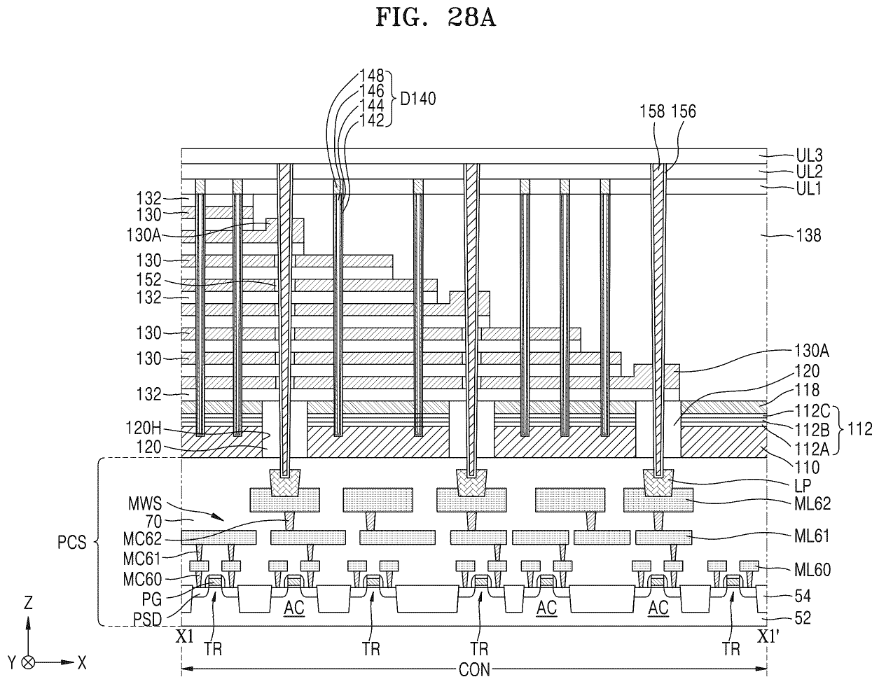

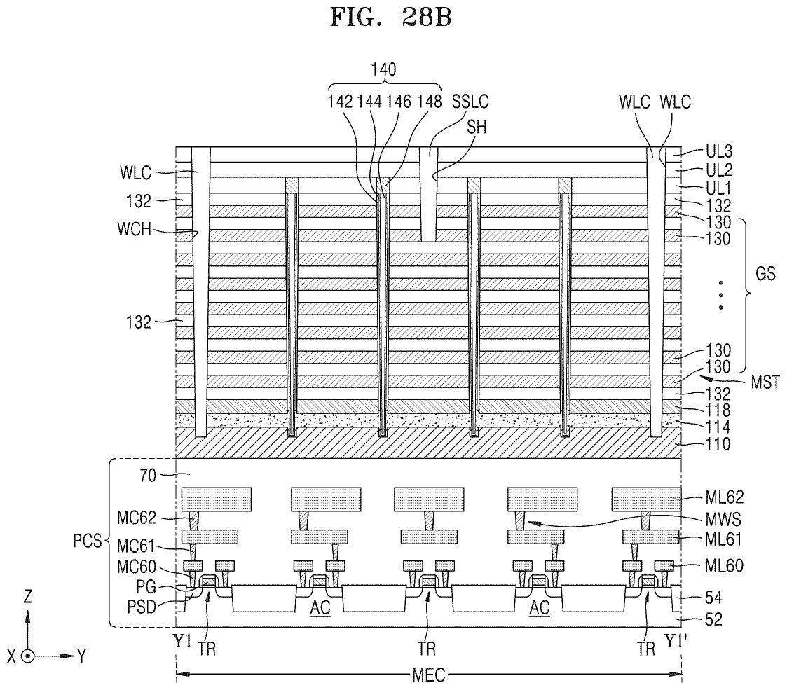

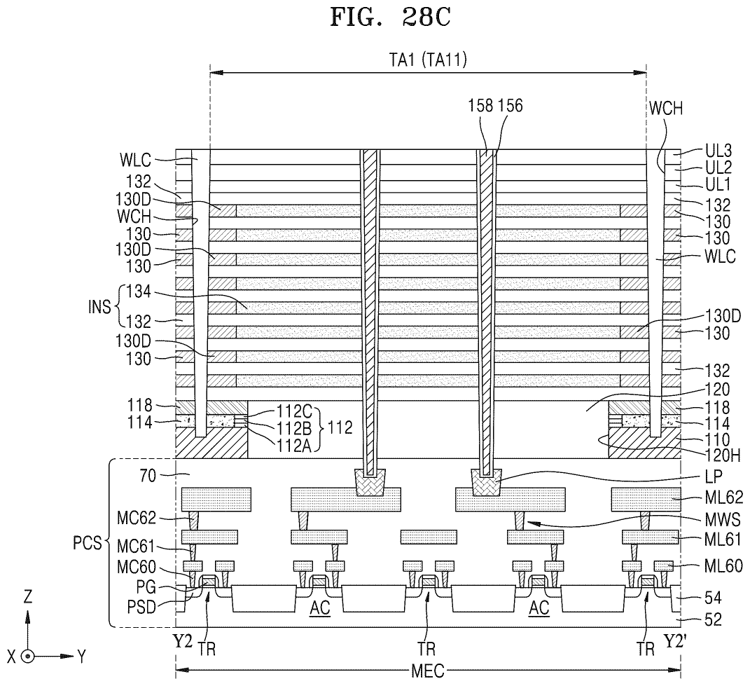

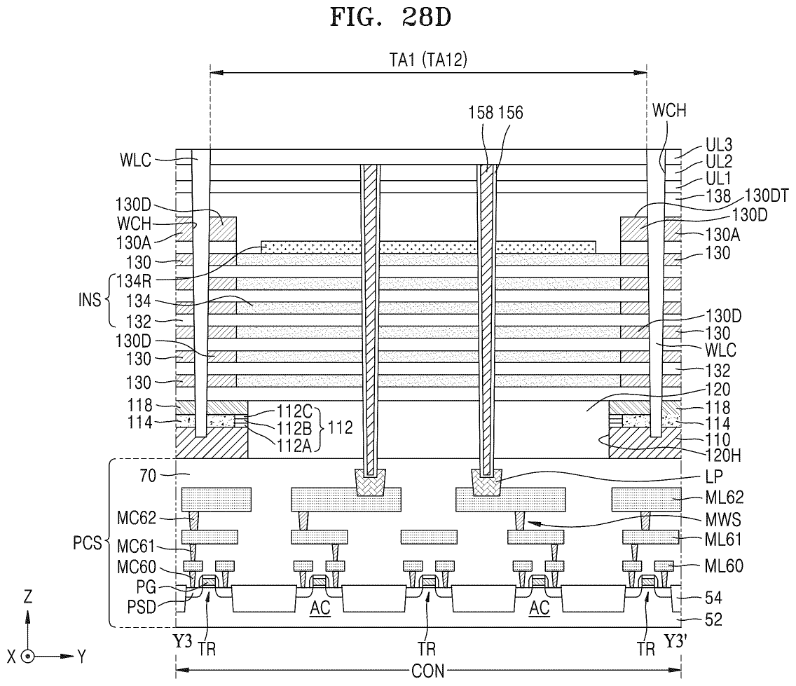

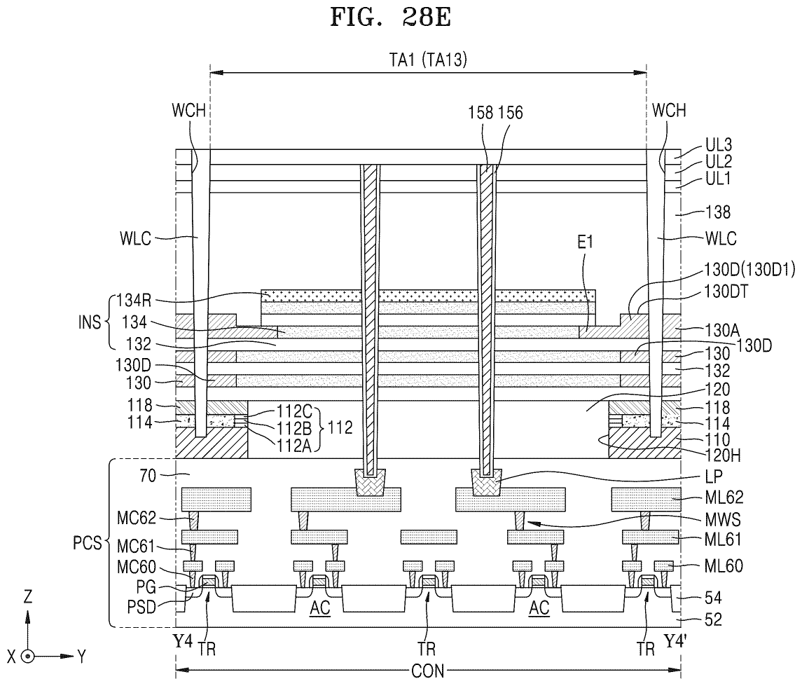

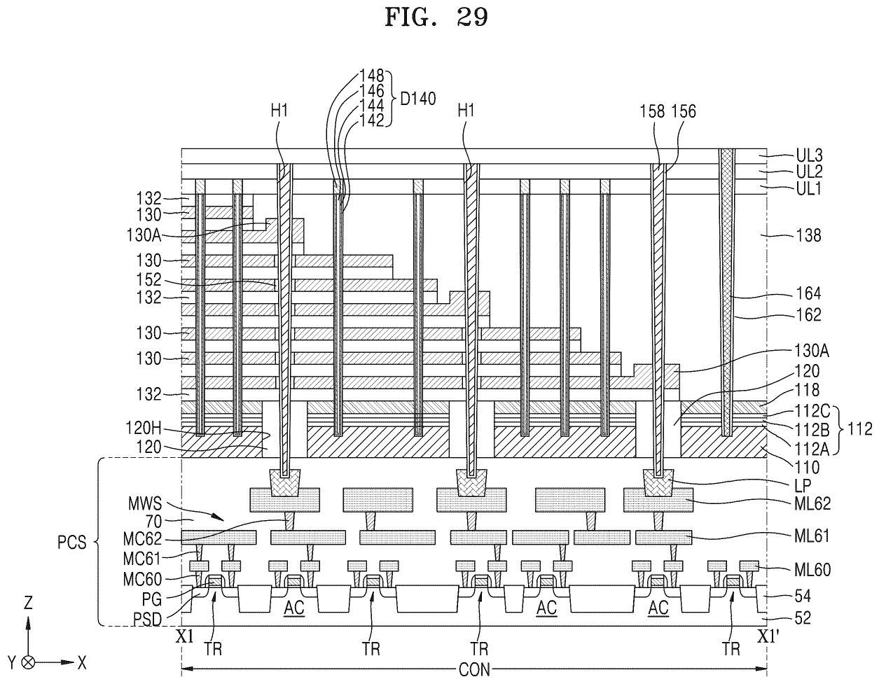

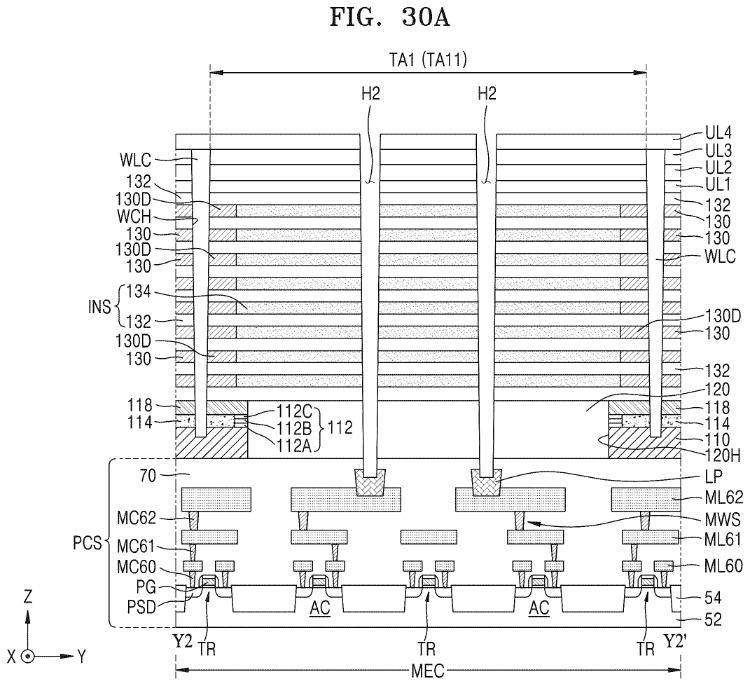

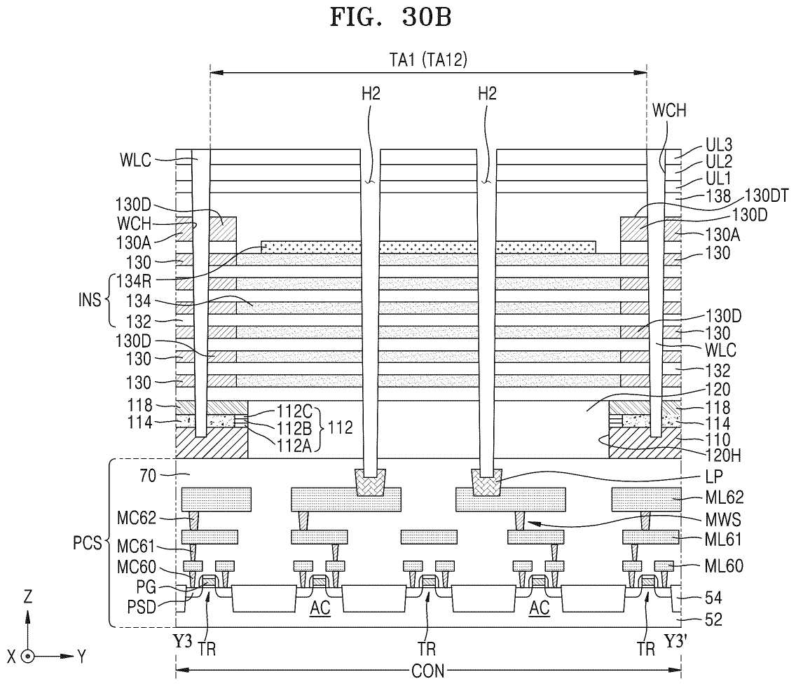

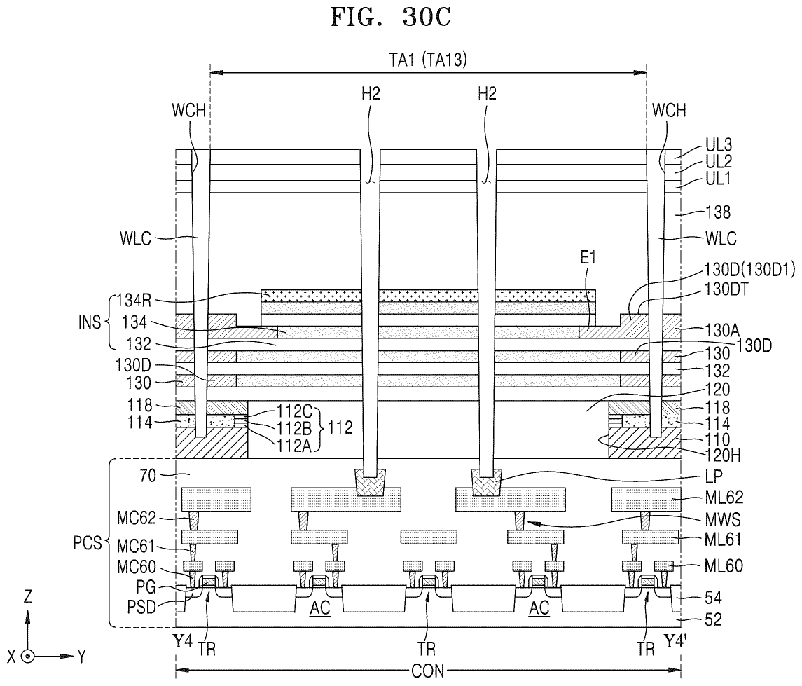

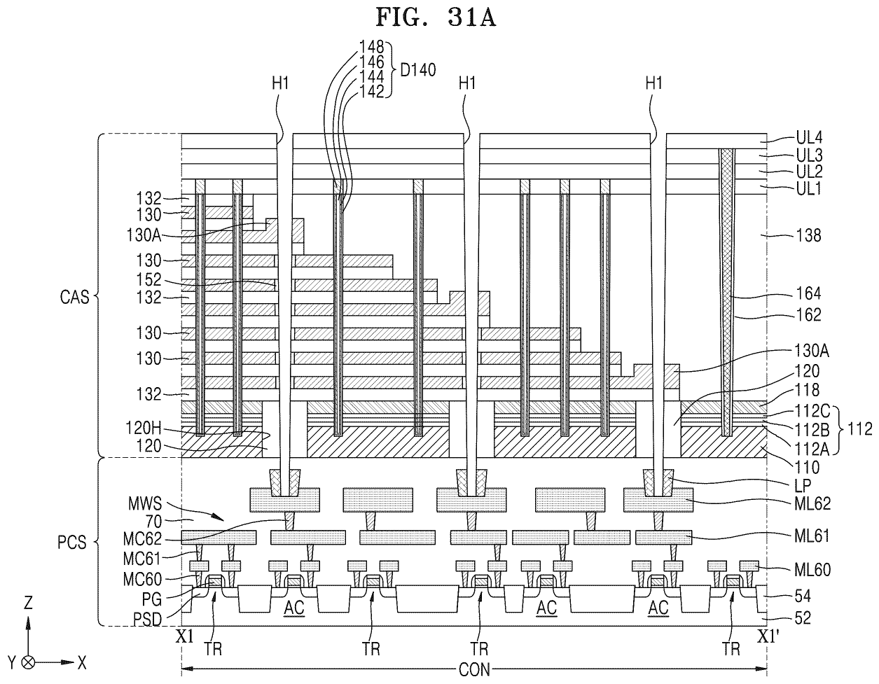

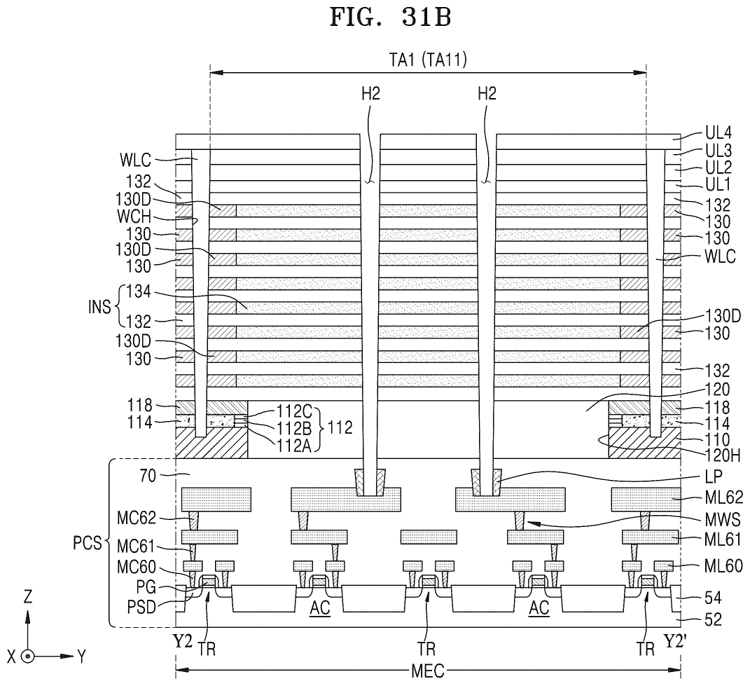

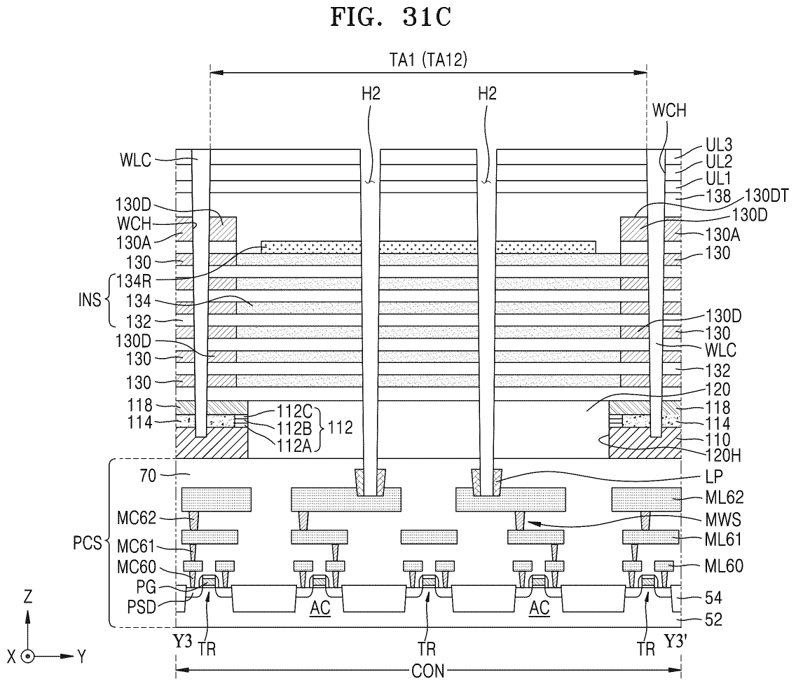

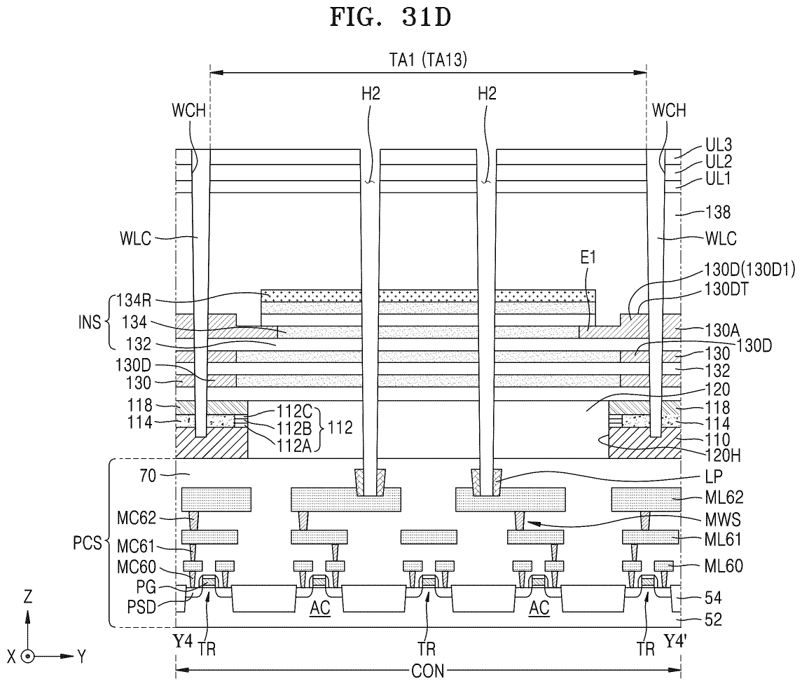

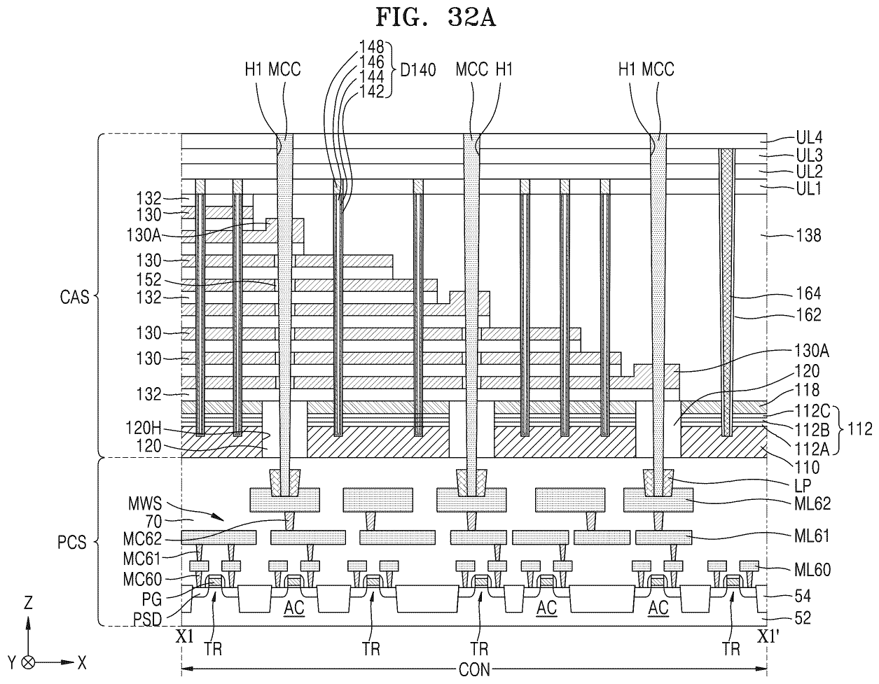

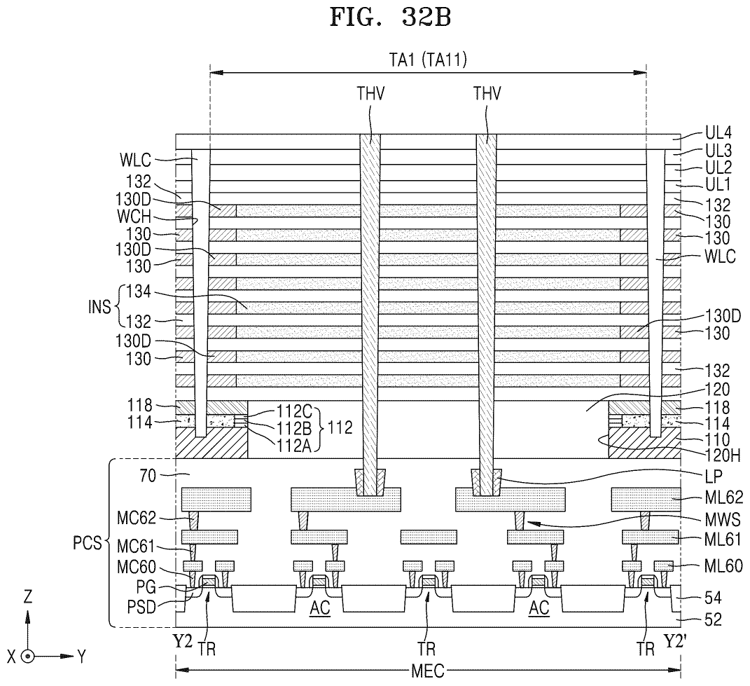

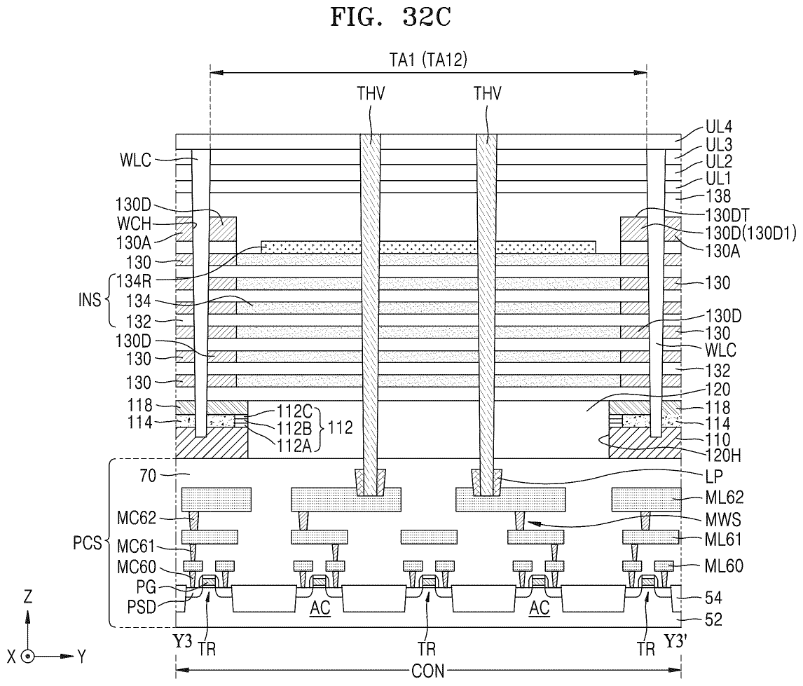

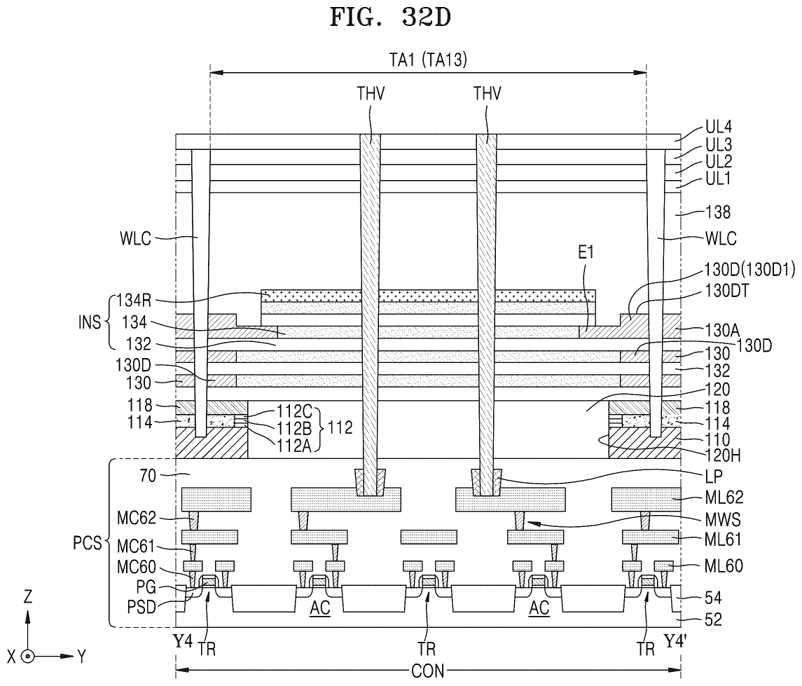

FIGS. 20A to 32D are cross-sectional views illustrating a method of manufacturing a semiconductor device, according to an example embodiment. More specifically, FIG. 20A, FIG. 21A, FIG. 22A, FIG. 23, FIG. 24A, FIG. 25A, FIG. 26, FIG. 27A, FIG. 28A, FIG. 29, FIG. 31A, and FIG. 32A are cross-sectional views illustrating some components of a region corresponding to the cross-section taken along the line X1-X1′ of FIG. 6A, according to a sequence of processes, FIG. 20B, FIG. 21B, FIG. 22B, FIG. 25B, and FIG. 28B are cross-sectional views illustrating some components of a region corresponding to the cross-section taken along the line Y1-Y1′ of FIG. 6A, according to the sequence of processes, FIG. 24B, FIG. 27B, FIG. 28C, FIG. 30A, FIG. 31B, and FIG. 32B are cross-sectional views illustrating some components of a region corresponding to the cross-section taken along the line Y2-Y2′ of FIG. 6B, according to the sequence of processes, FIG. 24C, FIG. 27C, FIG. 28D, FIG. 30B, FIG. 31C, and FIG. 32C are cross-sectional views illustrating some components of a region corresponding to the cross-section taken along the line Y3-Y3′ of FIG. 6B, according to the sequence of processes, and FIG. 24D, FIG. 27D, FIG. 28E, FIG. 30C, FIG. 31D, and FIG. 32D are cross-sectional views illustrating some components of a region corresponding to the cross-section taken along the line Y4-Y4′ of FIG. 6B, according to the sequence of processes. An example of a method of manufacturing the semiconductor device 100 described with reference to FIGS. 1 to 11 is described with reference to FIGS. 20A to 32D.

Referring to FIGS. 20A and 20B, a peripheral circuit structure PCS including a substrate 52, a plurality of transistors TR, a multilayer wiring structure MWS, a plurality of conductive landing pads LP, and an interlayer dielectric 70 may be formed. Each of the plurality of conductive landing pads LP may be arranged in correspondence with a position at which a memory cell contact MCC or a through-electrode THV (see FIGS. 7, 9, 10, and 11) is arranged. The interlayer dielectric 70 may be formed to cover a plurality of wiring layers ML62 at the uppermost position from among a plurality of wiring layers ML60, ML61, and ML62.

Referring to FIGS. 21A and 21B, a plate common source line 110 may be formed on the resulting product of FIGS. 20A and 20B, and an insulating plate 112 and a second conductive plate 118 may be formed in the stated order to cover the plate common source line 110. The insulating plate 112 may include a multilayer-structured insulating film including a first insulating thin film 112A, a second insulating thin film 112B, and a third insulating thin film 112C.

Next, as shown in FIG. 21A, a plurality of third through-openings 120H may be formed in a portion of the connection area CON to pass through the plate common source line 110, the insulating plate 112, and the second conductive plate 118, and a plurality of insulating plugs 120 may be formed to respectively fill the plurality of third through-openings 120H. Here, the plurality of insulating plugs 120 shown in FIGS. 9 to 11 may also be formed simultaneously with the formation of the plurality of insulating plugs 120 shown in FIG. 21A.

Referring to FIGS. 22A and 22B, in the memory cell area MEC and the connection area CON, a plurality of first insulating films 132 and a plurality of second insulating films 134 may be alternately stacked one-by-one on the second conductive plate 118 and the insulating plugs 120. The plurality of first insulating films 132 may each include a silicon oxide film, and the plurality of second insulating films 134 may each include a silicon nitride film or a hydrogenated silicon nitride film. Some of the plurality of second insulating films 134 may function to secure spaces for forming the plurality of gate lines 130 shown in FIGS. 7 and 8, in a subsequent process. Some others of the plurality of second insulating films 134 may be used to form portions of the insulating structure INS of the through-electrode region TA1 shown in FIGS. 9 to 11, in a subsequent process.

Referring to FIG. 23, in the resulting product having undergone the processes described with reference to FIGS. 22A and 22B, an etch stop film 136 may be formed to cover the uppermost first insulating film 132 from among the plurality of first insulating films 132, followed by removing a portion of each of the plurality of first insulating films 132 and the plurality of second insulating films 134 in the connection area CON by a photolithography process, thereby forming a stepped structure ST in which an end portion of each of the plurality of first insulating films 132 and the plurality of second insulating films 134 has a gradually decreasing width in the horizontal direction away from the plate common source line 110.

Referring to FIGS. 24A, 24B, 24C, and 24D, in the resulting product having undergone the process described with FIG. 23, a third insulating film 134R may be formed on the end portion of each of the plurality of second insulating films 134 constituting the stepped structure ST.

Although FIG. 24A illustrates third insulating films 134R respectively formed on end portions of some second insulating films 134 from among the plurality of second insulating films 134, a second insulating film 134 shown in FIG. 24A as not being covered by the third insulating film 134R, among the plurality of second insulating films 134, may have another portion not shown in FIG. 24A but covered by the third insulating film 134R.

In some example embodiments, to form the third insulating film 134R on the end portion of each of the plurality of second insulating films 134, a preliminary third insulating film may be formed to cover the entire surface of the resulting product having undergone the process described with FIG. 23, and then, unnecessary portions of the preliminary third insulating film may be removed.

In some example embodiments, the process, described with reference to FIGS. 22A and 22B, of forming the second insulating film 134, and the process, described with reference to FIGS. 24A, 24B, 24C, and 24D, of forming the preliminary third insulating film that is required to form the third insulating film 134R may be performed by an atomic layer deposition (ALD) process or a plasma-enhanced chemical vapor deposition (PECVD) process.

For example, to form the second insulating film 134 and the preliminary third insulating film, a silicon nitride film or a hydrogenated silicon nitride film may be formed in a plasma atmosphere by using SiH₄ or Si₂H₆ as a silicon atom (Si) source gas and using NH₃ or N₂ as a nitrogen atom (N) source gas. In some example embodiments, while the process of forming each of the second insulating film 134 and the preliminary third insulating film is being performed, when the flow rate of the silicon atom (Si) source gas relatively increases, the content ratio of silicon atoms (Si) may relatively increase in the second insulating film 134 or the preliminary third insulating film, which is obtained as a result, and when the flow rate of the nitrogen atom (N) source gas relatively increases, the content ratio of nitrogen atoms (N) and/or the content ratio of hydrogen atoms (H) may relatively increase in the second insulating film 134 or the preliminary third insulating film, which is obtained as a result, depending on the type of nitrogen atom (N) source gas. For each of the second insulating film 134 and the third insulating film 134R obtained from the preliminary third insulating film, an etch rate in a wet etching solution, for example, a phosphoric acid solution, may decrease along with the increasing content ratio of silicon atoms (Si), and an etch rate in a wet etching solution, for example, a phosphoric acid solution, may increase along with an increase in at least one of the content ratio of nitrogen atoms (N) and the content ratio of hydrogen atoms (H). In some example embodiments, in the case where power with a relatively low-frequency (for example, about 380 kHz) is applied to the inside of a reaction chamber for performing the process of forming each of the second insulating film 134 and the preliminary third insulating film, the etch rate of the second insulating film 134 or the third insulating film 134R, which corresponds to a resulting product, in a wet etching solution, for example, a phosphoric acid solution, may decrease as compared with the case where power with a relatively high-frequency (for example, about 13.56 MHz) is applied to the inside of the reaction chamber. As described above, by controlling the flow rate of the silicon atom (Si) source gas and/or the nitrogen atom (N) source gas, or by controlling the frequency of power applied during the deposition process, each of the second insulating film 134 and the third insulating film 134R may be formed such that each of the second the second insulating film 134 and the third insulating film 134R has an intended etch rate in a wet etching solution, for example, a phosphoric acid solution.

In this way, by controlling each of the second insulating film 134 and the third insulating film 134R to be removed by as much as an intended amount when a portion of each of the second insulating film 134 and the third insulating film 134R is removed in a subsequent process, the respective amounts of the second insulating film 134 and the third insulating film 134R, which are to be left in the insulating structure INS of the through-electrode region TA1 shown in FIGS. 9 to 11, may be determined.

As described above, an interlayer dielectric 138 may be formed to cover the resulting product in which the third insulating film 134R is formed on the end portion of each of the plurality of second insulating films 134. During the formation of the interlayer dielectric 138, the etch stop film 136 may be removed by performing a chemical mechanical polishing (CMP) process for planarizing the upper surface of the interlayer dielectric 138, and as a result, the uppermost first insulating film 132 from among the plurality of first insulating films 132 may be exposed around the interlayer dielectric 138. Next, a first upper insulating film UL1 may be formed to cover the upper surface of each of the uppermost first insulating film 132 and the interlayer dielectric 138.

Referring to FIGS. 25A and 25B, a plurality of channel structures 140, which extend lengthwise in the vertical direction (the Z direction) through the first upper insulating film UL1, the plurality of first insulating films 132, and the plurality of second insulating films 134 in the memory cell area MEC, and a plurality of dummy channel structures D140, which extend lengthwise in the vertical direction (the Z direction) through the first upper insulating film UL1, the plurality of first insulating films 132, the plurality of second insulating films 134, and the interlayer dielectric 138 in the connection area CON, may be formed.

Referring to FIG. 26, a second upper insulating film UL2 may be formed on the resulting product having undergone the processes described with reference to FIGS. 25A and 25B, and then, a plurality of vertical holes H1 may be formed in the connection area CON of a memory cell block. A conductive landing pad LP of the peripheral circuit structure PCS may be exposed at the lower surface of each of the plurality of vertical holes H1.

Each of the plurality of vertical holes H1 may pass through, in the vertical direction (the Z direction), the second upper insulating film UL2, the first upper insulating film UL1, the interlayer dielectric 138, one third insulating film 134R, the plurality of second insulating films 134, the plurality of first insulating films 132, the insulating plug 120, and a portion of the interlayer dielectric 70 of the peripheral circuit structure PCS.

Next, the horizontal-direction width of each of the plurality of vertical holes H1 may be expanded by etching respective portions of the second insulating film 134 and the third insulating film 134R, which are exposed in each of the plurality of vertical holes H1, thereby forming a plurality of indent spaces ID. In some indent spaces ID from among the plurality of indent spaces ID, only the second insulating film 134 out of the second insulating film 134 and the third insulating film 134R may be exposed, and in some other indent spaces ID from among the plurality of indent spaces ID, both the second insulating film 134 and the third insulating film 134R may be exposed together.

Referring to FIGS. 27A, 27B, 27C, and 27D, after the processes described with reference to FIG. 6 are performed, as shown in FIG. 27A, among the plurality of indent spaces ID connected to each of the plurality of vertical holes H1 in the connection area CON of the memory cell block, an indent space ID exposing the second insulating film 134 may be filled with an insulating ring 152, and an indent space ID exposing both the second insulating film 134 and the third insulating film 134R may be filled with a sacrificial insulating ring 154. The insulating ring 152 may include a silicon oxide film. The sacrificial insulating ring 154 may include the same material as the second insulating film 134.

In some example embodiments, a process may be performed such that the insulating ring 152 is formed first in the indent space ID exposing the second insulating film 134 in each of the plurality of vertical holes H1, followed by forming the sacrificial insulating ring 154 in the indent space ID exposing both the second insulating film 134 and the third insulating film 134R in each of the plurality of vertical holes H1. In some example embodiments, an etch stop insulating liner (not shown) may be arranged between the second insulating film 134 and the insulating ring 152. The etch stop insulating liner may include a silicon nitride film.

Next, the inside of each of the plurality of vertical holes H1 may be filled with an insulating spacer 156 and a sacrificial plug 158. In some example embodiments, the insulating spacer 156 may include silicon oxide and the sacrificial plug 158 may include polysilicon, but the inventive concepts are not limited thereto.

As shown in FIGS. 27B, 27C, and 27D, in areas in which the through-electrode region TA1 is to be formed, depending on the positions of the areas, a plurality of vertical holes H2 may be formed to selectively pass through, in the vertical direction (the Z direction), the second upper insulating film UL2, the first upper insulating film UL1, the interlayer dielectric 138, the third insulating film 134R, the plurality of second insulating films 134, the plurality of first insulating films 132, the insulating plug 120, and a portion of the interlayer dielectric 70 of the peripheral circuit structure PCS, and then, the inside of each of the plurality of vertical holes H2 may be filled with the insulating spacer 156 and the sacrificial plug 158.

In some example embodiments, the process of forming the plurality of vertical holes H1 in the connection area CON of the memory cell block and forming the insulating spacer 156 and the sacrificial plug 158 to fill the insides of the plurality of vertical holes H1, as described with reference to FIGS. 26 and 27A, and the process of forming the plurality of vertical holes H2 in the areas, in which the through-electrode region TA1 is to be formed, and forming the insulating spacer 156 and the sacrificial plug 158 to fill the insides of the plurality of vertical holes H2 may be simultaneously performed or may be sequentially performed separately from each other.

Referring to FIGS. 28A, 28B, 28C, 28D, and 28E, a third upper insulating film UL3 may be formed to cover the respective upper surfaces of a plurality of insulating spacers 156, a plurality of sacrificial plugs 158, and the second upper insulating film UL2 in the memory cell area MEC and the connection area CON.

In the resulting product in which the third upper insulating film UL3 is formed, a hole SH may be formed by etching the third upper insulating film UL3, the second upper insulating film UL2, the first upper insulating film UL1, some of the plurality of first insulating films 132, and some of the plurality of second insulating films 134 in the memory cell area MEC, and a string select line cut structure SSLC may be formed to fill the hole SH.

A plurality of word line cut holes WCH may be formed through the third upper insulating film UL3, the second upper insulating film UL2, the first upper insulating film UL1, the interlayer dielectric 138, the plurality of first insulating films 132, the plurality of second insulating films 134, the second conductive plate 118, and the insulating plate 112 in the memory cell area MEC and the connection area CON to expose the plate common source line 110.

Only in the memory cell area MEC out of the memory cell area MEC and the connection area CON, the insulating plate 112 may be selectively removed through an inner space of each of the plurality of word line cut holes WCH, and an empty space formed as a result may be filled with a first conductive plate 114. While the insulating plate 112 in the memory cell area MEC is being removed, portions, which are adjacent to the insulating plate 112, of a gate dielectric film 142 of a channel structure 140 in the memory cell area MEC may be removed together with the insulating plate 112, and as a result, the first conductive plate 114 may pass through a portion of the gate dielectric film 142 in the horizontal direction and contact a channel region 144.

In the memory cell area MEC and the connection area CON, the plurality of second insulating films 134, the third insulating film 134R, and the sacrificial insulating ring 154 may be substituted with the plurality of gate lines 130 through the inner space of each of the plurality of word line cut holes WCH. In each of the plurality of gate lines 130, a relatively thick end portion obtained by substituting the sacrificial insulating ring 154 and both the second insulating film 134 and the third insulating film 134R contacting the sacrificial insulating ring 154 may constitute a gate pad portion 130A.

After the first conductive plate 114 and the plurality of gate lines 130 are formed, the plurality of word line cut holes WCH may be respectively filled with a plurality of word line cut structures WLC. The width of each of the memory cell block and the through-electrode region TA1 in the second horizontal direction (the Y direction) may be determined by the plurality of word line cut structures WLC.

While, in the memory cell area MEC and the connection area CON, the plurality of second insulating films 134 and the third insulating film 134R are being substituted with the plurality of gate lines 130 through the inner space of each of the plurality of word line cut holes WCH, a portion of each of the plurality of second insulating films 134 and the third insulating film 134R in the through-electrode region TA1 may be substituted with a conductive layer, thereby forming a plurality of dummy conductive layers 130D in the through-electrode region TA1. As described with reference to FIGS. 24A, 24B, 24C, and 24D, while the process of forming each of the second insulating film 134 and the preliminary third insulating film for forming the third insulating film 134R is being performed, the etch rate of each of the second insulating film 134 and the third insulating film 134R in a wet etching solution, for example, a phosphoric acid solution, may be controlled by controlling various process conditions, thereby determining the respective widths of the plurality of dummy conductive layers 130D in the second horizontal direction (the Y direction) as shown in each of FIGS. 28C, 28D, and FIG. 28E.

Referring to FIG. 29, in the connection area CON of the memory cell block, a hole PH may be formed through the third upper insulating film UL3, the second upper insulating film UL2, the first upper insulating film UL1, the interlayer dielectric 138, the second conductive plate 118, and the insulating plate 112 to expose the plate common source line 110, and then, an insulating spacer 162 and a conductive plate contact 164 may be sequentially formed in the stated order in the hole PH.

Referring to FIGS. 30A, 30B, and 30C, a fourth upper insulating film UL4 may be formed on the resulting product having undergone the processes described with reference to FIG. 29, followed by removing a portion of each of the fourth upper insulating film UL4 and the third upper insulating film UL3, thereby exposing the insulating spacer 156 and the sacrificial plug 158. Next, the inside of each of the plurality of vertical holes H1 (see FIG. 29) and the plurality of vertical holes H2 may be emptied by removing the insulating spacer 156 and the sacrificial plug 158, which are exposed.

Referring to FIGS. 31A, 31B, 31C, and 31D, in the resulting product of FIGS. 30A, 30B, and 30C, by etching the conductive landing pad LP exposed at the lower surface of each of a plurality of vertical holes H1 and H2, the length of each of the plurality of vertical holes H1 and H2 in the vertical direction (the Z direction) may be increased, and a wiring layer ML62 of the multilayer wiring structure MWS of the peripheral circuit structure PCS may be exposed at the lower surface of each of the plurality of vertical holes H1 and H2.

Referring to FIGS. 32A, 32B, 32C, and 32D, a plurality of memory cell contacts MCC, which respectively fill the plurality of vertical holes H1 in the connection area CON of the memory cell block, and a plurality of through-electrodes THV, which respectively fill the plurality of vertical holes H2 in the through-electrode region TA1, may be formed.

In the processes described with reference to FIGS. 30A to 32D, the process of removing the insulating spacer 156 and the sacrificial plug 158 in each of the plurality of vertical holes H1 and respectively forming the plurality of memory cell contacts MCC in plurality of vertical holes H1, in the connection area CON of the memory cell block, and the process of removing the insulating spacer 156 and the sacrificial plug 158 in each of the plurality of vertical holes H2 and forming the plurality of through-electrodes THV to respectively fill the plurality of vertical holes H2, in the through-electrode region TA1, may be simultaneously performed or may be sequentially performed.

Next, as shown in FIGS. 7 to 11, a fifth upper insulating film UL5 may be formed on the resulting product of FIGS. 32A, 32B, 32C, and 32D, and a contact plug 172, which passes through the fifth upper insulating film UL5 and the fourth upper insulating film UL4 in the connection area CON of the memory cell block and is connected to a conductive plate contact 164, a plurality of contact plugs 176, which pass through the fifth upper insulating film UL5, the fourth upper insulating film UL4, and the third upper insulating film UL3 in the memory cell area MEC and are respectively connected to drain regions 148 of the plurality of channel structures 140, and a plurality of contact plugs 172, which pass through the fifth upper insulating film UL5 in the through-electrode region TA1 and are respectively connected to the through-electrodes THV, may be formed.

Next, a plurality of upper wiring layers UML may be formed on the fifth upper insulating film UL5 in the connection area CON of the memory cell block, and a plurality of bit lines BL may be formed on the fifth upper insulating film UL5 in the memory cell area MEC. In addition, a sixth upper insulating film UL6 may be formed to fill a space between each of the plurality of upper wiring layers UML and a space between each of the plurality of bit lines BL.

Although the method of manufacturing the semiconductor device 100 described with reference to FIGS. 1 to 11 has been described with reference to FIGS. 20A to 32D, it will be understood by those of ordinary skill in the art that, by making various modifications and changes to the method described with reference to FIGS. 20A to 32D without departing from the spirit and scope of the inventive concepts, the integrated circuit devices 200, 300, 400, 500, 500A, and 600 described with reference to FIGS. 12A to 17 and semiconductor devices having various structures modified and changed therefrom may be manufactured.

For example, to manufacture the semiconductor devices 200, 300, and 400 described with reference to FIGS. 12A to 14B, the etch rate of each of the second insulating film 134 and the third insulating film 134R in a wet etching solution may be controlled by controlling various process conditions while the process of forming each of the second insulating film 134 and the preliminary third insulating film for forming the third insulating film 134R is being performed as described with reference to FIGS. 24A, 24B, 24C, and 24D, thereby forming a plurality of dummy conductive layers 130D2, 130D3, and 130D4 having various widths in the second horizontal direction (the Y direction) as shown in FIGS. 12A to 14B.

To manufacture the semiconductor device 500 described with reference to FIGS. 15A and 15B, in the process described with reference to FIGS. 24A, 24B, 24C, and 24D, the third insulating film 134R may be formed in a local region of the through-electrode region TA1, in which the plurality of through-electrodes THV are arranged, and then, a portion of the third insulating film 134R may be removed from the local region. Here, a portion of the second insulating film 134, which is exposed as a result of removing the third insulating film 134R, may also be removed together. Next, the processes described with reference to FIGS. 25A to 32D may be performed, thereby manufacturing the semiconductor device 500 described with reference to FIGS. 15A and 15B.

To manufacture the semiconductor device 500A described with reference to FIG. 16, similar processes to those of the method, described with reference to FIGS. 15A and 15B, of manufacturing the semiconductor device 500 may be used. However, to manufacture the semiconductor device 500A, in the process described with reference to FIGS. 24A, 24B, 24C, and 24D, the third insulating film 134R in the local region of the through-electrode region TA1, in which the plurality of through-electrodes THV are arranged, may be completely removed. Here, a portion of the second insulating film 134, which is exposed as a result of removing the third insulating film 134R, may also be removed together. Next, the processes described with reference to FIGS. 25A to 32D may be performed, thereby manufacturing the semiconductor device 500A described with reference to FIG. 16.

According to the method, described with reference to FIGS. 20A to 32D, of manufacturing a semiconductor device, according to some example embodiments, even without arranging a separate dam structure, for securing an insulating distance of an insulating structure, around the through-electrode region TA1 in which the plurality of through-electrodes THV are arranged, the etch rate of each of the second insulating film 134 and the third insulating film 134R in a wet etch solution may be controlled by controlling various process conditions while the process of forming each of the second insulating film 134 and the preliminary third insulating film for forming the third insulating film 134R is being performed as described with reference to FIGS. 24A, 24B, 24C, and 24D, thereby securing the structural stability of the insulating structure INS surrounding the plurality of through-electrodes THV in the through-electrode region TA1. Therefore, according to the method of manufacturing a semiconductor device, according to some example embodiments, a manufacturing process of the semiconductor device may be simplified, and the area of the through-electrode region TA1, in which the plurality of through-electrodes THV are arranged, may be sufficiently secured, thereby providing a structure having an advantage in improving the degree of integration. In addition, in a semiconductor device including a plurality of memory cells that are 3-dimensionally arranged, even when the height of the cell array structure CAS in the vertical direction (the Z direction) is increased due to an increase in the number of stacked gate lines 130 to improve the degree of integration, the cell array structure CAS may be mitigated or prevented from suffering from leaning or collapse, thereby suppressing process defects and improving reliability in a manufacturing process of the semiconductor device.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

1. A semiconductor device comprising:
a peripheral circuit structure comprising a circuit substrate and a plurality of circuits on the circuit substrate; and
a through-electrode region overlapping the peripheral circuit structure in a vertical direction,
wherein the through-electrode region comprises
an insulating structure comprising a plurality of first insulating films and a plurality of second insulating films, the insulating structure having an upper surface having a varying height in the vertical direction along with each of a first horizontal direction and a second horizontal direction perpendicular to the first horizontal direction, the plurality of first insulating films and the plurality of second insulating films comprising different materials from each other and being alternately stacked one-by-one in the vertical direction,
an interlayer dielectric covering the upper surface of the insulating structure, and
a plurality of through-electrodes passing through the insulating structure and the interlayer dielectric in the vertical direction in a local region of the through-electrode region, each of the plurality of through-electrodes being configured to be connected to one circuit selected from the plurality of circuits of the peripheral circuit structure.

2. The semiconductor device of claim 1, further comprising:
a word line cut structure on one side of the through-electrode region in the second horizontal direction; and
a plurality of dummy conductive layers between the word line cut structure and the insulating structure in the through-electrode region, the plurality of dummy conductive layers being apart from each other in the vertical direction,
wherein a vertical level of the upper surface of the insulating structure in the local region of the through-electrode region is closer to the peripheral circuit structure than a vertical level of an upper surface of a dummy conductive layer, which is farthest from the peripheral circuit structure, among the plurality of dummy conductive layers.

3. The semiconductor device of claim 1, further comprising:
a word line cut structure on one side of the through-electrode region in the second horizontal direction; and
a plurality of dummy conductive layers between the word line cut structure and the insulating structure in the through-electrode region, the plurality of dummy conductive layers being apart from each other in the vertical direction,
wherein a vertical level of the upper surface of the insulating structure in the local region of the through-electrode region is farther from the peripheral circuit structure than a vertical level of an upper surface of a dummy conductive layer, which is farthest from the peripheral circuit structure, among the plurality of dummy conductive layers.

4. The semiconductor device of claim 1, wherein
the insulating structure further comprises a plurality of third insulating films contacting an upper second insulating film, which is adjacent to the interlayer dielectric, among the plurality of second insulting films in a portion of the through-electrode region,
each of the plurality of first insulating films comprises a silicon oxide film,
each of the plurality of second insulating films and the plurality of third insulating films comprises a silicon nitride film or a hydrogenated silicon nitride film, and
at least one of a first condition that a content ratio of silicon atoms (Si) in each of the plurality of third insulating films is less than a content ratio of silicon atoms (Si) in each of the plurality of second insulating films, a second condition that a content ratio of nitrogen atoms (N) in each of the plurality of third insulating films is greater than a content ratio of nitrogen atoms (N) in each of the plurality of second insulating films, or a third condition that a content ratio of hydrogen atoms (H) in each of the plurality of third insulating films is greater than a content ratio of hydrogen atoms (H) in each of the plurality of second insulating films is satisfied.

5. The semiconductor device of claim 1, wherein the insulating structure further comprises a third insulating film arranged in the local region of the through-electrode region,
the third insulating film comprises a constituent material that is different from a constituent material of each of the plurality of first insulating films and a constituent material of each of the plurality of second insulating films, and
at least one through-electrode selected from the plurality of through-electrodes passes through the third insulating film in the vertical direction.

6. The semiconductor device of claim 1, further comprising:
a plurality of memory cell blocks overlapping the peripheral circuit structure in the vertical direction, the plurality of memory cell blocks extending lengthwise in the first horizontal direction,
wherein each of the plurality of memory cell blocks comprises a memory cell area and a connection area, the memory cell area comprising a plurality of gate lines and a plurality of vertical channel structures passing through the plurality of gate lines in the vertical direction, the connection area arranged on one side of the memory cell area and including an edge portion of each of the plurality of gate lines,
the through-electrode region comprises a first through-electrode portion facing the memory cell area in the second horizontal direction, a second through-electrode portion facing the connection area in the second horizontal direction and arranged at a first position in the through-electrode region, and a third through-electrode portion facing the connection area in the second horizontal direction and arranged at a second position in the through-electrode region,
in each of the second through-electrode portion and the third through-electrode portion, the insulating structure further comprises a third insulating film contacting an upper second insulating film, which is adjacent to the interlayer dielectric, among the plurality of second insulating films, and
the third insulating film of the second through-electrode portion and the third insulating film of the third through-electrode portion are at different vertical levels, respectively.

7. A semiconductor device comprising:
a peripheral circuit structure comprising a circuit substrate and a plurality of circuits on the circuit substrate;
a plurality of memory cell blocks, each of the plurality of memory cell blocks overlapping the peripheral circuit structure in a vertical direction, each of the plurality of memory cell blocks extending lengthwise in a first horizontal direction; and
a through-electrode region overlapping the peripheral circuit structure in the vertical direction, the through-electrode region being between two adjacent memory cell blocks selected from the plurality of memory cell blocks,
wherein the through-electrode region comprises
an insulating structure comprising a plurality of first insulating films and a plurality of second insulating films, the insulating structure having an upper surface having a varying height in the vertical direction along with each of the first horizontal direction and a second horizontal direction perpendicular to the first horizontal direction, the plurality of first insulating films and the plurality of second insulating films comprising different materials from each other and being alternately stacked one-by-one in the vertical direction;
an interlayer dielectric covering the upper surface of the insulating structure; and
a plurality of through-electrodes passing through the insulating structure and the interlayer dielectric in the vertical direction in a local region of the through-electrode region, each of the plurality of through-electrodes being configured to be connected to one circuit selected from the plurality of circuits of the peripheral circuit structure.

8. The semiconductor device of claim 7, further comprising:
a plurality of word line cut structures arranged one-by-one on both sides of each of the plurality of memory cell blocks in the second horizontal direction to define a width of each of the plurality of memory cell blocks in the second horizontal direction,
a width of the through-electrode region in the second horizontal direction is defined by a pair of word line cut structures that are adjacent to each other and selected from the plurality of word line cut structures, and
the through-electrode region further comprises a plurality of dummy conductive layers, the plurality of dummy conductive layers being between the insulating structure and at least one of the pair of word line cut structures, the plurality of dummy conductive layers being apart from each other in the vertical direction.

9. The semiconductor device of claim 7, wherein the insulating structure further comprises a plurality of third insulating films contacting an upper second insulating film, which is adjacent to the interlayer dielectric, among the plurality of second insulating films in a portion of the through-electrode region, and
each of the plurality of third insulating films comprises a constituent material that is different from a constituent material of each of the plurality of first insulating films and a constituent material of each of the plurality of second insulating films.

10. The semiconductor device of claim 9, wherein the plurality of third insulating films comprise at least one third insulating film arranged in the local region of the through-electrode region, and
at least one through-electrode selected from the plurality of through-electrodes passes through the at least one third insulating film in the vertical direction.

11. The semiconductor device of claim 9, wherein the plurality of third insulating films comprise at least one third insulating film arranged outside the local region of the through-electrode region, and
the at least one third insulating film is apart from the plurality of through-electrodes.

12. The semiconductor device of claim 9, wherein each of the plurality of first insulating films comprises a silicon oxide film,
each of the plurality of second insulating films and the plurality of third insulating films comprises a silicon nitride film or a hydrogenated silicon nitride film, and
a content ratio of silicon atoms (Si) in the constituent material of each of the plurality of second insulating films is different from a content ratio of silicon atoms (Si) in the constituent material of each of the plurality of third insulating films.

13. The semiconductor device of claim 7, further comprising:
a pair of word line cut structures defining a width of the through-electrode region in the second horizontal direction; and
a plurality of dummy conductive layers arranged in the through-electrode region and contacting the pair of word line cut structures,
wherein a vertical level of the upper surface of the insulating structure in the local region of the through-electrode region is closer to the peripheral circuit structure than a vertical level of an upper surface of a dummy conductive layer, which is farthest from the peripheral circuit structure, among the plurality of dummy conductive layers.

14. The semiconductor device of claim 7, further comprising:
a pair of word line cut structures defining a width of the through-electrode region in the second horizontal direction; and
a plurality of dummy conductive layers arranged in the through-electrode region and contacting the pair of word line cut structures,
wherein a vertical level of the upper surface of the insulating structure in the local region of the through-electrode region is farther from the peripheral circuit structure than a vertical level of an upper surface of a dummy conductive layer, which is farthest from the peripheral circuit structure, among the plurality of dummy conductive layers.

15. The semiconductor device of claim 7, further comprising:
a pair of word line cut structures defining a width of the through-electrode region in the second horizontal direction; and
a plurality of dummy conductive layers arranged in the through-electrode region and contacting the pair of word line cut structures,
wherein the local region of the through-electrode region includes a first local region and a second local region,
a vertical level of the upper surface of the insulating structure in the first local region is closer to the peripheral circuit structure than a vertical level of an upper surface of a dummy conductive layer, which is farthest from the peripheral circuit structure, among the plurality of dummy conductive layers, and
a vertical level of the upper surface of the insulating structure in the second local region is farther from the peripheral circuit structure than the vertical level of the upper surface of the dummy conductive layer, which is farthest from the peripheral circuit structure, among the plurality of dummy conductive layers.

16. The semiconductor device of claim 7, wherein the insulating structure further comprises at least one third insulating film, the at least one third insulating film being between an upper second insulating film, which is adjacent to the interlayer dielectric, among the plurality of second insulating films in the local region of the through-electrode region and the interlayer dielectric, the at least one third insulating film being in contact with the upper second insulating film,
each of the plurality of first insulating films comprises a silicon oxide film,
each of the at least one third insulating film and the plurality of second insulating films comprises a silicon nitride film or a hydrogenated silicon nitride film, a content ratio of silicon atoms (Si) in the at least one third insulating film being greater than a content ration of silicon atoms (Si) in each of the plurality of second insulating films, and
at least one through-electrode selected from the plurality of through-electrodes passes through the at least one third insulating film in the vertical direction.

17. The semiconductor device of claim 7, wherein each of the plurality of memory cell blocks comprises a memory cell area and a connection area, the memory cell area comprising a plurality of gate lines and a plurality of vertical channel structures passing through the plurality of gate lines in the vertical direction, the connection area arranged on one side of the memory cell area and including an edge portion of each of the plurality of gate lines,
the through-electrode region comprises a first through-electrode portion facing the memory cell area in the second horizontal direction, a second through-electrode portion facing the connection area in the second horizontal direction and arranged at a first position in the through-electrode region, and a third through-electrode portion facing the connection area in the second horizontal direction and arranged at a second position in the through-electrode region,
in each of the second through-electrode portion and the third through-electrode portion, the insulating structure further comprises a third insulating film contacting an upper second insulating film, which is adjacent to the interlayer dielectric, among the plurality of second insulating films, and
the third insulating film of the second through-electrode portion and the third insulating film of the third through-electrode portion are at different vertical levels respectively.

18. The semiconductor device of claim 7, wherein, in the second horizontal direction, a width of the through-electrode region is greater than a width of each of the plurality of memory cell blocks.

19. The semiconductor device of claim 7, wherein, in the second horizontal direction, a width of the through-electrode region is equal to a width of each of the plurality of memory cell blocks.

20. A semiconductor device comprising:
a peripheral circuit structure comprising a circuit substrate and a plurality of circuits on the circuit substrate;
a plurality of mats overlapping the peripheral circuit structure in a vertical direction, each of the plurality of mats comprising a plurality of memory cell blocks extending lengthwise in a first horizontal direction; and
at least one through-electrode region overlapping the peripheral circuit structure in the vertical direction, the at least one through-electrode region being at at least one of a first position or a second position, the first position being between two adjacent memory cell blocks selected from the plurality of memory cell blocks, and the second position being between two adjacent mats in a second horizontal direction perpendicular to the first horizontal direction from among the plurality of mats,
wherein the at least one through-electrode region comprises
an insulating structure comprising a plurality of first insulating films, a plurality of second insulating films, and a plurality of third insulating films, the plurality of first insulating films and the plurality of second insulating films comprising different materials from each other, the plurality of first insulating films and the plurality of second insulating films alternately stacked one-by-one in the vertical direction, the plurality of third insulating films contacting an upper second insulating film among the plurality of second insulating films, the insulating structure having an upper surface that has a varying height in the vertical direction along with each of the first horizontal direction and the second horizontal direction;
an interlayer dielectric covering the upper surface of the insulating structure; and
a plurality of through-electrodes passing through the insulating structure and the interlayer dielectric in the vertical direction in a local region of the at least one through-electrode region, each of the plurality of through-electrodes being configured to be connected to one circuit selected from the plurality of circuits of the peripheral circuit structure, and wherein each of the plurality of first insulating films comprises a silicon oxide film, and
each of the plurality of second insulating films and the plurality of third insulating films comprises a silicon nitride film or a hydrogenated silicon nitride film.

21. (canceled)
